(19) United States
(12) Patent Application Publication
(10) Pub. No.: US 2014/0183503 A1
(43) Pub. Date: Jul. 3, 2014

(54) Light-Emitting Element, Light-Emitting Device, Electronic Appliance, and Lighting Device

(71) Applicant: Semiconductor Energy Laboratory Co., Ltd., Kanagawa-ken (JP)

(72) Inventors: Hiroshi Kadoma, Sagamihara (JP); Kaori Ogita, Isehara (JP); Satoko Shitagaki, Isehara (JP); Nobuharu Ohsawa, Zama (JP); Satoshi Seo, Sagamihara (JP); Harue Osaka, Atsugi (JP)

(73) Assignee: Semiconductor Energy Laboratory Co., Ltd., Kanagawa-ken (JP)

(21) Appl. No.: 14/141,667

(22) Filed: Dec. 27, 2013

(30) Foreign Application Priority Data
Dec. 28, 2012 (JP) 2012-286619

(51) Int. Cl. H01L 51/00

(52) U.S. Cl. CPC H01L 51/0072; H01L 51/0074
USPC 257/40; 546/77

(57) ABSTRACT

Disclosed is a light-emitting element having high emission efficiency, capable of driving at low voltage, and showing a long lifetime. The light-emitting element contains a compound between a pair of electrodes, and the compound is configured to give a first peak of m/z around 202 and a second peak of m/z around 227 in a mass spectrum. The first and second peaks are product ions of the compound and possess compositions of C₁₆H₉ and C₁₇H₁₀N, respectively, which are derived from a dibenzo[f,h]quinoline unit.

### BACKGROUND OF THE INVENTION

1. Field of the Invention

One embodiment of the present invention relates to, for example, a light-emitting element containing an organic compound that is capable of converting triplet excited energy into luminescence. One embodiment of the present invention also relates to, for example, a light-emitting device, an electronic appliance, and a lighting device each of which includes the light-emitting element.

2. Description of the Related Art

In recent years, research and development have been actively conducted on light-emitting elements using electroluminescence (EL). In a basic structure of such a light-emitting element, a layer containing a light-emitting substance is interposed between a pair of electrodes. By applying voltage to this element, light emission from the light-emitting substance can be obtained.

Such a light-emitting element is self-luminous elements and has advantages over liquid crystal displays, such as high visibility of the pixels and no need of backlight; thus, such a light-emitting element is considered to be suitable as a flat panel display element. Besides, such a light-emitting element has advantages in that it can be manufactured to be thin and lightweight, and has very fast response speed.

Furthermore, since such a light-emitting element can be formed in a film form, planar light emission can be easily obtained; thus, a large element utilizing planar light emission can be formed. This feature is difficult to obtain with point light sources typified by incandescent lamps and LEDs or linear light sources typified by fluorescent lamps. Thus, the light-emitting element also has great potential as a planar light source applicable to a lighting device and the like.

Such light-emitting elements utilizing electroluminescence can be broadly classified according to whether a light-emitting substance is an organic compound or an inorganic compound. In the case of an organic EL element in which a layer containing an organic compound used as a light-emitting substance is provided between a pair of electrodes, application of voltage to the light-emitting element causes injection of electrons from a cathode and holes from an anode into the layer containing the light-emitting organic compound and thus current flows. The injected electrons and holes then lead the organic compound having a light-emitting property to its excited state, whereby light emission is obtained from the excited light-emitting organic compound.

The excited state of an organic compound can be a singlet excited state or a triplet excited state. Light emission from the singlet excited state (S*) is called fluorescence, and light emission from the triplet excited state (T*) is called phosphorescence. The statistical generation ratio of S* to T* in a light-emitting element is thought to be 1:3.

With a compound that can convert energy of a singlet excited state into light (hereinafter, called a fluorescent compound), only light emission from the singlet excited state (fluorescence) is observed and that from the triplet excited state (phosphorescence) is not observed at room temperature. Therefore, the internal quantum efficiency (the ratio of the number of generated photons to the number of injected carriers) of a light-emitting element including the fluorescent compound is assumed to have a theoretical limit of 25%, on the basis of S*:T*=1:3.

In contrast, with a compound that can convert energy of a triplet excited state into light emission (hereinafter called phosphorescent compound), light emission from the triplet excited state (phosphorescence) is observed. Further, since intersystem crossing (i.e., transition from a singlet excited state to a triplet excited state) easily occurs in a phosphorescent compound, the internal quantum efficiency can be theoretically increased to 100%. In other words, the emission efficiency can be four times as much as that of the fluorescence compound. For this reason, light-emitting elements using a phosphorescent compound have been recently under active development so that high-efficiency light-emitting elements can be achieved.

When formed using the above phosphorescent compound, a light-emitting layer of a light-emitting element is often formed such that the phosphorescent compound is dispersed in a matrix containing another compound in order to suppress concentration quenching or quenching due to triplet-triplet annihilation of the phosphorescent compound. Here, the compound used as the matrix is called a host material, and the compound dispersed in the matrix, such as a phosphorescent compound, is called a guest material.

In the case where a phosphorescent compound is a guest material, a host material needs to have higher triplet excitation energy (energy difference between a ground state and a triplet excited state) than the phosphorescent compound.

Furthermore, since singlet excitation energy (energy difference between a ground state and a singlet excited state) is higher than triplet excitation energy, a substance that has high triplet excitation energy also has high singlet excitation energy. Thus, the above substance that has high triplet excitation energy is also effective in a light-emitting element using a fluorescent compound as a light-emitting substance.

Studies have been conducted on a variety of compounds which can be used as the host material when a phosphorescent compound is used as the guest material. For example, studies have been conducted on compounds having triphenylene rings or having dibenzo[f,h]quinoxaline rings (see, for example, Patent Documents 1 and 2).

### [Patent Document 1] Japanese Translation of PCT International Application No. 2010-535806

### [Patent Document 2] Japanese Published Patent Application No. 2007-189001

### SUMMARY OF THE INVENTION

As reported in Patent Document 1 or 2, although host materials of phosphorescent compounds have been developed, there is room for improvement in terms of light-emitting characteristics or synthesis efficiency of the host material as well as driving voltage, reliability, cost, or the like, of a light-emitting element using the host material, and further development is required for more excellent phosphorescent compounds.

In view of the above problems, one embodiment of the present invention provides a light-emitting element having high emission efficiency. Another embodiment of the present invention provides a light-emitting element which has low driving voltage. Another embodiment of the present invention provides a light-emitting element which has a long lifetime. Another embodiment of the present invention provides a light-emitting element which has high heat resistance. Another embodiment of the present invention provides a light-emitting element which has an organic compound with an excellent carrier-transport property. Another embodiment of the present invention provides a light-emitting element which has an organic compound with high electrochemical stability. Another embodiment of the present invention provides a novel light-emitting element, a novel light-emitting device, a novel electronic appliance, or a novel lighting device.

Note that the descriptions of these objects do not disturb the existence of other objects. Note that one embodiment of the present invention achieves at least one of the above objects. Other objects are apparent from and can be derived from the description of the specification, the drawings, and the claims.

One embodiment of the present invention is a light-emitting element which contains an organic compound between a pair of electrodes. The organic compound has a dibenzo[f,h]quinoline ring, an arylene group, and a hole-transport skeleton.

Another embodiment of the present invention is a light-emitting element which contains an organic compound between a pair of electrodes. The organic compound has a dibenzo[f,h]quinoline ring, an arylene group, and a hole-transport skeleton. The dibenzo[f,h]quinoline ring and the hole-transport skeleton are bonded to each other through the arylene group.

Since the organic compound used in one embodiment of the present invention has the hole-transport skeleton as well as the dibenzo[f,h]quinoline ring in, holes and electrons can be easily accepted. Thus, electrons and holes can easily recombine on the organic compound. Moreover, since the dibenzo[f,h]quinoline ring and the hole-transport skeleton are bonded to each other through the arylene group in the organic compound, the band gap can be prevented from being narrowed and the triplet excitation energy can be prevented from being reduced as compared to an organic compound in which a dibenzo[f,h]quinoline ring and a hole-transport skeleton are directly bonded. Thus, when the organic compound is used for a light-emitting element, the light-emitting element can have high current efficiency.

As the hole-transport skeleton, a π-electron rich heteroaromatic ring is preferable. As the π-electron rich heteroaromatic ring, a carbazole ring, a dibenzofuran ring, or a dibenzothiophene ring is preferable. As the arylene group, any of a substituted or unsubstituted phenylene group and a substituted or unsubstituted biphenyldiyl group is preferable.

A light-emitting device, an electronic device, and a lighting device each using the above light-emitting element also belong to the category of the present invention. Note that the light-emitting device in this specification includes, in its category, an image display device and a light source. The light-emitting device includes the following modules in its category: a module in which a connector, such as a flexible printed circuit (FPC), a tape automated bonding (TAB) tape, or a tape carrier package (TCP), is attached to a panel, a module in which a printed wiring board is provided at the end of a TCP, and a module in which an integrated circuit (IC) is directly mounted on a light-emitting element by a chip-on-glass (COG) method.

According to one embodiment of the present invention, a light-emitting element which has low driving voltage and high current efficiency can be provided. According to one embodiment of the present invention, the use of the light-emitting element makes it possible to provide a light-emitting device, an electronic device, and a lighting device which have lower power consumption.

### BRIEF DESCRIPTION OF THE DRAWINGS

FIGS. 1A to 1C each illustrate a light-emitting element of one embodiment of the present invention.

FIGS. 2A and 2B illustrate a light-emitting device of one embodiment of the present invention.

FIGS. 3A and 3B illustrate a light-emitting device of one embodiment of the present invention.

FIGS. 4A and 4B each illustrate a light-emitting device of one embodiment of the present invention.

FIGS. 5A and 5B each illustrate a light-emitting device of one embodiment of the present invention.

FIGS. 6A to 6E illustrate lighting devices of one embodiment of the present invention.

FIGS. 7A and 7B illustrate a touch sensor.

FIG. 8 is a circuit diagram illustrating a touch sensor.

FIG. 9 is a cross-sectional view illustrating a touch sensor.

FIG. 10 illustrates a display module including a display device of one embodiment of the present invention.

FIGS. 11A to 11H each illustrate an electronic appliance including a display device of one embodiment of the present invention.

FIGS. 12A to 12H each illustrate an electronic appliance including a display device of one embodiment of the present invention.

FIGS. 13A and 13B are ¹H NMR charts of 2-[3-(dibenzothiophen-4-yl)phenyl]dibenzo[f,h]quinoline (abbreviation: 2mDBTPDBQu-II).

FIG. 14 shows results of MS analysis of 2mDBTPDBQu-II.

FIGS. 15A to 15D show results of ToF-SIMS analysis of 2mDBTPDBQu-II.

FIGS. 16A and 16B show absorption and emission spectra of a toluene solution of 2mDBTPDBQu-II.

FIGS. 17A and 17B show absorption and emission spectra of a thin film of 2mDBTPDBQu-II.

FIG. 18 illustrates a light-emitting element of Examples.

FIG. 19 shows current density-luminance characteristics of a light-emitting element 1 and a comparative light-emitting element 2 (reference element 2).

FIG. 20 shows voltage-luminance characteristics of the light-emitting element 1 and the comparative light-emitting element 2.

FIG. 21 shows luminance-current efficiency characteristics of the light-emitting element 1 and the comparative light-emitting element 2.

FIG. 22 shows voltage-current characteristics of the light-emitting element 1 and the comparative light-emitting element 2.

FIG. 23 shows current density-luminance characteristics of a light-emitting element 3.

FIG. 24 shows voltage-luminance characteristics of the light-emitting element 3.

FIG. 25 shows luminance-current efficiency characteristics of the light-emitting element 3.

FIG. 26 shows voltage-current characteristics of the light-emitting element 3.

FIGS. 27A and 27B are ¹H NMR charts of 2-{3-[3-(dibenzothiophen-4-yl)phenyl]phenyl}dibenzo[f,h]quinoline (abbreviation: 2mDBTBPDBQu-II).

FIG. 28 shows results of MS analysis of 2mDBTBPDBQu-II.

FIGS. 29A to 29D show results of ToF-SIMS analysis of 2mDBTBPDBQu-II.

FIGS. 30A and 30B show absorption and emission spectra of a toluene solution of 2mDBTBPDBQu-II.

FIGS. 31A and 31B show absorption and emission spectra of a thin film of 2mDBTBPDBQu-II.

FIG. 32 shows current density-luminance characteristics of a light-emitting element 4 and a comparative light-emitting element 5 (reference element 5).

FIG. 33 shows voltage-luminance of the light-emitting element 4 and the comparative light-emitting element 5.

FIG. 34 shows luminance-current efficiency characteristics of the light-emitting element 4 and the comparative light-emitting element 5.

FIG. 35 shows voltage-current characteristics of the light-emitting element 4 and the comparative light-emitting element 5.

FIG. 36 shows results of reliability tests performed on the light-emitting element 4 and the comparative light-emitting element 5.

### DETAILED DESCRIPTION OF THE INVENTION

Hereinafter, embodiments of the present invention will be described in detail with reference to the accompanying drawings. Note that the present invention is not limited to the description below, and it is easily understood by those skilled in the art that various changes and modifications can be made without departing from the spirit and scope of the present invention. Therefore, the invention should not be construed as being limited to the description in the following embodiments.

### Embodiment 1

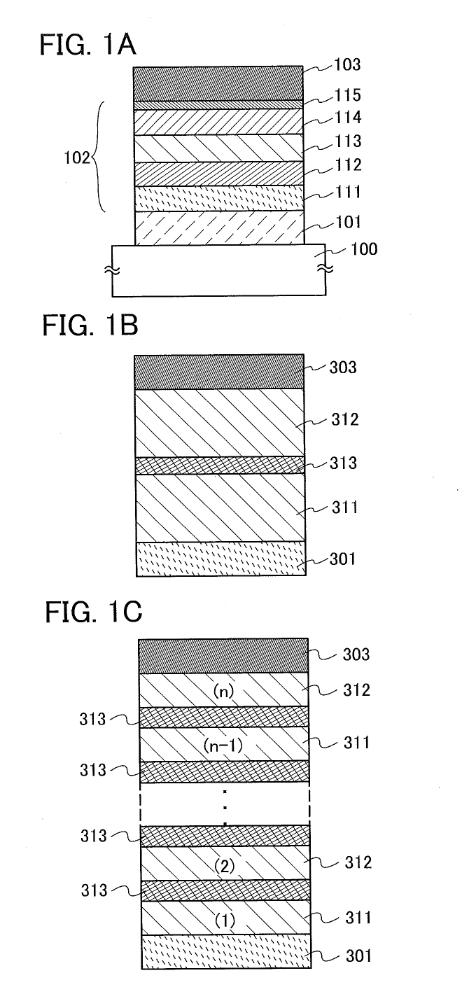

In this embodiment, light-emitting elements each of which includes a light-emitting layer between a pair of electrodes are described with reference to FIGS. 1A to 1C.

First, the light-emitting element illustrated in FIG. 1A is described.

As illustrated in FIG. 1A, the light-emitting element described in this embodiment includes an EL layer 102 between a first electrode 101 and a second electrode 103. The EL layer 102 includes at least a light-emitting layer 113 and also includes a hole-injection layer 111, a hole-transport layer 112, an electron-transport layer 114, an electron-injection layer 115, and the like. Note that in this embodiment, the first electrode 101 is used as an anode and the second electrode 103 is used as a cathode.

The light-emitting layer 113 contains an organic compound. The organic compound has a dibenzo[f,h]quinoline ring, an arylene group, and a hole-transport skeleton. It is particularly preferable that the dibenzo[f,h]quinoline ring and the hole-transport skeleton be bonded to each other through the arylene group.

Since the organic compound has the hole-transport skeleton as well as the dibenzo[f,h]quinoline ring, holes and electrons can be easily accepted. Thus, electrons and holes can easily recombine in the light-emitting layer. Moreover, since the dibenzo[f,h]quinoline ring and the hole-transport skeleton are bonded to each other through the arylene group in the organic compound, the band gap between the HOMO level and the LUMO level can be prevented from being narrowed and the triplet excitation energy can be prevented from being reduced as compared to an organic compound in which a dibenzo[f,h]quinoline ring and a hole-transport skeleton are directly bonded. Thus, when the organic compound is used for a light-emitting element, the light-emitting element can have high current efficiency.

Thus, the use of the organic compound in a light-emitting element enables the light-emitting element to have high current efficiency, low driving voltage, and a long lifetime.

Further details of the light-emitting elements in this embodiment are given below.

A substrate 100 is used as a support of the light-emitting element. For example, glass, quartz, plastic, or the like can be used for the substrate 100. Furthermore, a flexible substrate may be used. The flexible substrate is a substrate that can be bent, such as a plastic substrate made of, for example, a polycarbonate, a polyarylate, or a poly(ether sulfone). Alternatively, a film (made of polypropylene, a polyester, poly(vinyl fluoride), poly(vinyl chloride), or the like), an inorganic film formed by evaporation, or the like can be used. Note that another material may be used as long as it can function as a support in a process of manufacturing the light-emitting element.

As the first electrode 101 and the second electrode 103, a metal, an alloy, an electrically conductive compound, a mixture thereof, and the like can be used. Specific examples include indium oxide-tin oxide (ITO: indium tin oxide), indium oxide-tin oxide containing silicon or silicon oxide, indium oxide-zinc oxide, indium oxide containing tungsten oxide and zinc oxide, gold (Au), platinum (Pt), nickel (Ni), tungsten (W), chromium (Cr), molybdenum (Mo), iron (Fe), cobalt (Co), copper (Cu), palladium (Pd), and titanium (Ti). Further, any of the following materials can be used: elements that belong to Group 1 or Group 2 of the periodic table, that is, alkali metals such as lithium (Li) and cesium (Cs) or alkaline earth metals such as magnesium (Mg), calcium (Ca), and strontium (Sr), and alloys containing at least one of the metals (e.g., Mg—Ag and Al—Li); rare earth metals such as europium (Eu) and ytterbium (Yb), and alloys containing at least one of the metals; graphene; and the like. The first electrode 101 and the second electrode 103 can be formed by, for example, a sputtering method, an evaporation method (including a vacuum evaporation method), or the like.

As a substance with a high hole-transport property that is used for the hole-injection layer 111 and the hole-transport layer 112, a π-electron rich heteroaromatic compound (e.g., a carbazole derivative or an indole derivative) or an aromatic amine compound can be used. For example, the following substances can be used: a compound having an aromatic amine skeleton such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(Spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II).

Among the materials given above, a compound having a carbazole skeleton is preferable because a carbazole compound is highly reliable and has a high hole-transport property to contribute to a reduction in driving voltage.

Further, as a material that can be used for the hole-injection layer 111 and the hole-transport layer 112, a high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can be used.

As each of the hole-injection layer 111 and the hole-transport layer 112, a layer in which any of the substances having a high hole-transport property given above and a substance having an acceptor property are mixed is preferably used, in which case a favorable carrier-injection property is obtained. Examples of the acceptor substance to be used include oxides of transition metals such as oxides of metals belonging to Groups 4 to 8 of the periodic table. Specifically, molybdenum oxide is particularly preferable.

The light-emitting layer 113 preferably contains, for example, a host material (a first organic compound) and a phosphorescent material (a second organic compound). Another material may be further included as an assist material (a third organic compound).

Here, as the above host material (the first organic compound), the organic compound having a dibenzo[f,h]quinoline ring, an arylene group, and a hole-transport skeleton is used. Specifically, an organic compound in which a dibenzo[f,h]quinoline ring and a hole-transport skeleton are bonded to each other through an arylene group is used.

As the hole-transport skeleton, a π-electron rich heteroaromatic ring is preferable. As the π-electron rich heteroaromatic ring, a carbazole ring, a dibenzofuran ring, or a dibenzothiophene ring is preferable. As the arylene group, any of a substituted or unsubstituted phenylene group and a substituted or unsubstituted biphenyldiyl group is preferable.

The organic compound can be specifically represented by the general formulae (G0), (G1), (G2-1), (G2-2), (G3-1), and (G3-2) given below.

E-Ar-A (G0)

In the general formula (G0), A represents any of a substituted or unsubstituted carbazolyl group, a substituted or unsubstituted dibenzothiophenyl group, and a substituted or unsubstituted dibenzofuranyl group; E represents a substituted or unsubstituted dibenzo[f,h]quinoline ring; and Ar represents an arylene group having 6 to 13 carbon atoms. The arylene group may have one or more substituents that may be bonded to each other to form a ring.

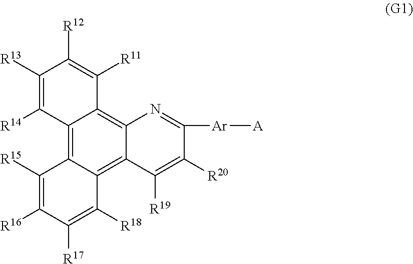

In the general formula (G1), A represents any of a substituted or unsubstituted carbazolyl group, a substituted or unsubstituted dibenzothiophenyl group, and a substituted or unsubstituted dibenzofuranyl group; R¹¹ to R²⁰ separately represent any of hydrogen, an alkyl group having 1 to 4 carbon atoms, and a substituted or unsubstituted aryl group having 6 to 13 carbon atoms; and Ar represents an arylene group having 6 to 13 carbon atoms. The arylene group may have one or more substituents that may be bonded to each other to form a ring.

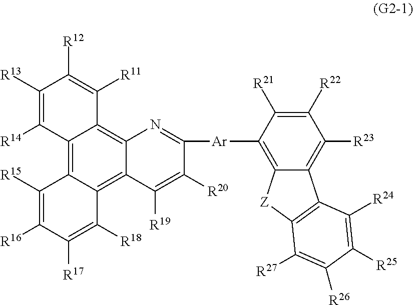

In the general formula (G2-1), Z represents oxygen or sulfur; R¹¹ to R²⁷ separately represent any of hydrogen, an alkyl group having 1 to 4 carbon atoms, and a substituted or unsubstituted aryl group having 6 to 13 carbon atoms; and Ar represents an arylene group having 6 to 13 carbon atoms. The arylene group may have a substituents or substituents that may be bonded to each other to form a ring.

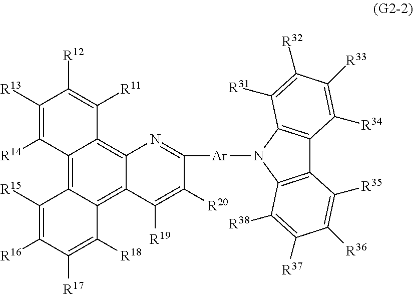

In the general formula (G2-2), R¹¹ to R²⁰ and R³¹ to R³⁸ separately represent any of hydrogen, an alkyl group having 1 to 4 carbon atoms, and a substituted or unsubstituted aryl group having 6 to 13 carbon atoms; and Ar represents an arylene group having 6 to 13 carbon atoms. The arylene group may have one or more substituents that may be bonded to each other to faun a ring.

In the general formulae (G2-1) and (G2-2), Ar is preferably either a substituted or unsubstituted phenylene group or a substituted or unsubstituted biphenyldiyl group. In particular, Ar is preferably a substituted or unsubstituted phenylene group. Ar is preferably a substituted or unsubstituted ni-phenylene group for a high triplet excitation energy level.

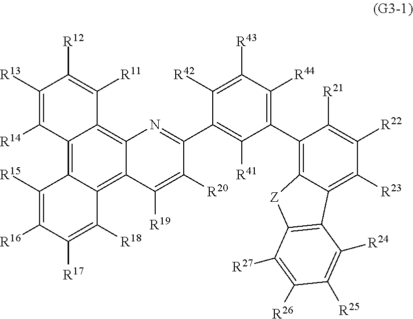

In the general formula (G3-1), Z represents oxygen or sulfur; and R¹¹ to R²⁷ and R⁴¹ to R⁴⁴ separately represent any of hydrogen, an alkyl group having 1 to 4 carbon atoms, and a substituted or unsubstituted aryl group having 6 to 13 carbon atoms.

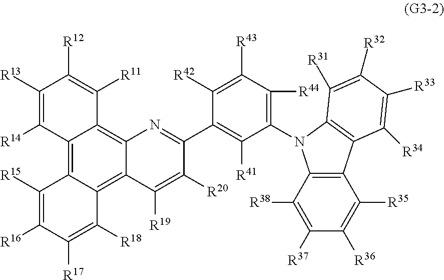

In the general formula (G3-2), R¹¹ to R²⁰, R³¹ to R³⁸, and R⁴¹ to R⁴⁴ separately represent any of hydrogen, an alkyl group having 1 to 4 carbon atoms, and a substituted or unsubstituted aryl group having 6 to 13 carbon atoms.

Specific examples of Ar in the general formulae (G0), (G1), (G2-1), and (G2-2) are substituents represented by structural formulae (1-1) to (1-15).

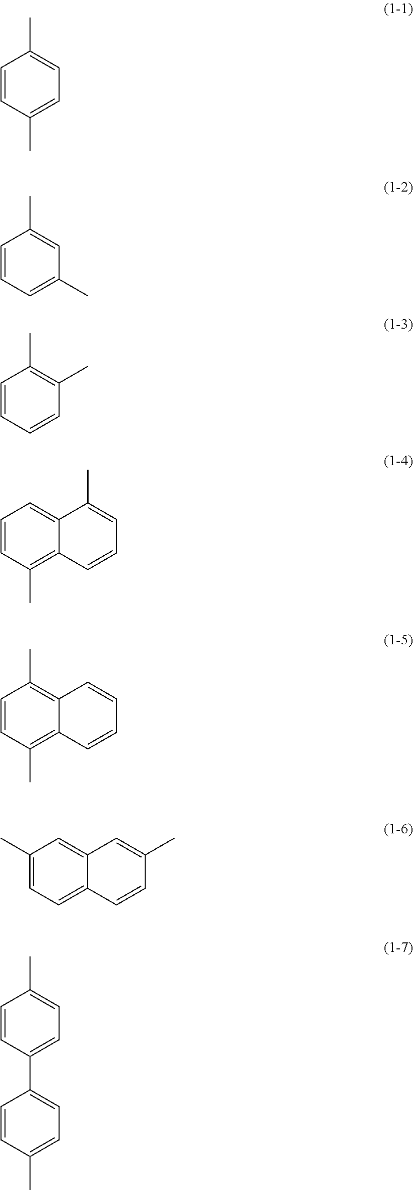

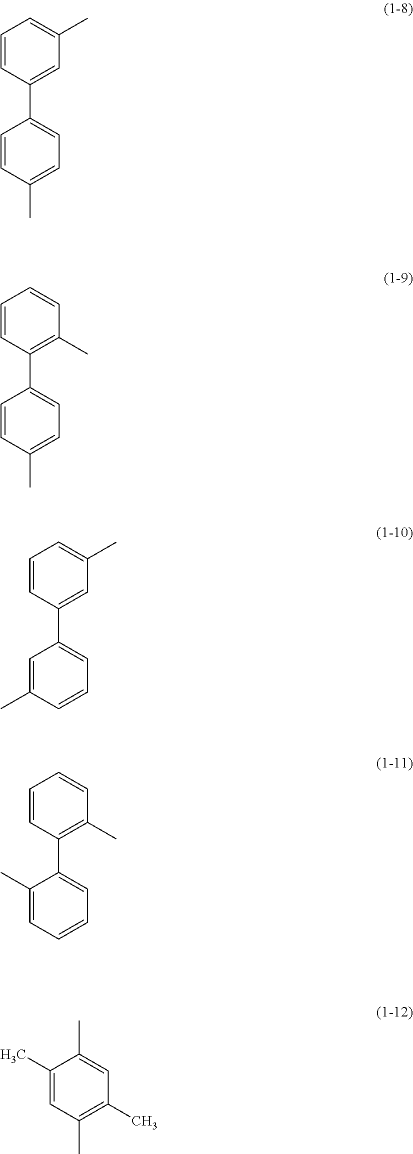

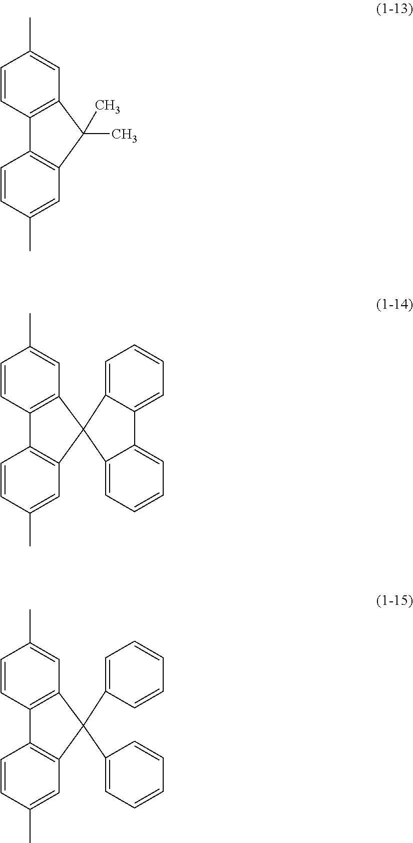

Specific examples of R¹¹ to R²⁷, R³¹ to R³⁸, and R⁴¹ to R⁴⁴ in the general formulae (G1), (G2-1), (G2-2), (G3-1), and (G3-2) are substituents represented by structural formulae (2-1) to (2-23).

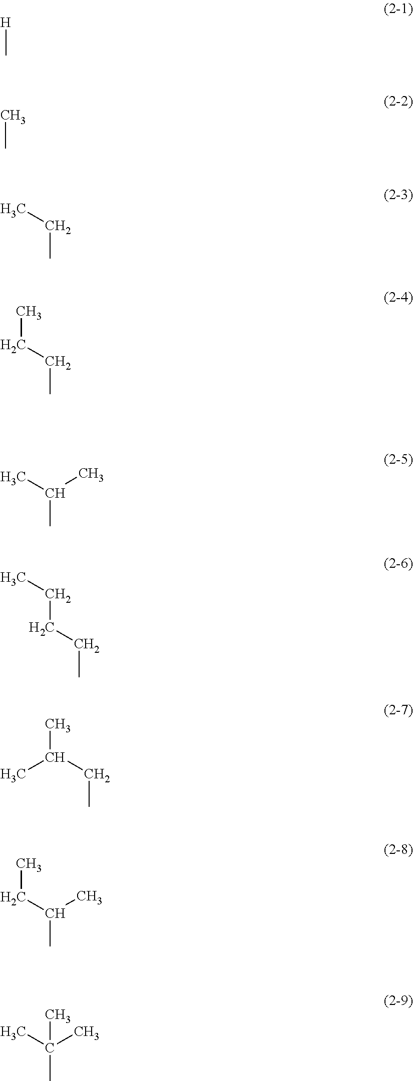

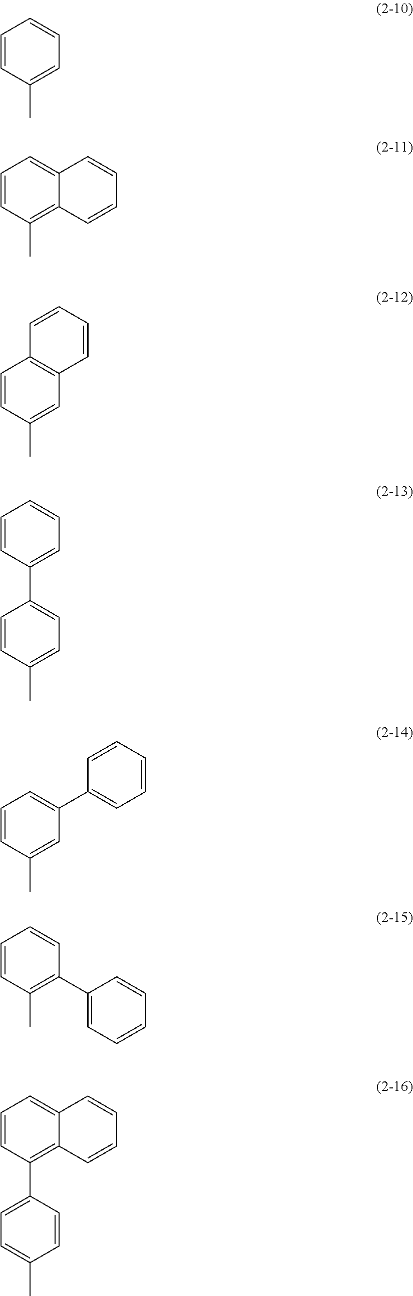

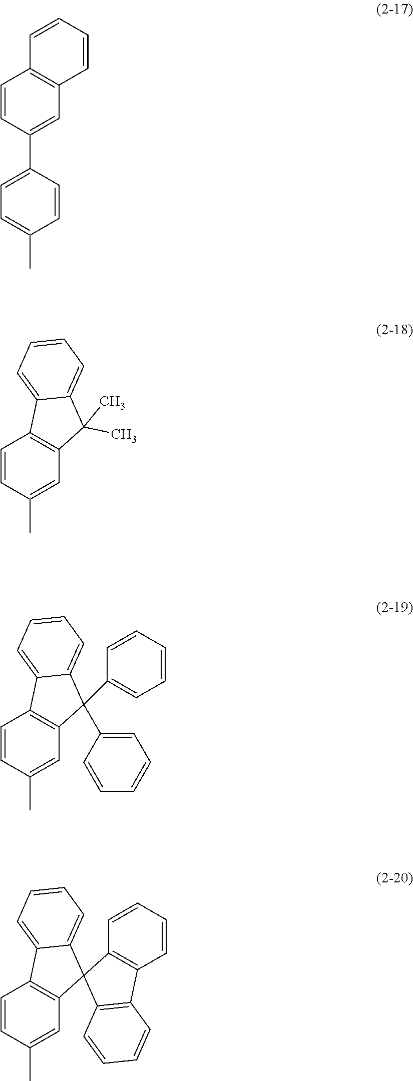

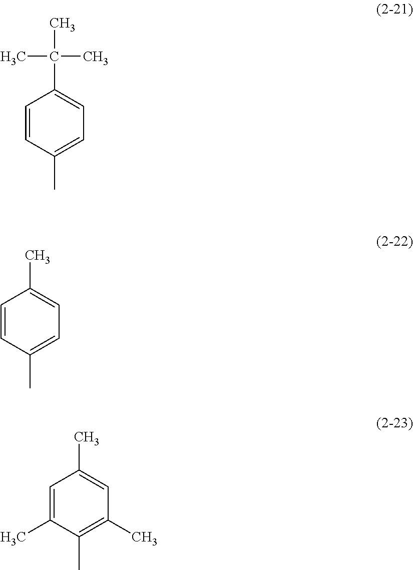

Specific examples of the organic compound represented by the general formula (G1) include organic compounds represented by structural formulae (100) to (154), (200) to (254), and (300) to (354). Note that one embodiment of the present invention is not limited thereto.

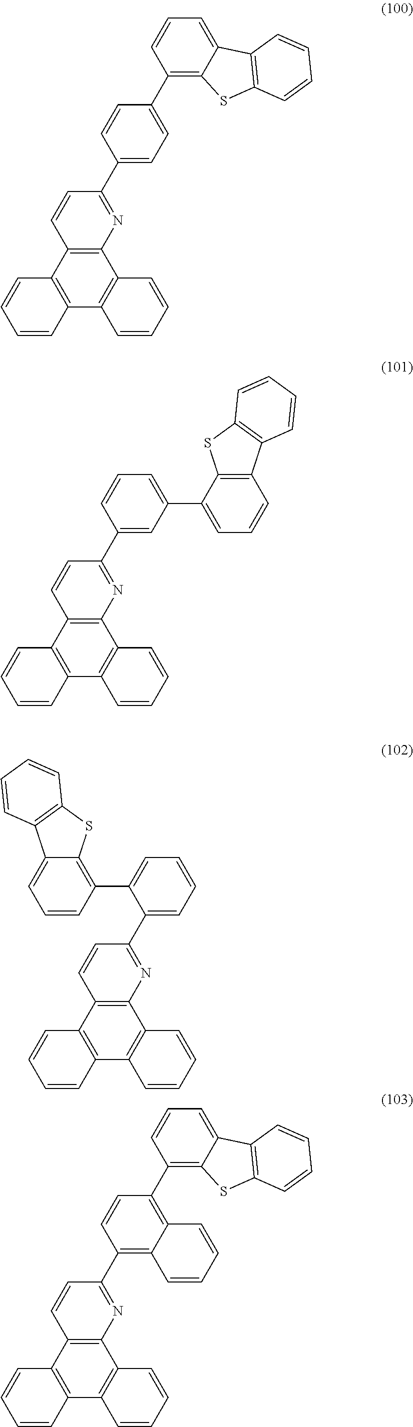

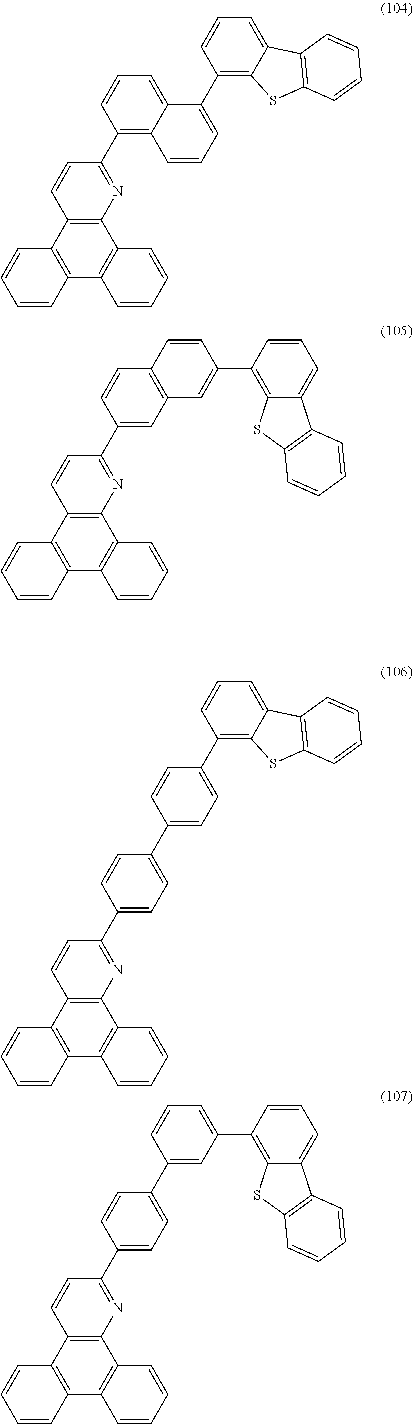

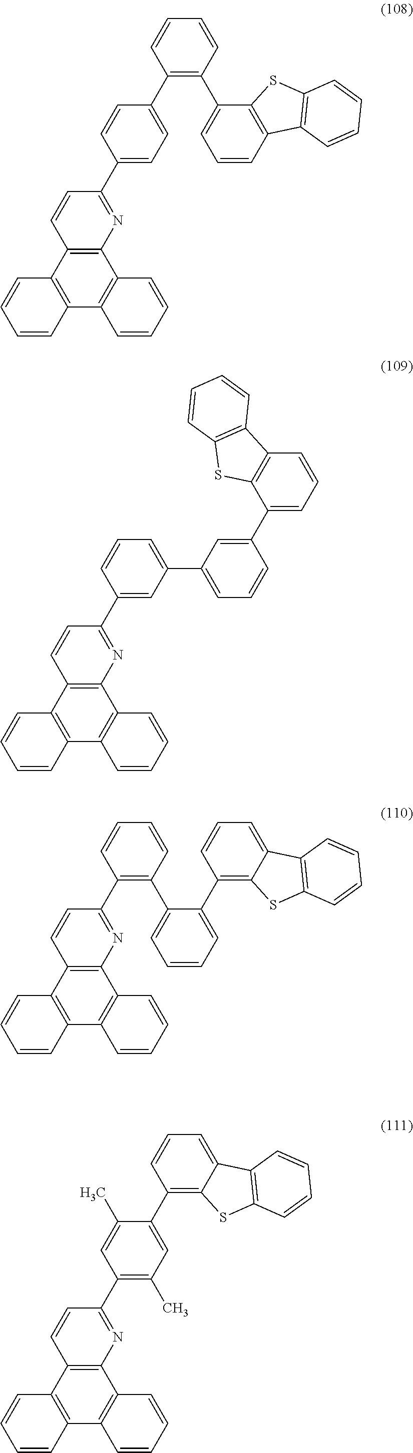

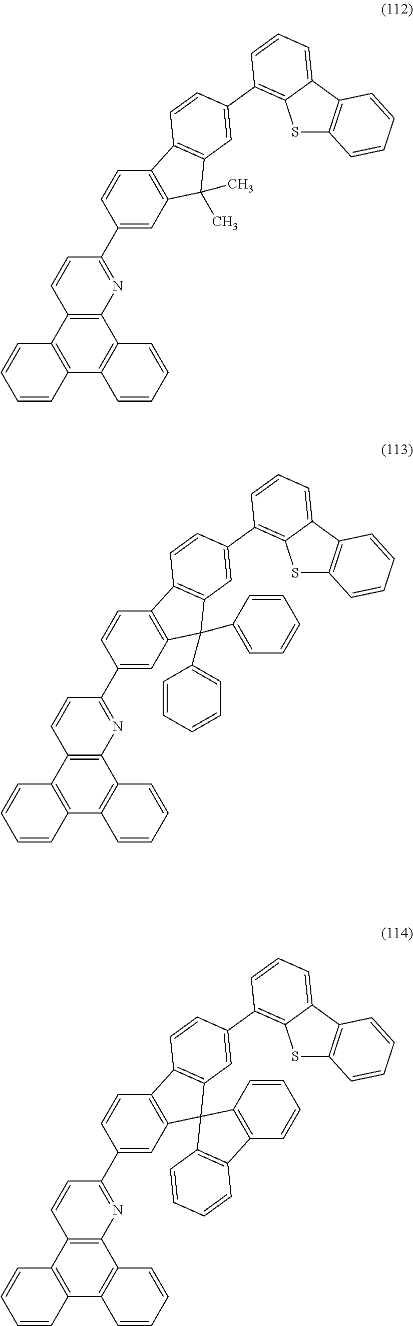

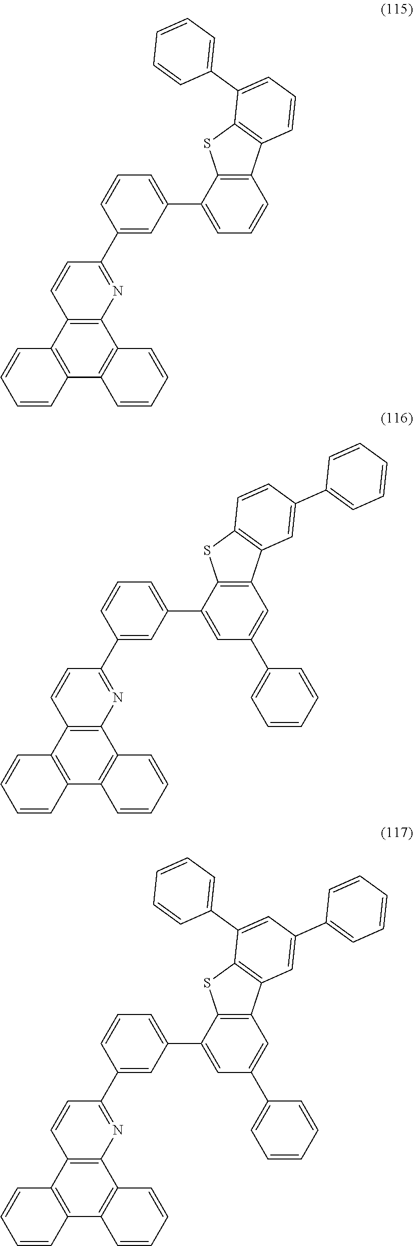

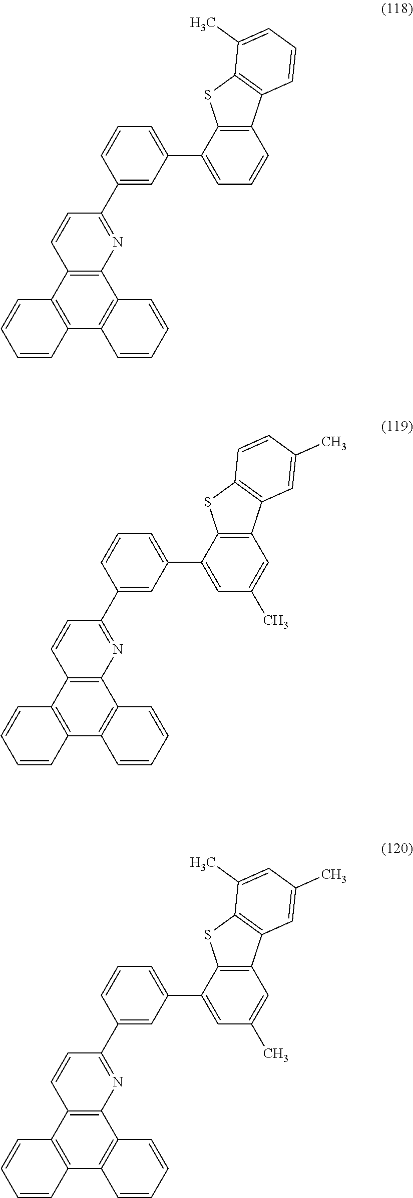

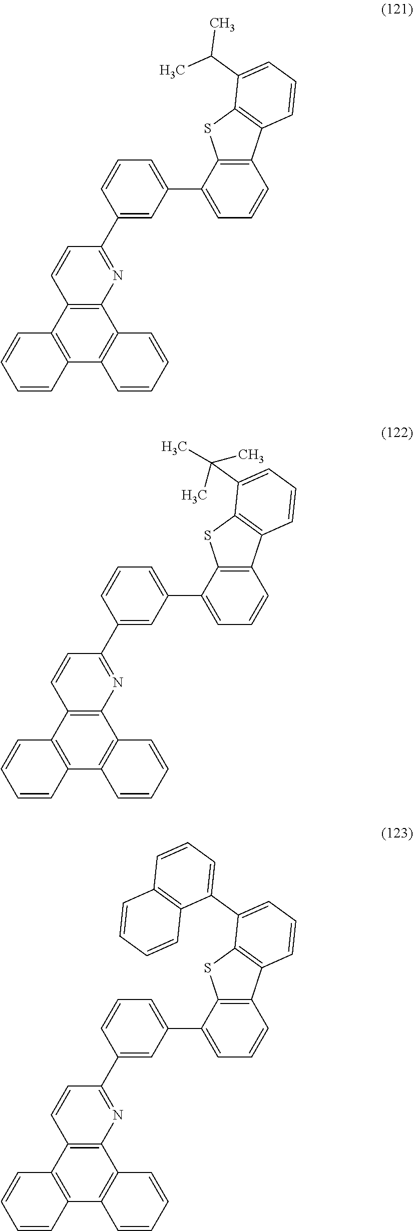

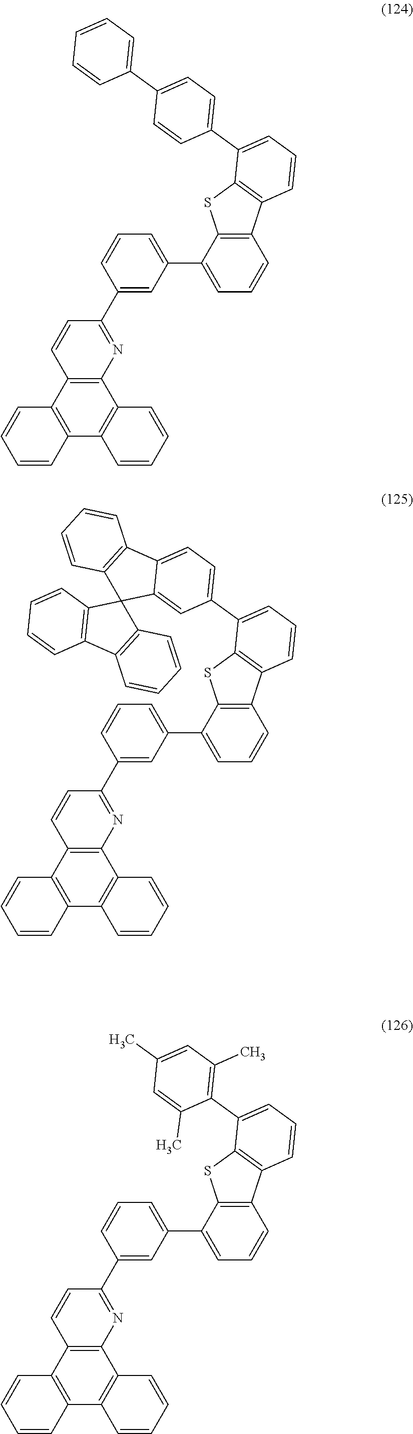

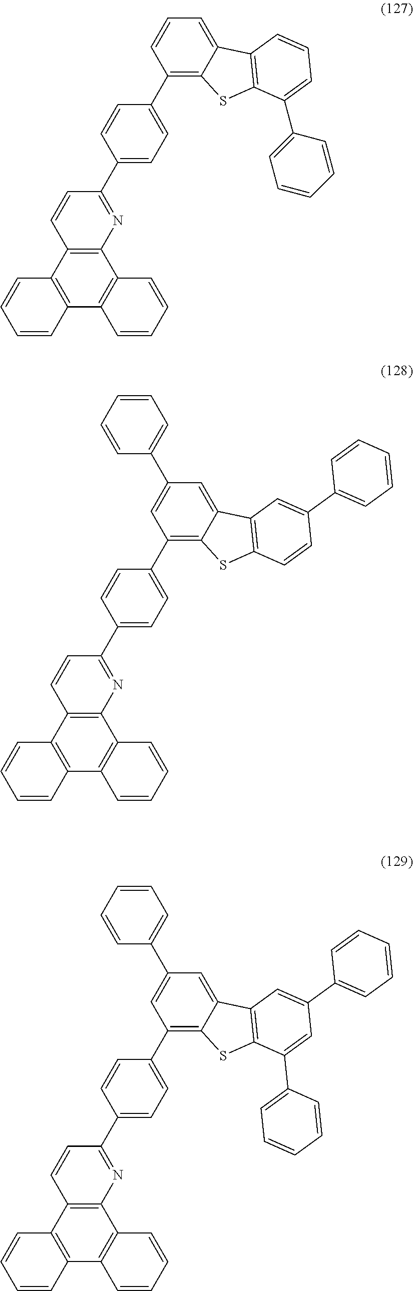

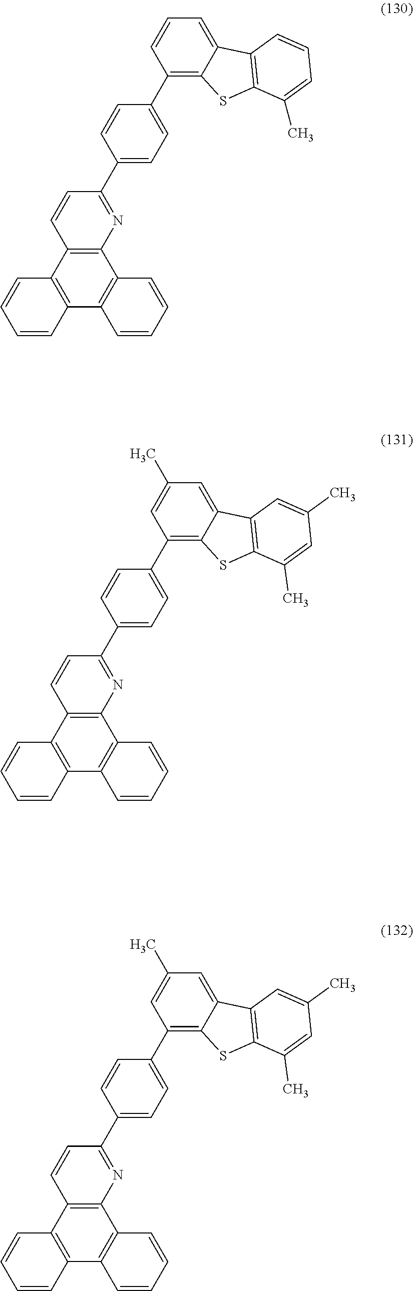

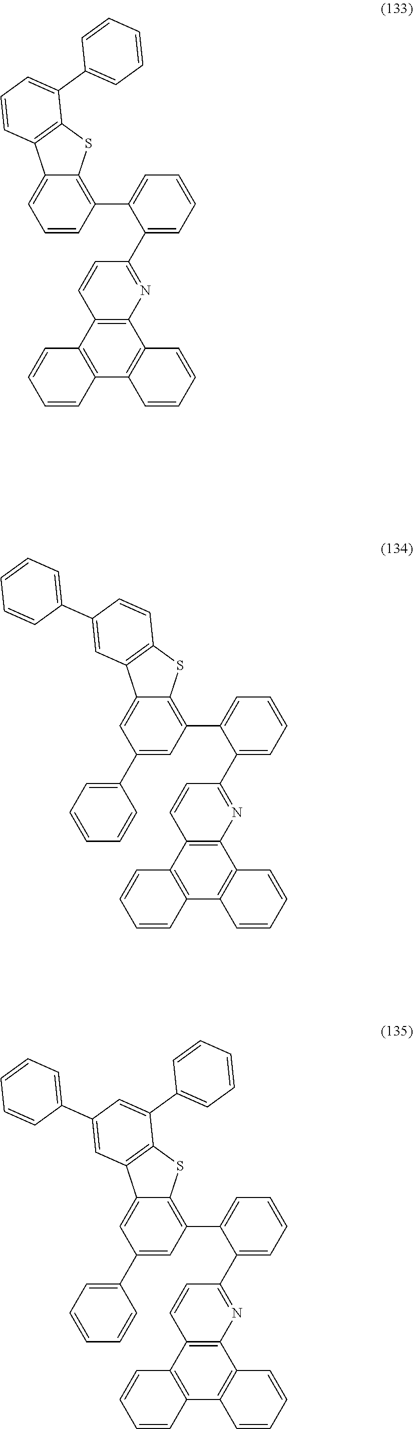

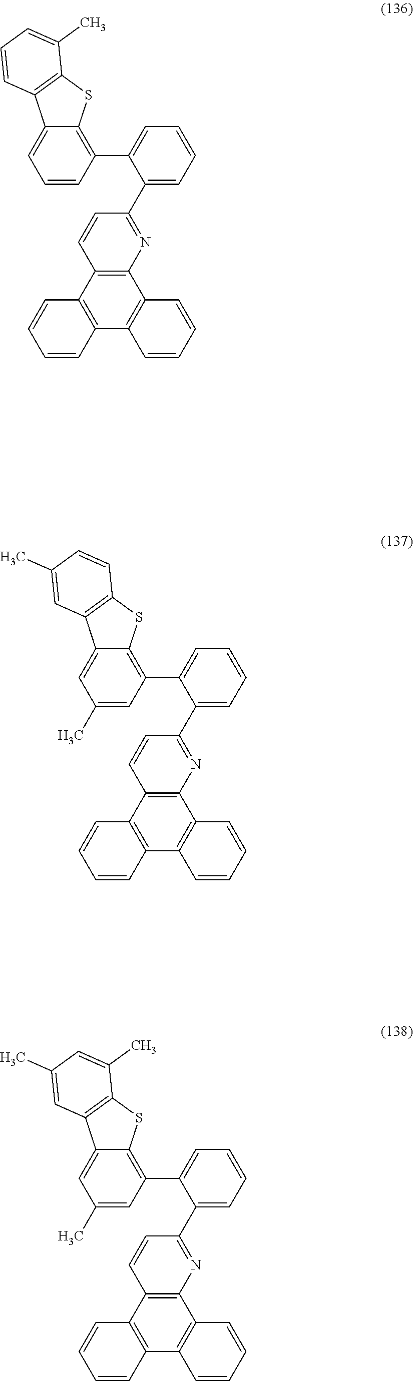

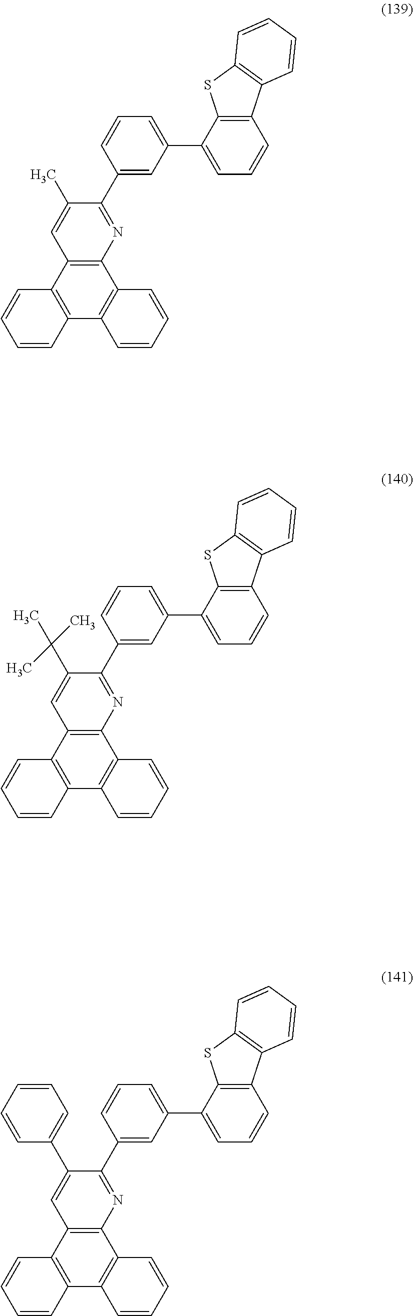

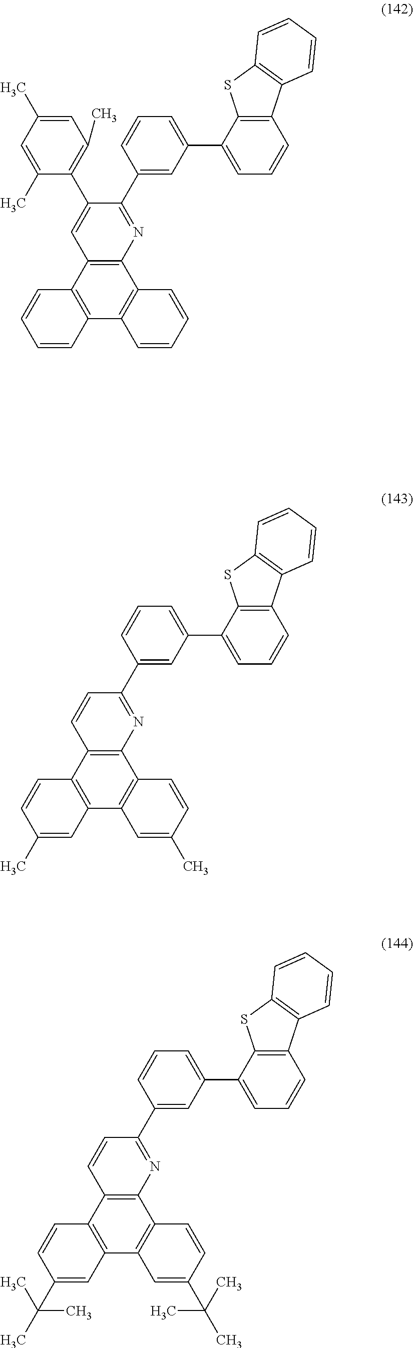

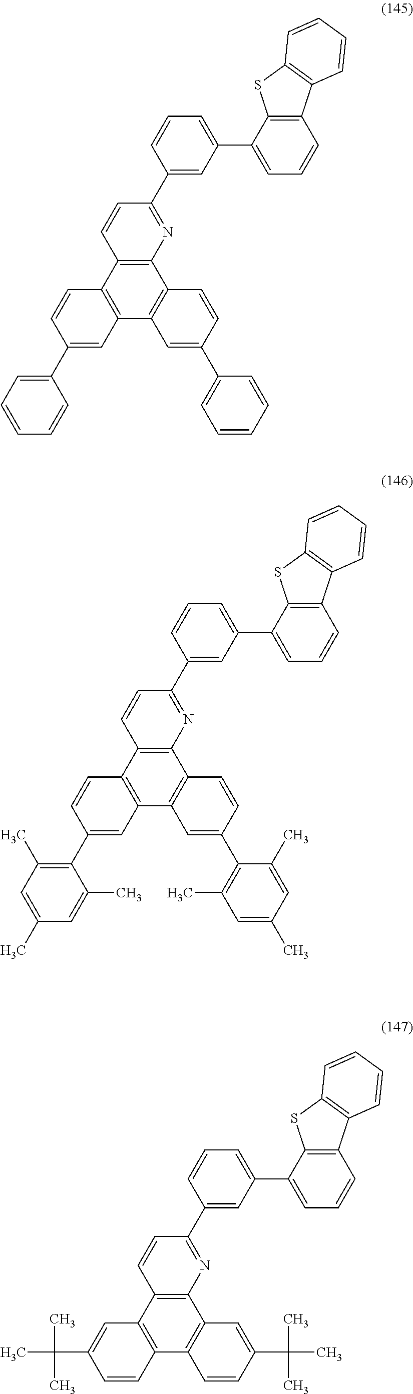

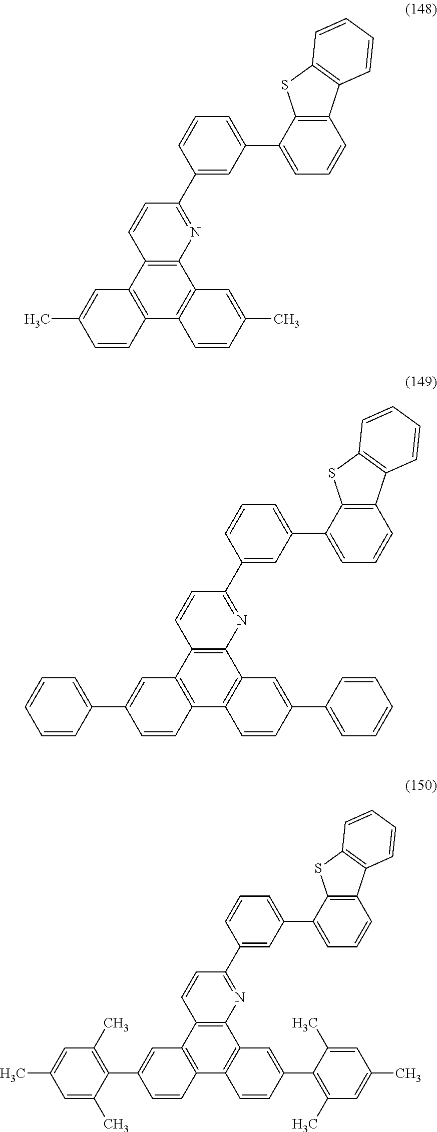

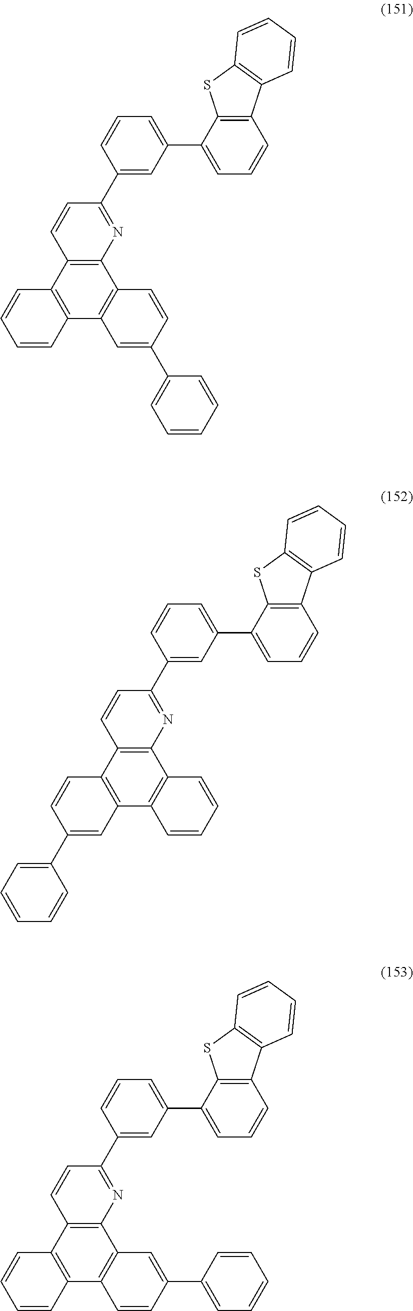

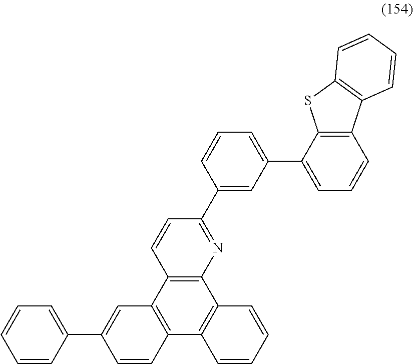

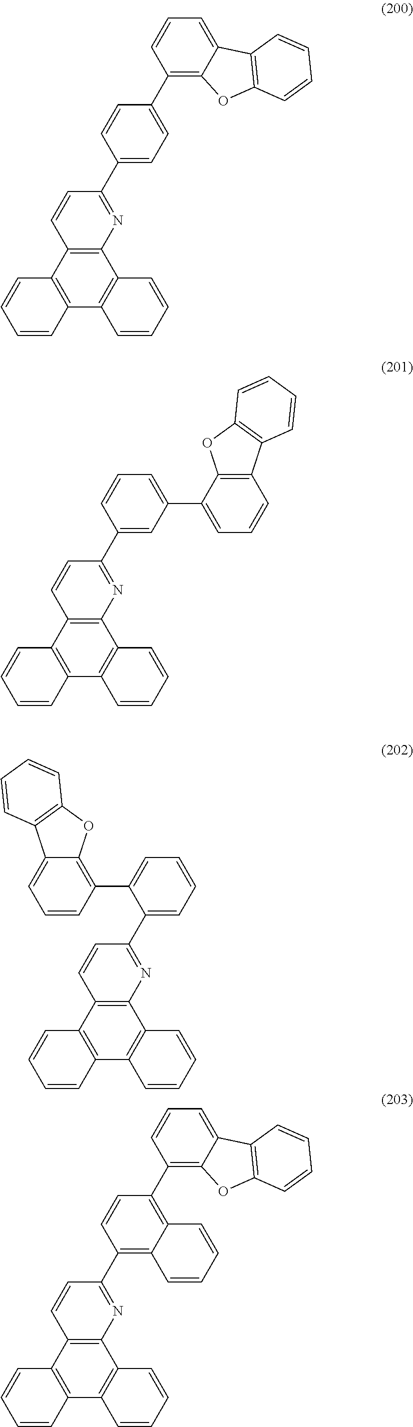

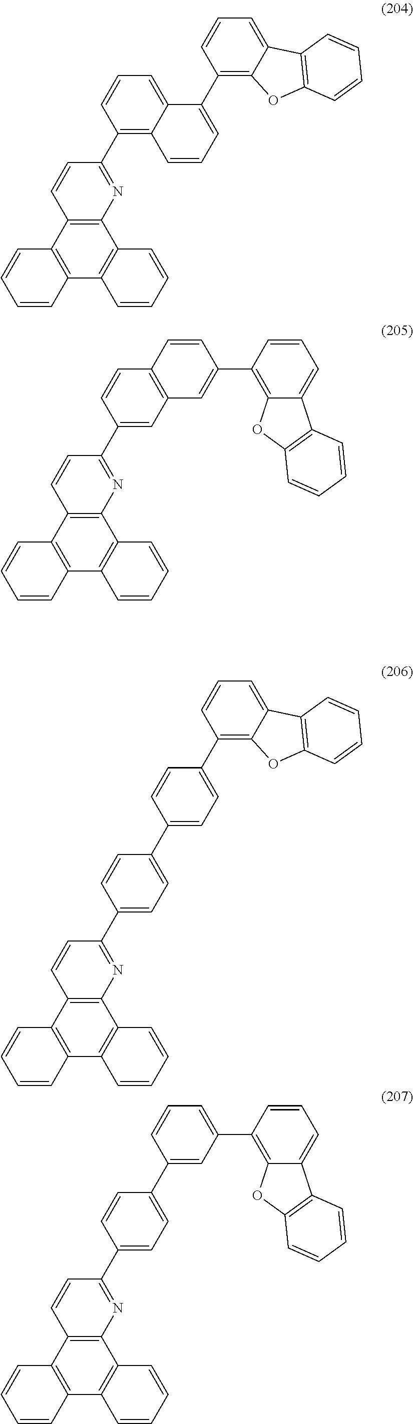

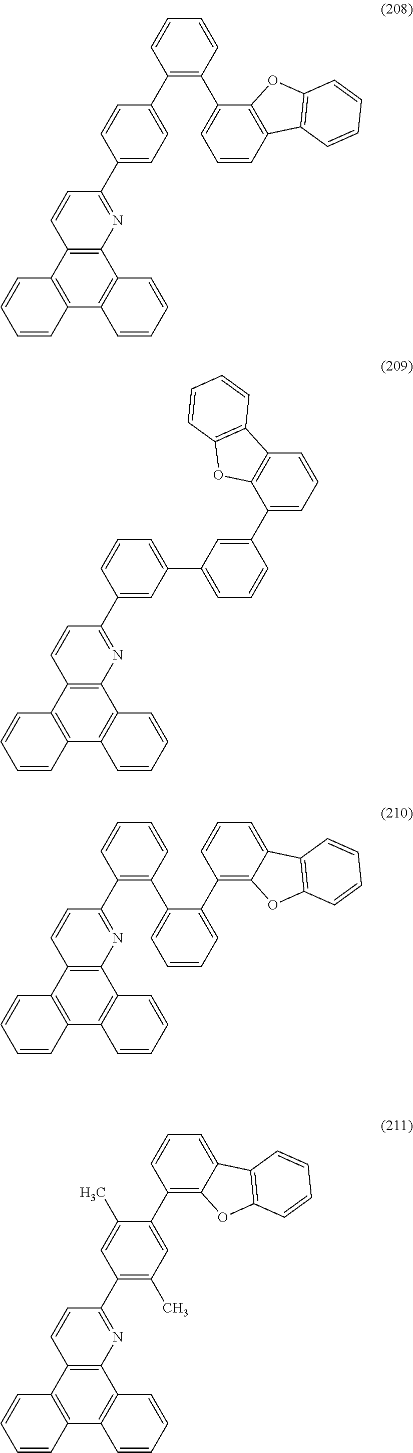

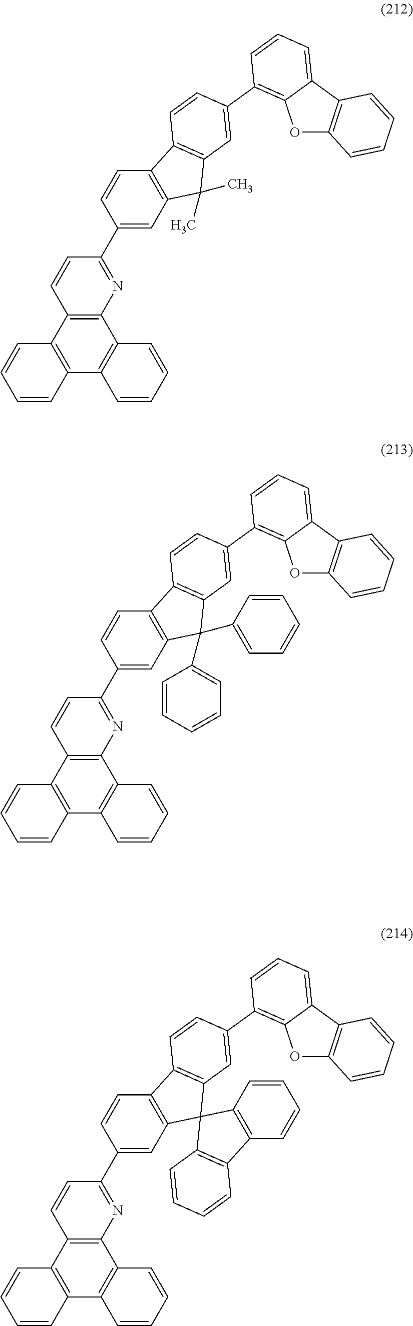

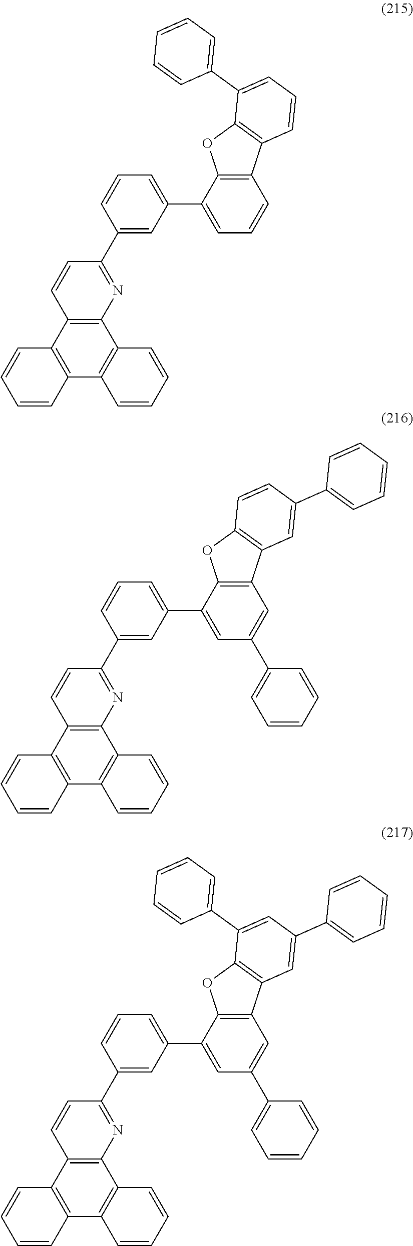

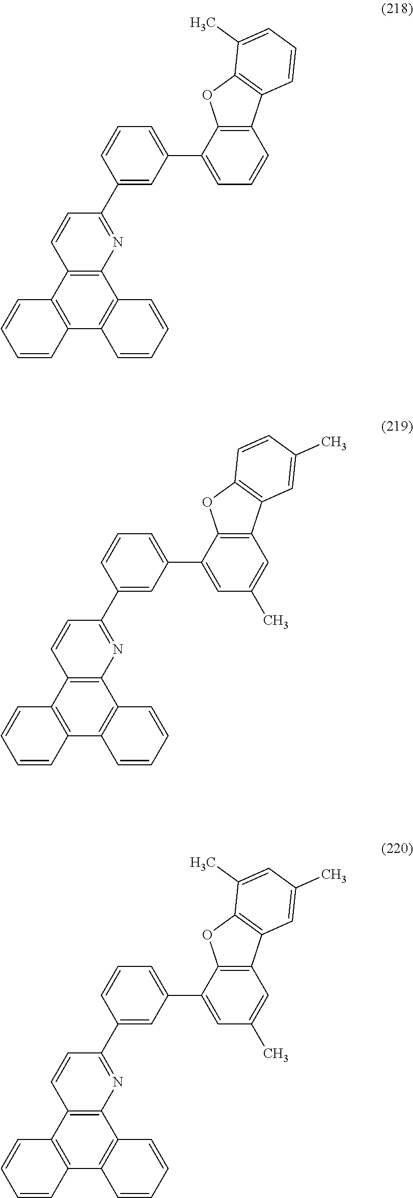

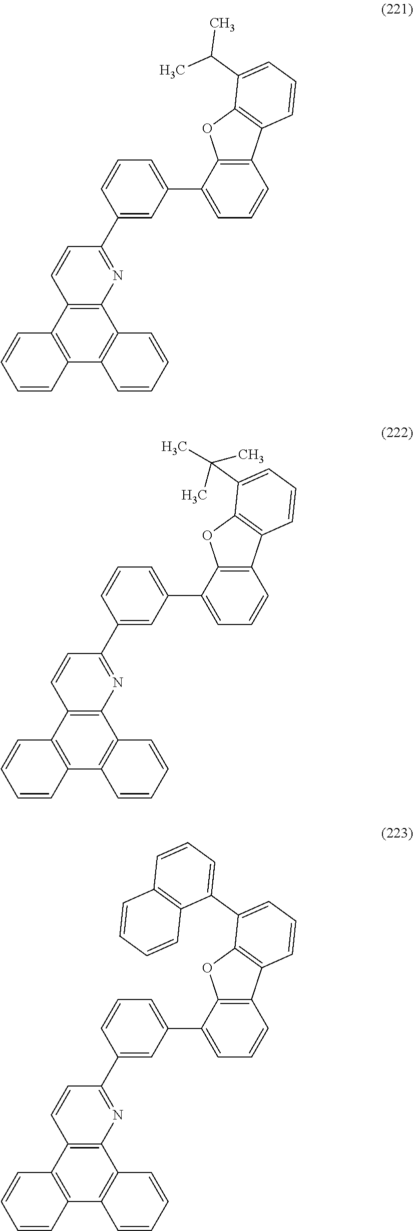

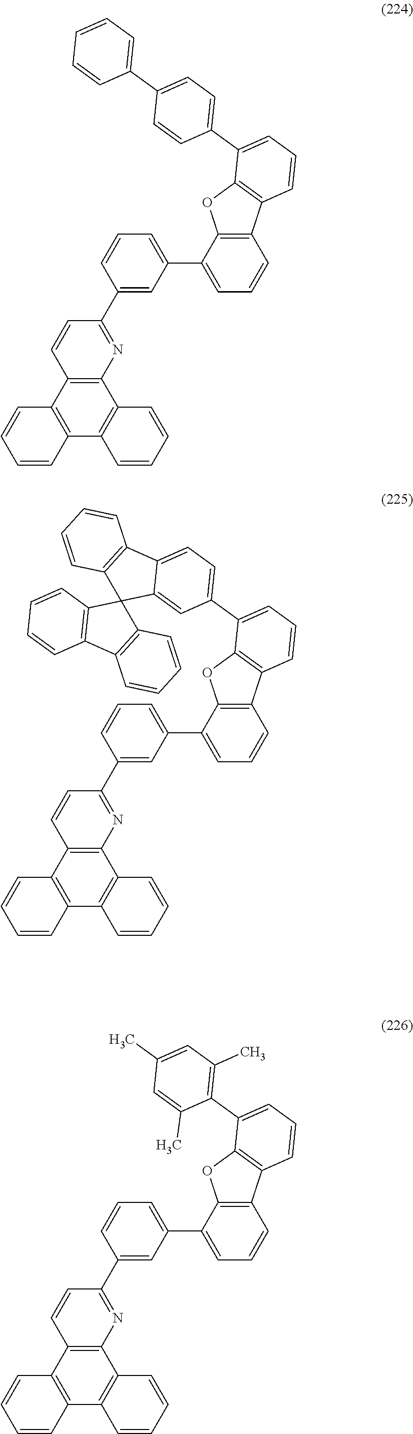

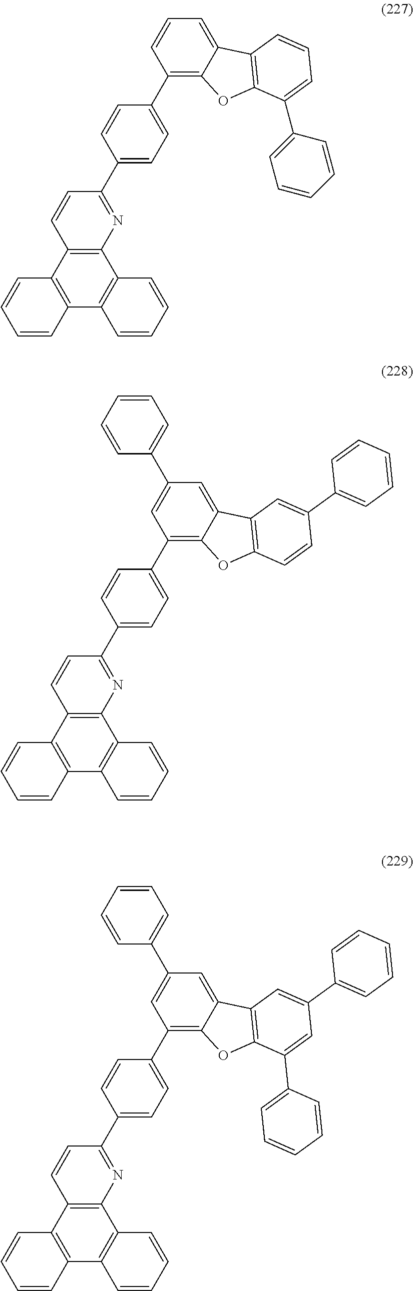

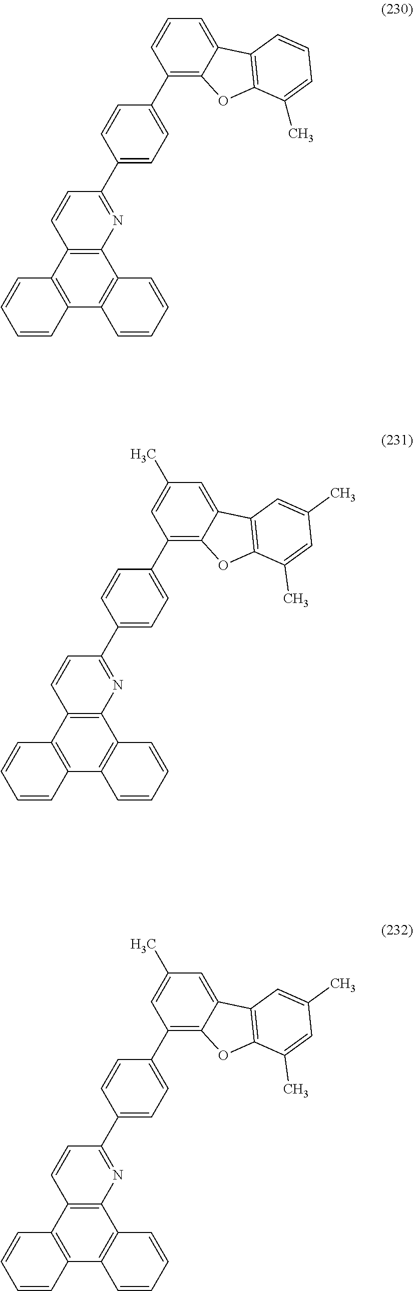

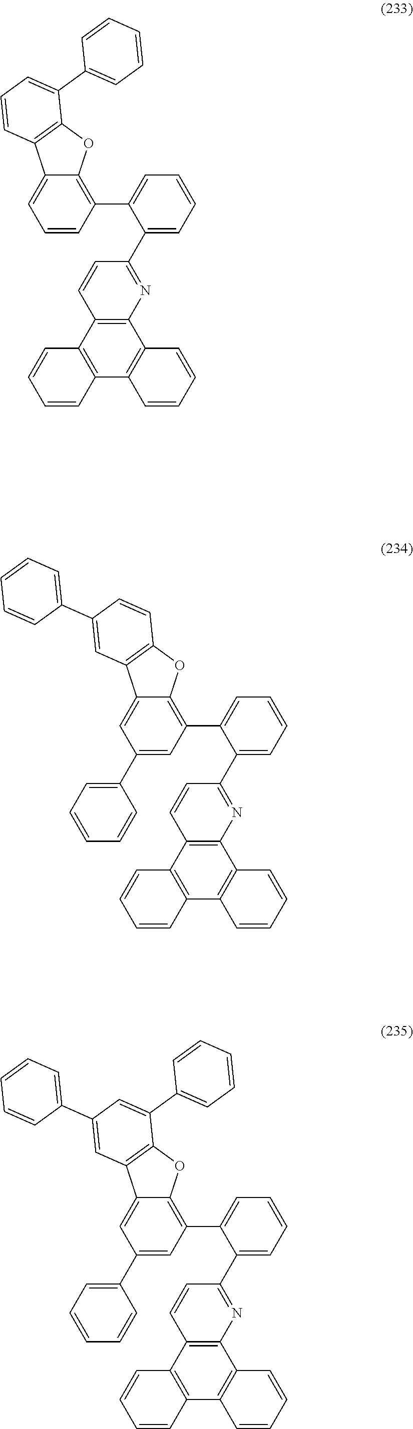

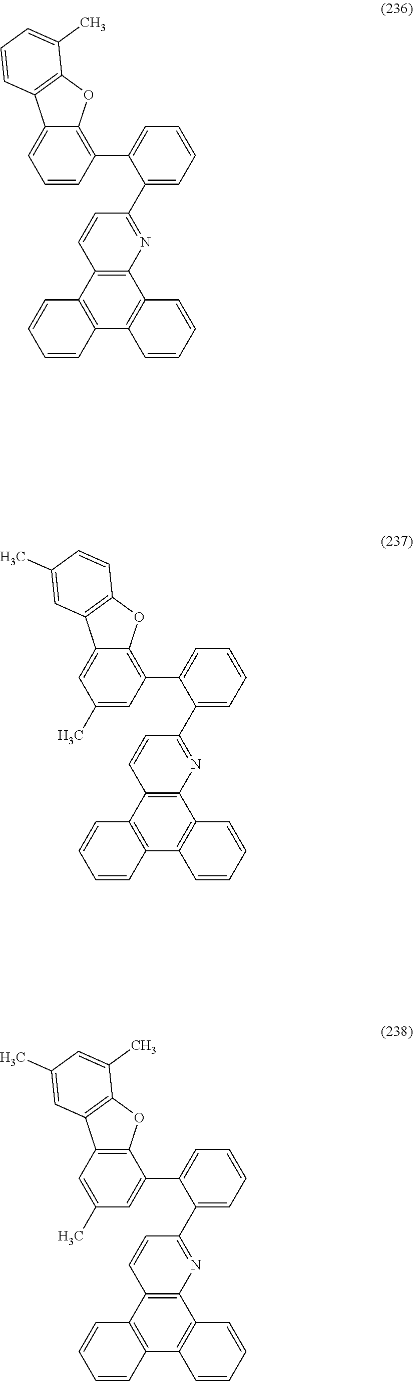

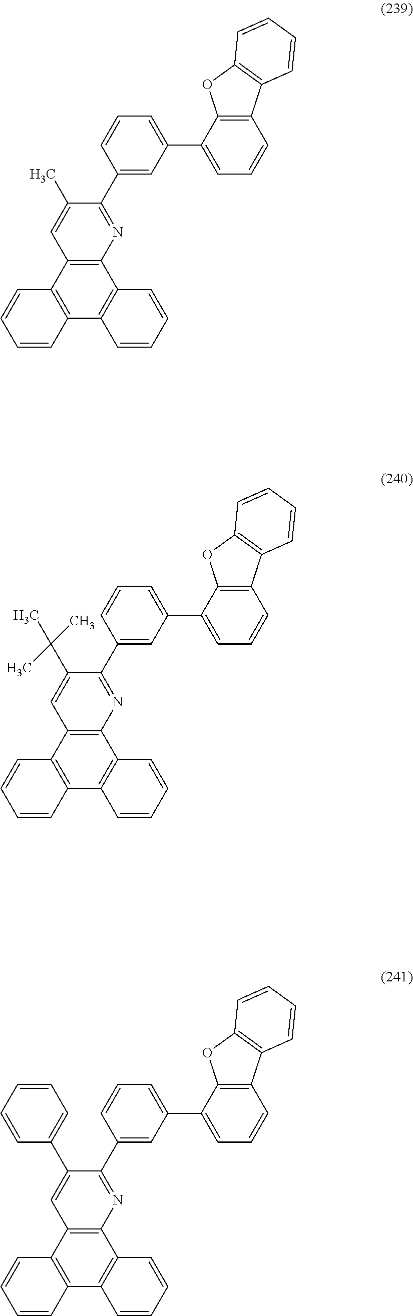

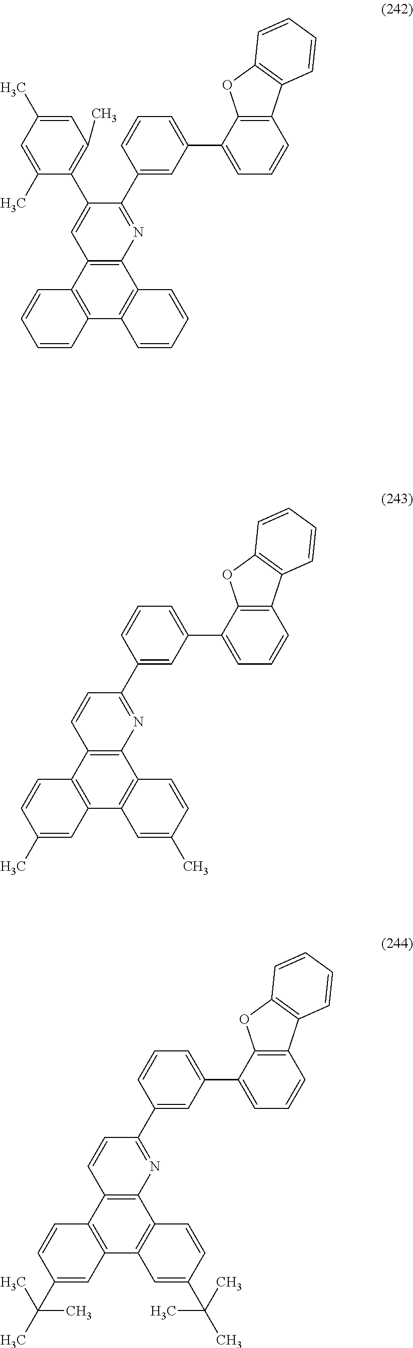

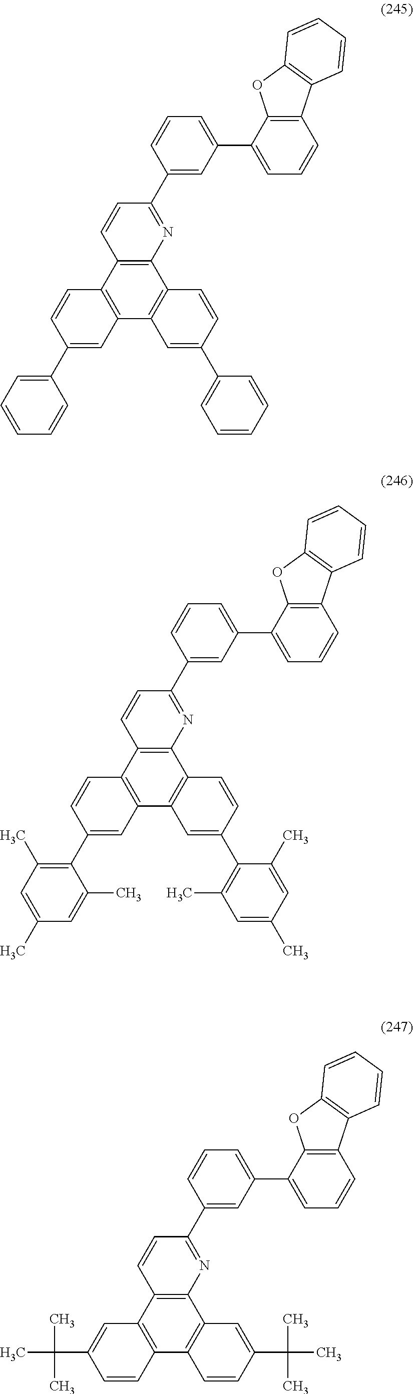

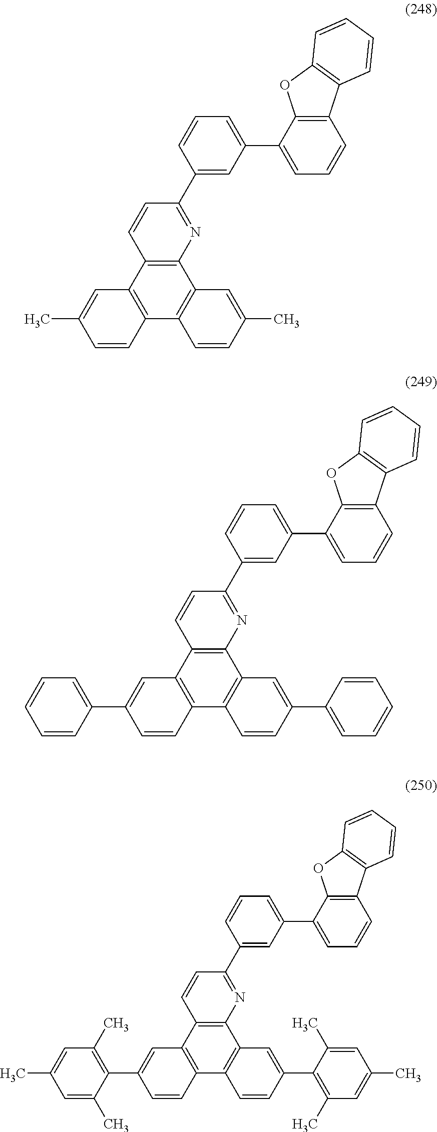

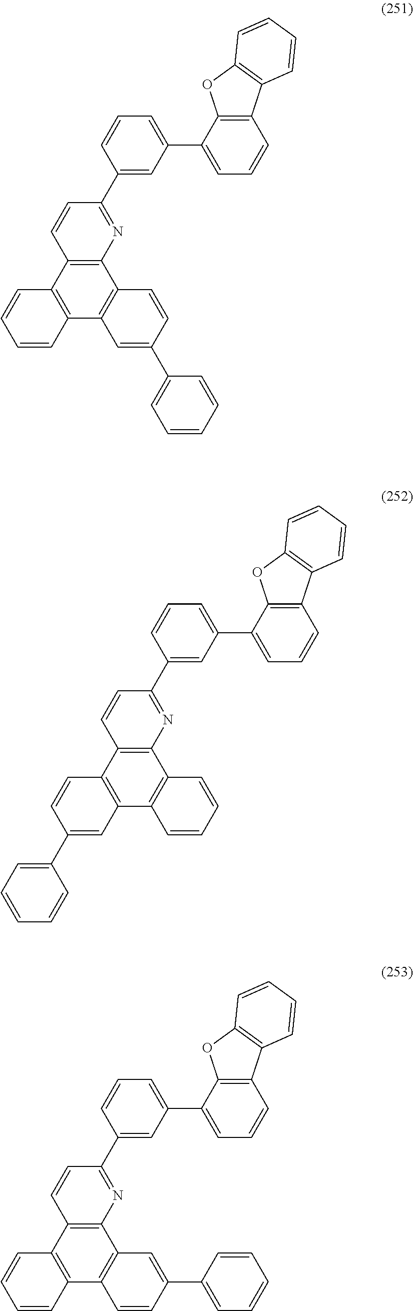

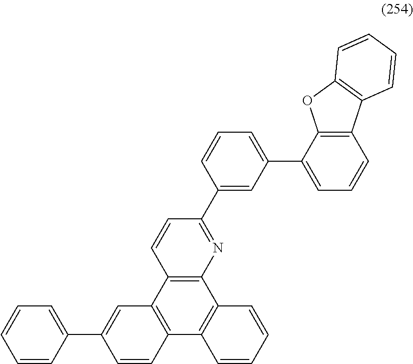

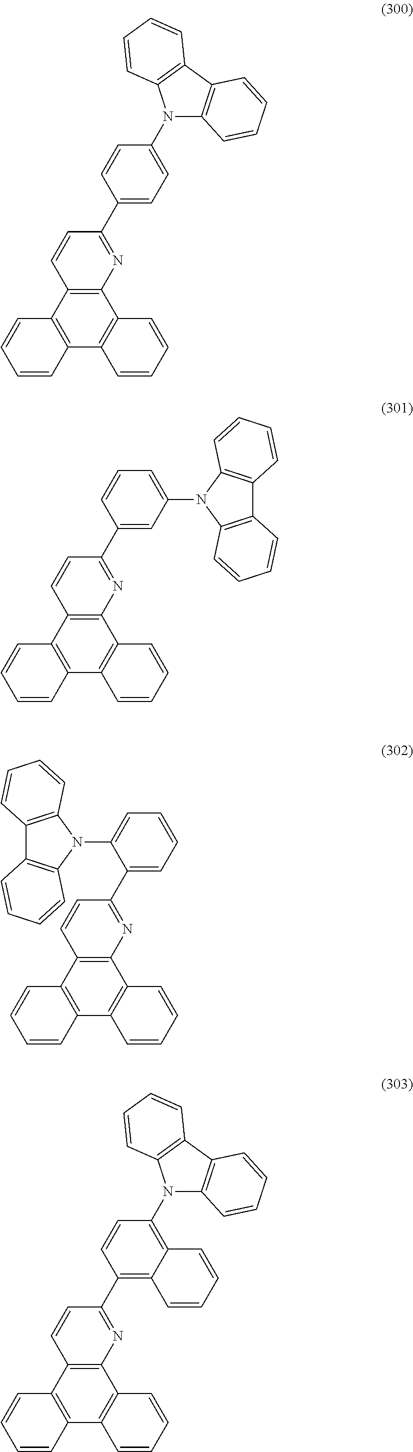

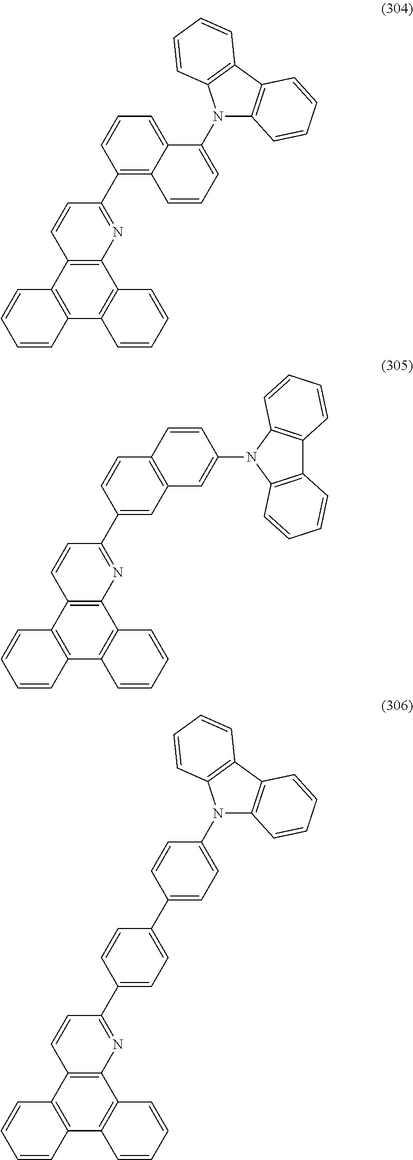

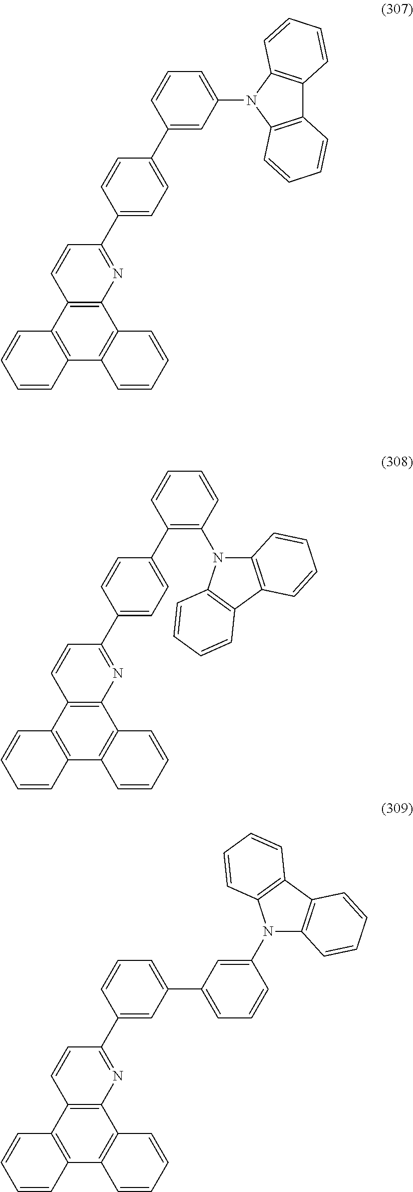

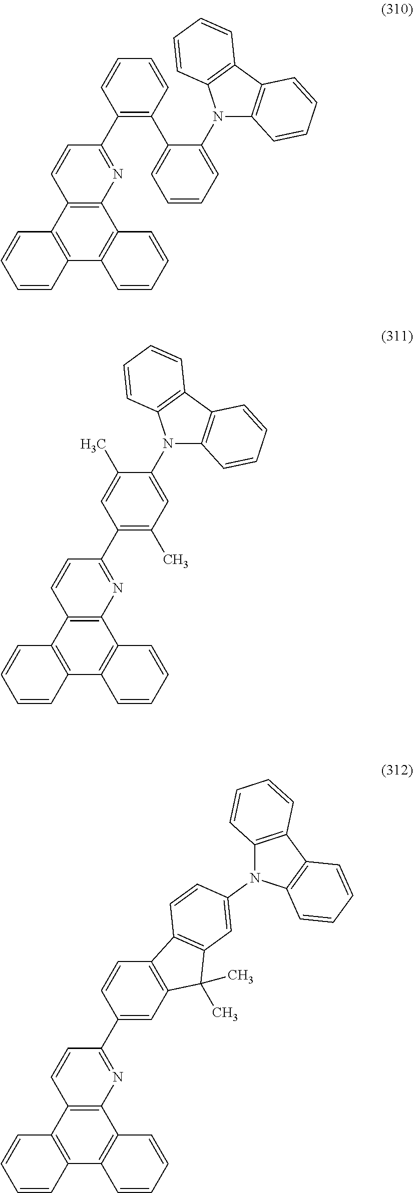

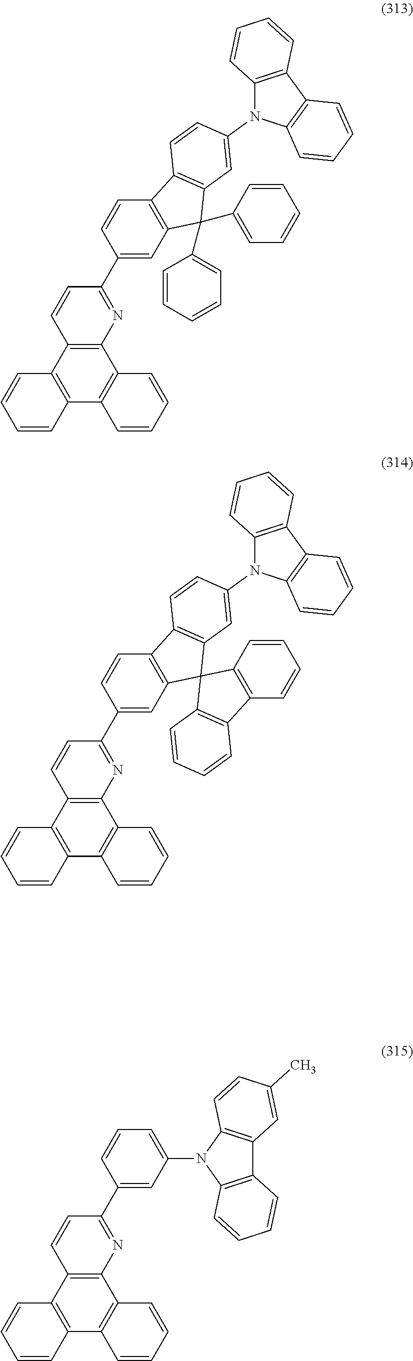

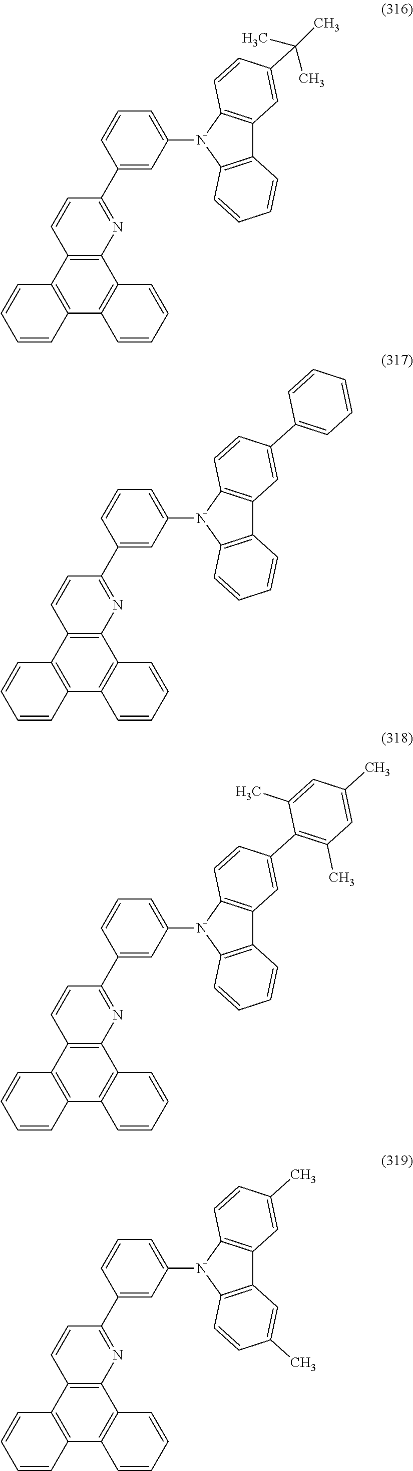

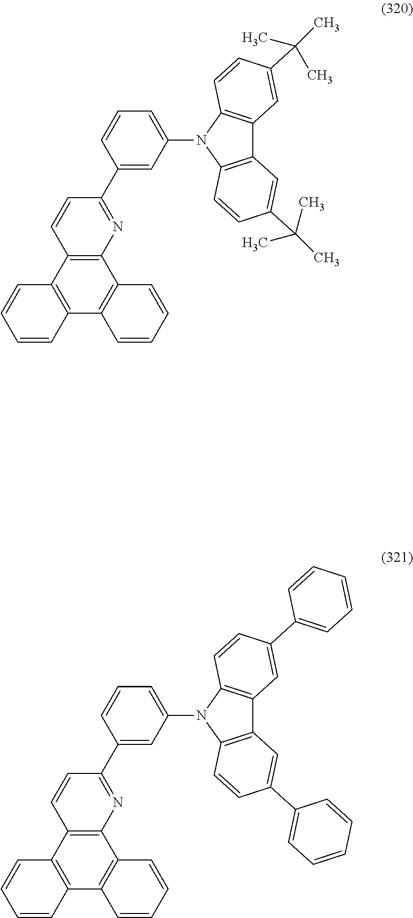

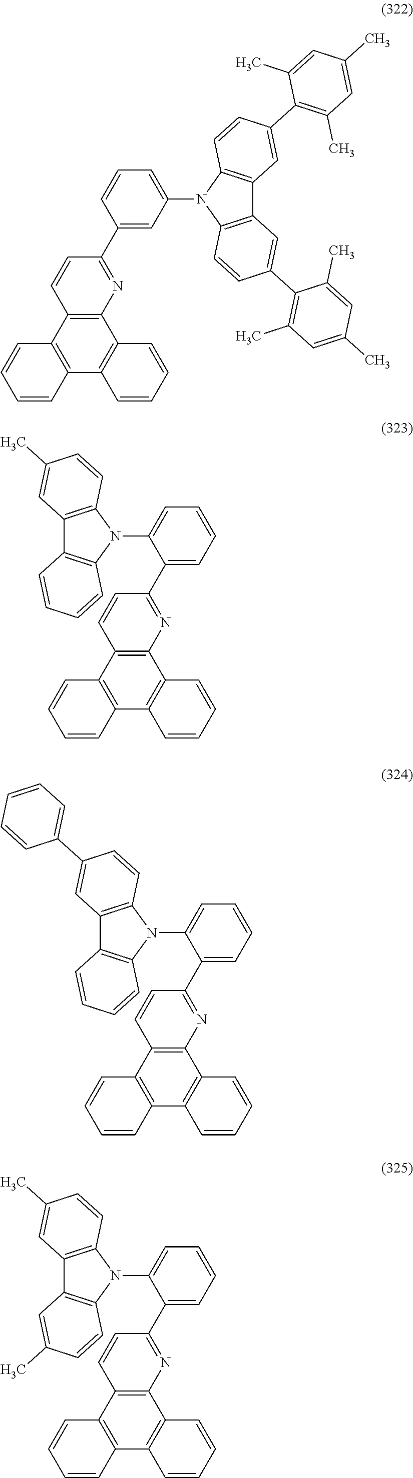

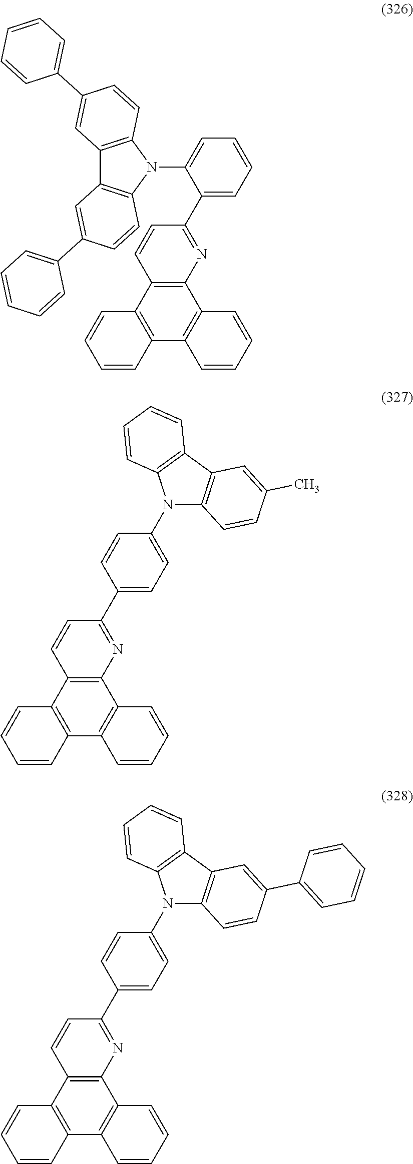

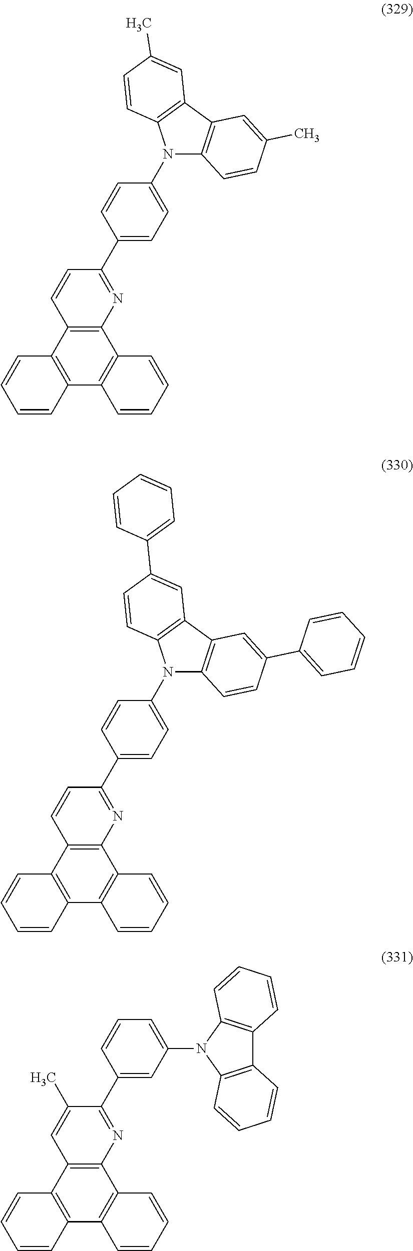

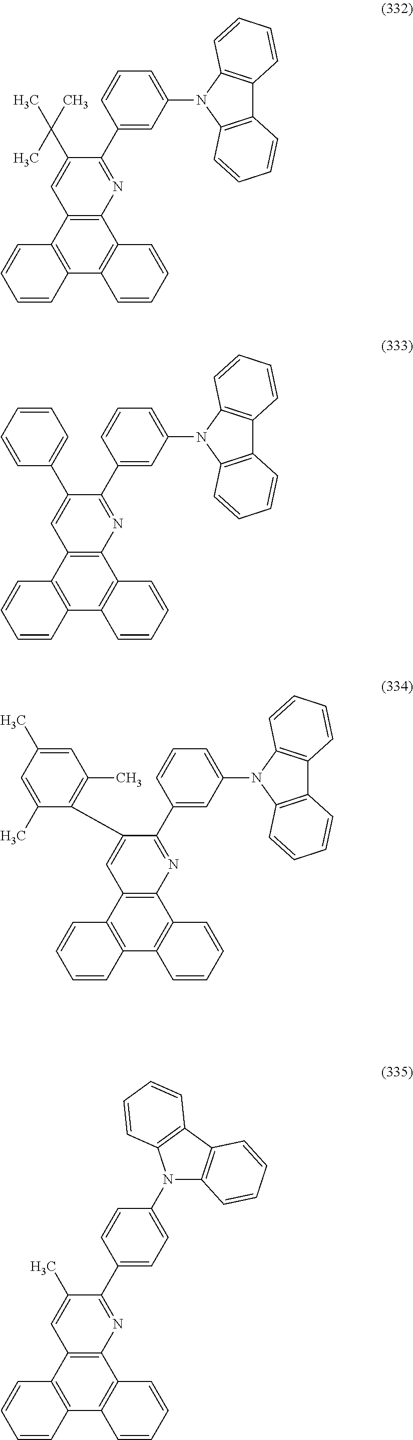

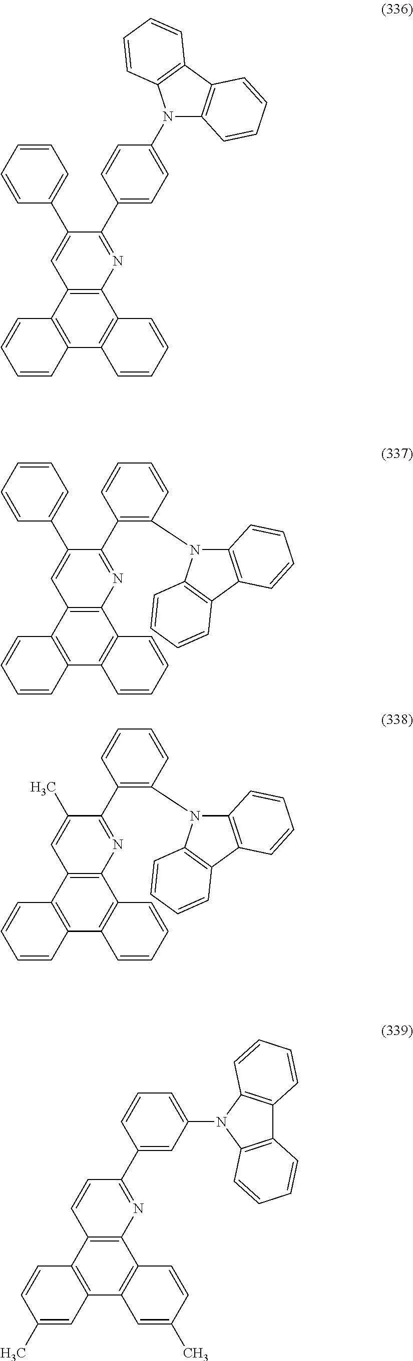

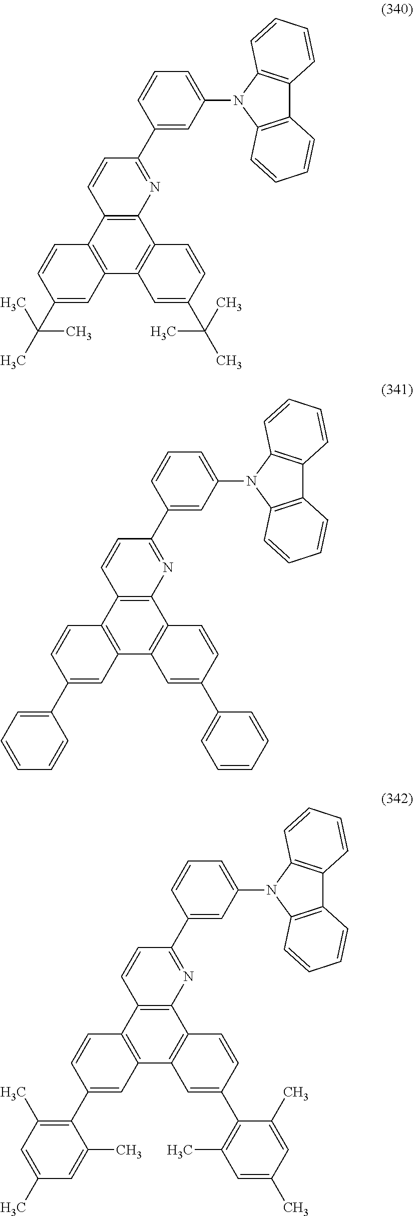

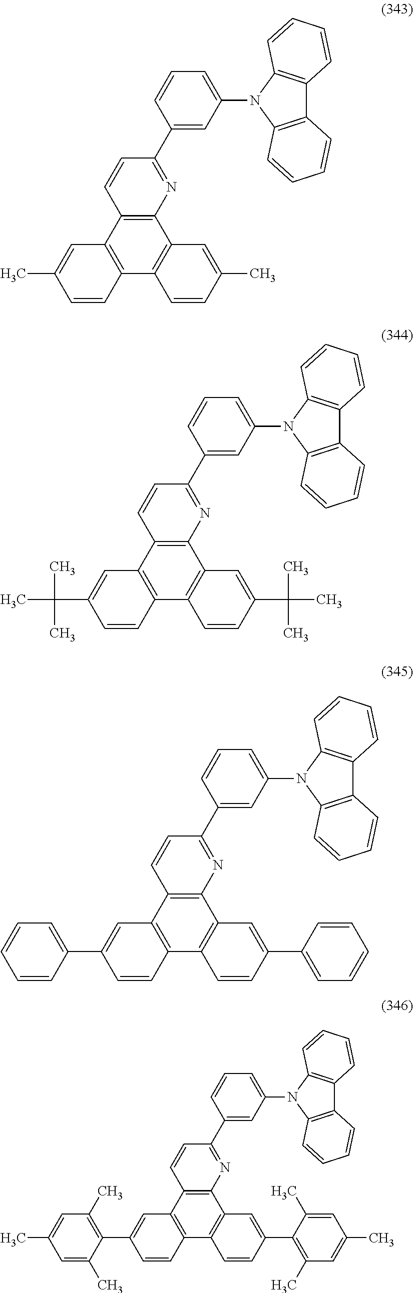

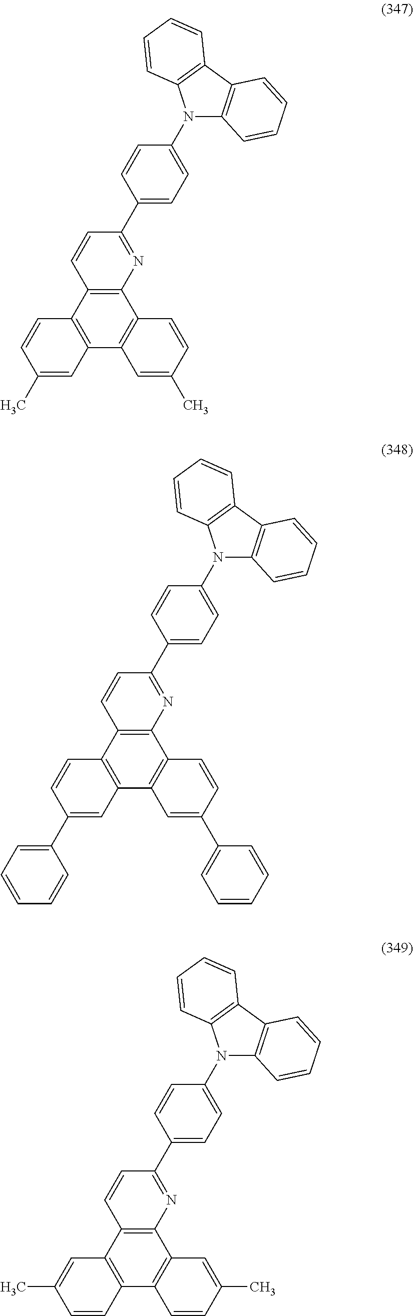

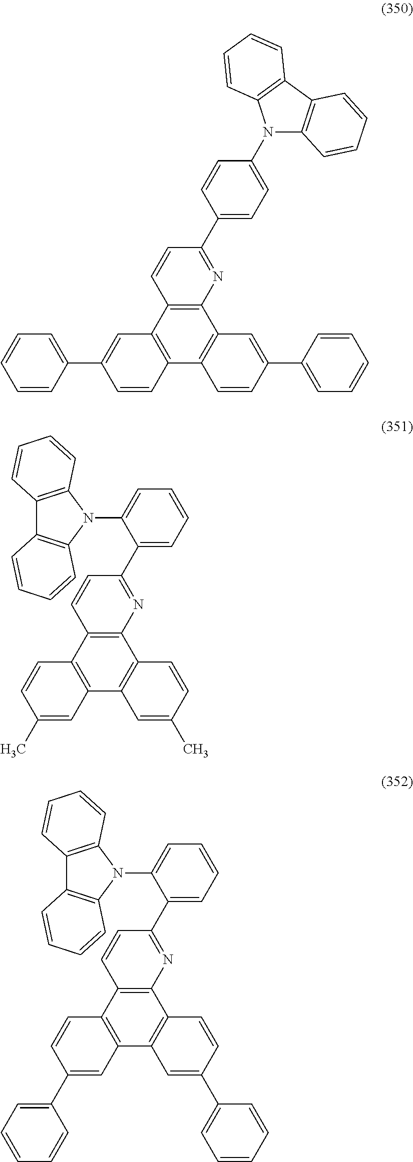

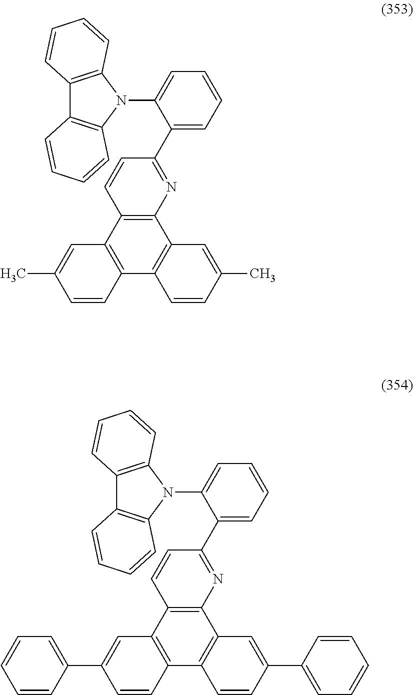

A variety of reactions can be applied to a synthesis method of any of the organic compounds that can be used for a light-emitting element of one embodiment of the present invention. For example, synthesis reactions described below enable the synthesis of the organic compound represented by the general formula (G1). Note that the synthesis method is not limited to those described below.

### <Method 1 of Synthesizing Organic Compound Represented by the General Formula (G1)>

First, a synthesis scheme (A-1) is shown below.

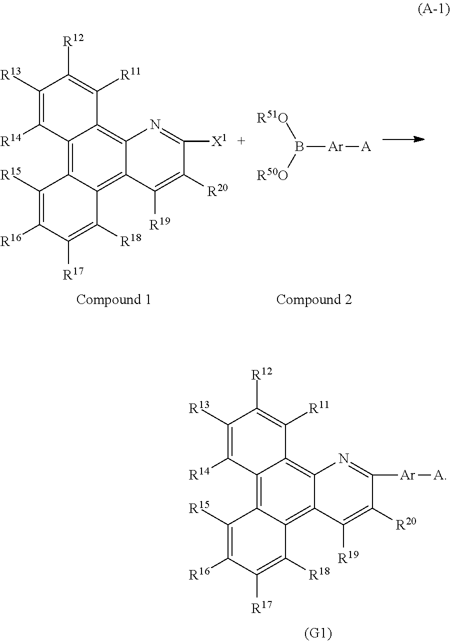

The aforementioned organic compound represented by the general formula (G1) can be synthesized as shown in the synthesis scheme (A-1). Specifically, a halide of a dibenzo[f,h]quinoline derivative (Compound 1) is coupled with an organoboron compound or boronic acid of a carbazole derivative, a dibenzofuran derivative, or a dibenzothiophene derivative (Compound 2) by the Suzuki-Miyaura reaction, whereby the organic compound represented by the general formula (G1) can be obtained.

In the synthesis scheme (A-1), A represents any of a carbazolyl group, a dibenzothiophenyl group, and a dibenzofuranyl group; R¹¹ to R²⁰ separately represent any of hydrogen, an alkyl group having 1 to 4 carbon atoms, and a substituted or unsubstituted aryl group having 6 to 13 carbon atoms; and R⁵⁰ and R⁵¹ separately represent either hydrogen or an alkyl group having 1 to 6 carbon atoms. In the synthesis scheme (A-1), R⁵⁰ and R⁵¹ may be bonded to each other to form a ring. Further, X¹ represents a halogen.

Examples of the palladium catalyst that can be used in the synthesis scheme (A-1) include, but are not limited to, palladium(II) acetate, tetrakis(triphenylphosphine)palladium(0), and bis(triphenylphosphine)palladium(II) dichloride.

Examples of ligands of the palladium catalyst that can be used in the synthesis scheme (A-1) include tri(ortho-tolyl)phosphine, triphenylphosphine, and tricyclohexylphosphine. Note that the ligand of the palladium catalyst is not limited to these ligands.

Examples of a base that can be used in the synthesis scheme (A-1) include, but are not limited to, organic bases such as sodium tert-butoxide and inorganic bases such as potassium carbonate and sodium carbonate.

Examples of a solvent that can be used in the synthesis scheme (A-1) include, but not limited to, a mixed solvent of toluene and water; a mixed solvent of toluene, alcohol such as ethanol, and water; a mixed solvent of xylene and water; a mixed solvent of xylene, alcohol such as ethanol, and water; a mixed solvent of benzene and water; a mixed solvent of benzene, alcohol such as ethanol, and water; and a mixed solvent of water and an ether such as ethylene glycol dimethyl ether. Further, a mixed solvent of toluene and water, a mixed solvent of toluene, ethanol, and water, or a mixed solvent of an ether such as ethylene glycol dimethyl ether and water is more preferable.

The Suzuki-Miyaura reaction shown in the synthesis scheme (A-1) may be replaced with a cross coupling reaction using an organoaluminum compound, an organozirconium compound, an organozinc compound, an organotin compound, or the like as well as the organoboron compound or boronic acid represented by Compound 2. However, one embodiment of the present invention is not limited thereto.

Further, in the Suzuki-Miyaura reaction shown in the synthesis scheme (A-1), an organoboron compound or boronic acid of a dibenzo[f,h]quinoline derivative may be coupled with a halide of a carbazole derivative, a halide of a dibenzofuran derivative, a halide of a dibenzothiophene derivative, a carbazole derivative having a triflate group as a substituent, a dibenzofuran derivative having a triflate group as a substituent, or a dibenzothiophene derivative having a triflate group as a substituent.

In the above manner, the organic compound represented by the general formula (G1) can be synthesized.

### <Method 2 of Synthesizing Organic Compound Represented by the General Formula (G1)>

Another method of synthesizing the organic compound represented by the general formula (G1) is described below. First, a synthesis scheme (B-1) in which a boron compound of A is used as a material is shown below.

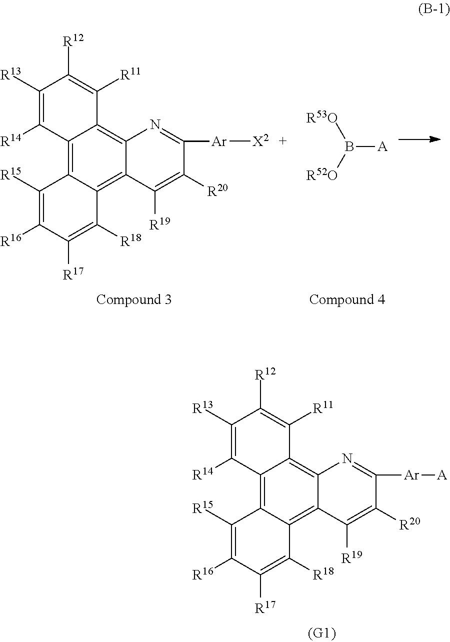

As shown in the synthesis scheme (B-1), a halide of a dibenzo[f,h]quinoline derivative (Compound 3) is coupled with boronic acid or an organoboron compound of a carbazole derivative, a dibenzofuran derivative, or a dibenzothiophene derivative (Compound 4) by the Suzuki-Miyaura reaction, whereby the organic compound represented by the general formula (G1) can be obtained.

In the synthesis scheme (B-1), A represents any of a carbazolyl group, a dibenzothiophenyl group, and a dibenzofuranyl group; and R¹¹ to R²⁰ separately represent any of hydrogen, an alkyl group having 1 to 4 carbon atoms, and a substituted or unsubstituted aryl group having 6 to 13 carbon atoms. In addition, Ar represents an arylene group having 6 to 13 carbon atoms. The arylene group may have one or more substituents that may be bonded to each other to form a ring. Further, R⁵² and R⁵³ separately represent hydrogen or an alkyl group having 1 to 6 carbon atoms. In the synthesis scheme (B-1), R⁵² and R⁵³ may be bonded to each other to form a ring. Further, X² represents a halogen or a triflate group, and the halogen is preferably iodine or bromine.

Examples of a palladium catalyst which can be used in the synthesis scheme (B-1) include, but are not limited to, palladium(II) acetate, tetrakis(triphenylphosphine)palladium(0), and bis(triphenylphosphine)palladium(II) dichloride.

Examples of a ligand of the palladium catalyst that can be used in the synthesis scheme (B-1) include, but are not limited to, tri(ortho-tolyl)phosphine, triphenylphosphine, and tricyclohexylphosphine.

Examples of a base that can be used in the synthesis scheme (B-1) include, but are not limited to, organic bases such as sodium tert-butoxide and inorganic bases such as potassium carbonate and sodium carbonate.

Examples of a solvent that can be used in the synthesis scheme (B-1) include, but are not limited to, a mixed solvent of toluene and water; a mixed solvent of toluene, alcohol such as ethanol, and water; a mixed solvent of xylene and water; a mixed solvent of xylene, alcohol such as ethanol, and water; a mixed solvent of benzene and water; a mixed solvent of benzene, alcohol such as ethanol, and water; and a mixed solvent of water and an ether such as ethylene glycol dimethyl ether. Further, a mixed solvent of toluene and water, a mixed solvent of toluene, ethanol, and water, or a mixed solvent of an ether such as ethylene glycol dimethyl ether and water is more preferable.

The Suzuki-Miyaura reaction shown in the synthesis scheme (B-1) may be replaced with a cross coupling reaction using an organoaluminum compound, an organozirconium compound, an organozinc compound, an organotin compound, or the like as well as the organoboron compound or boronic acid represented by Compound 4. However, one embodiment of the present invention is not limited thereto. Further, in this coupling, a triflate group or the like may be used other than a halogen; however, the present invention is not limited thereto.

Further, in the Suzuki-Miyaura reaction shown in the synthesis scheme (B-1), boronic acid or an organoboron compound of a dibenzo[f,h]quinoline derivative may be coupled with a halide of a carbazole derivative, a halide of a dibenzofuran derivative, a halide of a dibenzothiophene derivative, a carbazole derivative having a triflate group as a substituent, a dibenzofuran derivative having a triflate group as a substituent, or a dibenzothiophene derivative having a triflate group as a substituent.

In the synthesis scheme (B-1), when A is an N-carbazolyl derivative, the following synthesis scheme (B-2) allows the organic compound represented by the general formula (G2-2) to be obtained.

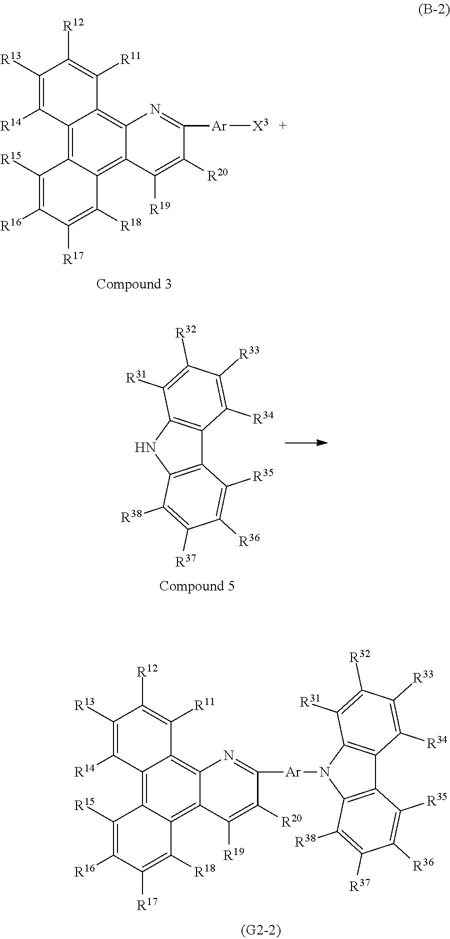

As shown in the synthesis scheme (B-2), the halide of a dibenzo[f,h]quinoline derivative (Compound 3) is coupled with a 9H-carbazole derivative (Compound 5) by using a metal catalyst, metal, or a metal compound in the presence of a base, whereby the heterocyclic compound (G2-2) described in this embodiment can be obtained.

In the synthesis scheme (B-2), R¹¹ to R²⁰ separately represent any of hydrogen, an alkyl group having 1 to 4 carbon atoms, and a substituted or unsubstituted aryl group having 6 to 13 carbon atoms. In addition, Ar represents an arylene group having 6 to 13 carbon atoms. The arylene group may have one or more substituents that may be bonded to each other to form a ring. In addition, R³¹ to R³⁸ separately represent any of hydrogen, an alkyl group having 1 to 4 carbon atoms, and a substituted or unsubstituted aryl group having 6 to 13 carbon atoms. In addition, X³ represents a halogen or a triflate group, and the halogen is preferably iodine or bromine.

Examples of a palladium catalyst that can be used in the case where the Buchwald-Hartwig reaction is performed in the synthesis scheme (B-2) includes bis(dibenzylideneacetone)palladium(0) and palladium(II) acetate.

Examples of a ligand of the palladium catalyst that can be used in the synthesis scheme (B-2) include tri(tert-butyl)phosphine, tri(n-hexyl)phosphine, and tricyclohexylphosphine.

Examples of a base that can be used in the synthesis scheme (B-2) include organic bases such as sodium tert-butoxide and inorganic bases such as potassium carbonate.

Examples of a solvent that can be used in the synthesis scheme (B-2) include toluene, xylene, benzene, and tetrahydrofuran.

Other than the Buchwald-Hartwig reaction, the Ullmann reaction or the like may be used, and the reaction that can be used is not limited to these reactions.

In the above manner, the organic compound that can be used as a mode of this embodiment can be synthesized.

Note that each of the above organic compounds has a high T₁ level and thus also has a high S₁ level. Thus, any of the above organic compounds can also be used as a host material for a material emitting fluorescence.

As examples of the guest material (the second organic compound), a phosphorescent material and a material emitting thermally activated delayed fluorescence (TADF) can be given.

As the phosphorescent material, for example, a phosphorescent material having an emission peak at 440 nm to 520 nm is given, examples of which include organometallic iridium complexes having 4H-triazole skeletons, such as tris{2-[5-(2-methylphenyl)-4-(2,6-dimethylphenyl)-4H-1,2,4-triazol-3-yl-κN2]phenyl-κC}iridium(III) (abbreviation: Ir(mpptz-dmp)₃), tris(5-methyl-3,4-diphenyl-4H-1,2,4-triazolato)iridium(III) (abbreviation: [Ir(Mptz)₃]), and tris[4-(3-biphenylyl)-5-isopropyl-3-phenyl-4H-1,2,4-triazolato]iridium(III) (abbreviation: Ir(iPrptz-3b)₃); organometallic iridium complexes having 1H-triazole skeletons, such as tris[3-methyl-1-(2-methylphenyl)-5-phenyl-1H-1,2,4-triazolato]iridium(III) (abbreviation: [Ir(Mptzl-mp)₃]) and tris(1-methyl-5-phenyl-3-propyl-1H-1,2,4-triazolato)iridium(III) (abbreviation: Ir(Prptzl-Me)₃); organometallic iridium complexes having imidazole skeletons, such as fac-tris[1-(2,6-diisopropylphenyl)-2-phenyl-1H-imidazole]iridium(III) (abbreviation: Ir(iPrpmi)₃) and tris[3-(2,6-dimethylphenyl)-7-methylimidazo[1,2-f]phenanthridinato]iridium(III) (abbreviation: Ir(dmpimpt-Me)₃); and organometallic iridium complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: Flrpic), bis{2-[3′,5′-bis(trifluoromethyl)phenyl]pyridinato-N,C^{2′}}iridium(III) picolinate (abbreviation: Ir(CF₃ppy)₂(pic)), and bis[2-(4′,6′-difluorophenyl)pyridinato-N,C^{2′}]iridium(III)acetylacetonate (abbreviation: FIracac). Among the materials given above, the organometallic iridium complexes having 4H-triazole skeletons have high reliability and high emission efficiency and are thus especially preferable.

Examples of the phosphorescent material having an emission peak at 520 nm to 600 nm include organometallic iridium complexes having pyrimidine skeletons, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[4-(2-norbornyl)-6-phenylpyrimidinato]iridium(III) (endo- and exo-mixture) (abbreviation: [Ir(nbppm)₂(acac)]), (acetylacetonato)bis[5-methyl-6-(2-methylphenyl)-4-phenylpyrimidinato] (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having pyrazine skeletons, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having pyridine skeletons, such as tris(2-phenylpyridinato-N,C^{2′})iridium(III) (abbreviation: [Ir(ppy)₃]), bis(2-phenylpyridinato-N,C^{2′})iridium(III)acetylacetonate (abbreviation: [Ir(ppy)₂(acac)]), bis(benzo[h]quinolinato)iridium(III)acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), and bis(2-phenylquinolinato-N,C^{2′})iridium(III)acetylacetonate (abbreviation: [Ir(pq)₂(acac)]); and a rare earth metal complex such as tris(acetylacetonato) (monophenanthroline)terbium(III) (abbreviation: [Tb(acac)₃(Phen)]). Among the materials given above, the organometallic iridium complexes having pyrimidine skeletons are particularly preferable because of their distinctively high reliability and emission efficiency.

Examples of the phosphorescent material having an emission peak at 600 nm to 700 nm include organometallic iridium complexes having pyrimidine skeletons, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having pyrazine skeletons, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having pyridine skeletons, such as tris(1-phenylisoquinolinato-N,C^{2′})iridium(Ill) (abbreviation: [Ir(piq)₃]) and bis(1-phenylisoquinolinato-N,C^{2′})iridium(III)acetylacetonate (abbreviation: [Ir(piq)₂(acac)]); a platinum complex such as 2,3,7,8,12,13,17,18-octaethyl-21H,23H-porphyrin platinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). Among the materials given above, the organometallic iridium complexes having pyrimidine skeletons have distinctively high reliability and emission efficiency and are thus especially preferable. Furthermore, the organometallic iridium complexes having pyrazine skeletons can provide red light emission with favorable chromaticity.

In the case of using an assist material (the third organic compound) in the light-emitting layer, the aforementioned substances with a high hole-transport property that can be used for the hole-injection layer 111 and the hole-transport layer 112 may be used.

Specifically, a compound having a carbazole skeleton is preferably used as the assist material (the third organic compound) owing to its high reliability, high hole-transport property, and contribution to a reduction in driving voltage.

It is preferable that each of the host material (the first organic compound) and the assist material (the third organic compound) do not have its absorption spectrum in the blue wavelength range. Specifically, an absorption edge of the absorption spectrum is preferably at 440 nm or less.

The electron-transport layer 114 is a layer containing a substance with a high electron-transport property. For the electron-transport layer 114, a metal complex such as tris(8-quinolinolato)aluminum (abbreviation: Alq₃), tris(4-methyl-8-quinolinolato)aluminum (abbreviation: Almq₃), bis(10-hydroxybenzo[h]quinolinato)beryllium(II) (abbreviation: BeBq₂), BAlq, Zn(BOX)₂, or bis[2-(2-hydroxyphenyl)benzothiazolato]zinc(II) (abbreviation: Zn(BTZ)₂) can be used. Further, a heteroaromatic compound such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), or 4,4′-bis(5-methylbenzoxazol-2-yl)stilbene (abbreviation: BzOs) can be used. Further, a high molecular compound such as poly(2,5-pyridinediyl) (abbreviation: PPy), poly[(9,9-dihexylfluorene-2,7-diyl)-co-(pyridine-3,5-diyl)] (abbreviation: PF-Py) or poly[(9,9-dioctylfluorene-2,7-diyl)-co-(2,2′-bipyridine-6,6′-diyl)] (abbreviation: PF-BPy) can be used. The substances given here are mainly substances having an electron mobility of 10⁻⁶ cm²/Vs or more. Note that other than these substances, any substance that has an electron-transport property higher than a hole-transport property may be used for the electron-transport layer 114.

The electron-transport layer 114 is not limited to a single layer buy may be a stack including two or more layers containing any of the above substances.

It is also possible to use, for the electron-transport layer 114, the organic compound represented by any of the general formulae (G0), (G1), (G2-1), (G2-2), (G3-1), and (G3-2).

The electron-injection layer 115 is a layer containing a substance with a high electron-injection property. For the electron-injection layer 115, a compound of an alkali metal or an alkaline earth metal, such as lithium fluoride (LiF), cesium fluoride (CsF), calcium fluoride (CaF₂), or lithium oxide (LiOₓ), can be used. A compound of a rare earth metal, such as erbium fluoride (ErF₃), can also be used. Any of the above substances for forming the electron-transport layer 114 can also be used.

A composite material in which an organic compound and an electron donor (donor) are mixed may also be used for the electron-injection layer 115. Such a composite material is excellent in an electron-injection property and an electron-transport property because electrons are generated in the organic compound by the electron donor. In this case, the organic compound is preferably a material which is excellent in transporting the generated electrons. Specifically, for example, any of the above substances for Ruining the electron-transport layer 114 (e.g., a metal complex or a heteroaromatic compound) can be used. As the electron donor, a substance exhibiting an electron-donating property with respect to the organic compound may be used. Specifically, an alkali metal, an alkaline earth metal, and a rare earth metal are preferable, and for example, lithium, cesium, magnesium, calcium, erbium, ytterbium, and the like are given. Further, an alkali metal oxide or an alkaline earth metal oxide is preferable, and for example, lithium oxide, calcium oxide, barium oxide, and the like are given. A Lewis base such as magnesium oxide can also be used. An organic compound such as tetrathiafulvalene (abbreviation: TTF) can also be used.

Note that each of the above hole-injection layer 111, hole-transport layer 112, light-emitting layer 113, electron-transport layer 114, and electron-injection layer 115, can be formed by a method such as an evaporation method (e.g., a vacuum evaporation method), an inkjet method, or a coating method.

In the above light-emitting element, current flows due to a potential difference between the first electrode 101 and the second electrode 103 and holes and electrons recombine in the EL layer 102, whereby light is emitted. Then, the emitted light is extracted outside through one or both of the first electrode 101 and the second electrode 103. Thus, one or both of the first electrode 101 and the second electrode 103 are electrodes having a light-transmitting property.

Next, the light-emitting elements illustrated in FIGS. 1B and 1C are described.

The light-emitting element illustrated in FIG. 1B is a tandem light-emitting element including a plurality of light-emitting layers (a first light-emitting layer 311 and a second light-emitting layer 312) between a first electrode 301 and a second electrode 303.

The first electrode 301 functions as an anode, and the second electrode 303 functions as a cathode. Note that the first electrode 301 and the second electrode 303 can have structures similar to those of the first electrode 101 and the second electrode 103.

The plurality of light-emitting layers (the first light-emitting layer 311 and the second light-emitting layer 312) can have a structure similar to that of the light-emitting layer 113. Note that the structures of the first light-emitting layer 311 and the second light-emitting layer 312 may be the same or different from each other as long as at least one of the first light-emitting layer 311 and the second light-emitting layer 312 has a structure similar to that of the light-emitting layer 113. In addition to the first light-emitting layer 311 and the second light-emitting layer 312, the hole-injection layer 111, the hole-transport layer 112, the electron-transport layer 114, and the electron-injection layer 115 which are described above may be provided as appropriate.

A charge-generation layer 313 is provided between the plurality of light-emitting layers (the first light-emitting layer 311 and the second light-emitting layer 312). The charge-generation layer 313 has a function of injecting electrons into one of the light-emitting layers and injecting holes into the other of the light-emitting layers when voltage is applied between the first electrode 301 and the second electrode 303. In this embodiment, when voltage is applied such that the potential of the first electrode 301 is higher than that of the second electrode 303, the charge-generation layer 313 injects electrons into the first light-emitting layer 311 and injects holes into the second light-emitting layer 312.

Note that in terms of light extraction efficiency, the charge-generation layer 313 preferably has a property of transmitting visible light (specifically, the charge-generation layer 313 has a visible light transmittance of 40% or higher). Further, the charge-generation layer 313 functions even when it has conductivity lower than that of the first electrode 301 or the second electrode 303.

The charge-generation layer 313 may have either a structure in which an electron acceptor (acceptor) is added to an organic compound having a high hole-transport property or a structure in which an electron donor (donor) is added to an organic compound having a high electron-transport property. Alternatively, both of these structures may be stacked.

In the case where the electron acceptor is added to the organic compound having a high hole-transport property, examples of the organic compound having a high hole-transport property include aromatic amine compounds such as NPB, TPD, TDATA, MTDATA, and 4,4′-bis[N-(spiro-9,9′-bifluoren-2-yl)-N-phenylamino]biphenyl (abbreviation: BSPB), and the like. The substances given here are mainly substances having a hole mobility of 10⁻⁶ cm²/Vs or more. Note that other than these substances, any organic compound that has a hole-transport property higher than an electron-transport property may be used.

Examples of the electron acceptor include 7,7,8,8-tetracyano-2,3,5,6-tetrafluoroquinodimethane (abbreviation: F₄-TCNQ), chloranil, oxides of transition metals such as oxides of metals that belong to Groups 4 to 8 of the periodic table. Specifically, vanadium oxide, niobium oxide, tantalum oxide, chromium oxide, molybdenum oxide, tungsten oxide, manganese oxide, and rhenium oxide are preferable because of their high electron-accepting properties. Among these, molybdenum oxide is especially preferable since it is stable in the air, has a low hygroscopic property, and is easy to handle.

In the case where the electron donor is added to the organic compound having a high electron-transport property, examples of the organic compound having a high electron-transport property which can be used are metal complexes having a quinoline skeleton or a benzoquinoline skeleton, such as Alq, Almq₃, BeBq₂, and BAlq, and the like. Other examples are metal complexes having an oxazole-based or thiazole-based ligand, such as Zn(BOX)₂ and Zn(BTZ)₂. Other than metal complexes, PBD, OXD-7, TAZ, BPhen, BCP, or the like can be used. The substances given here are mainly substances having an electron mobility of 10⁻⁶ cm²/Vs or more. Note that other than these substances, any organic compound that has an electron-transport property higher than a hole-transport property may be used.

Examples of the electron donor which can be used are alkali metals, alkaline earth metals, rare earth metals, metals that belong to Group 13 of the periodic table, and oxides or carbonates thereof. Specifically, lithium (Li), cesium (Cs), magnesium (Mg), calcium (Ca), ytterbium (Yb), indium (In), lithium oxide, cesium carbonate, or the like is preferably used. An organic compound, such as tetrathianaphthacene, may also be used as the electron donor.

Although the light-emitting element having two light-emitting layers is illustrated in FIG. 1B, the present invention can be similarly applied to a light-emitting element in which n light-emitting layers (n is three or more) are stacked as illustrated in FIG. 1C. In the case where a plurality of light-emitting layers are provided between a pair of electrodes as in the light-emitting element of this embodiment, by providing the charge-generation layer 313 between the light-emitting layers, the light-emitting element can emit light in a high luminance region while the current density is kept low. Since the current density can be kept low, the element can have a long lifetime.

Further, by forming light-emitting layers to emit light of different colors, a light-emitting element that can provide desired emission color as a whole can be obtained. For example, by forming a light-emitting element having two light-emitting layers such that the emission color of the first light-emitting layer and the emission color of the second light-emitting layer are complementary colors, the light-emitting element can provide white light emission as a whole. Note that the word “complementary” means color relationship in which an achromatic color is obtained when colors are mixed. That is, emission of white light can be obtained by mixture of light emitted from substances whose emission colors are complementary colors.

The same can be applied to a light-emitting element having three light-emitting layers. For example, the light-emitting element as a whole can emit white light when the emission color of the first light-emitting layer is red, the emission color of the second light-emitting layer is green, and the emission color of the third light-emitting layer is blue.

As described above, the light-emitting element in which the light-emitting layer is interposed between the pair of electrodes, which is described in this embodiment, contains an organic compound between the pair of electrodes. The organic compound has a dibenzo[f,h]quinoline ring, an arylene group, and a hole-transport skeleton. In particular, an organic compound in which a dibenzo[f,h]quinoline ring and a hole-transport skeleton are bonded to each other through an arylene group is used. Such an organic compound has a wide energy gap and a high T₁ level. Thus, by using the organic compound as a host material in which a light-emitting substance is dispersed in a light-emitting layer in a light-emitting element, high current efficiency can be obtained. In particular, the organic compound of one embodiment of the present invention is suitably used as a host material in which a phosphorescent compound is dispersed.

When a light-emitting element contains the organic compound in a light-emitting layer, the light-emitting element can be driven at low voltage and can have a long lifetime.

Note that the structure described in this embodiment can be combined as appropriate with any of the structures described in the other embodiments or the example.

### Embodiment 2

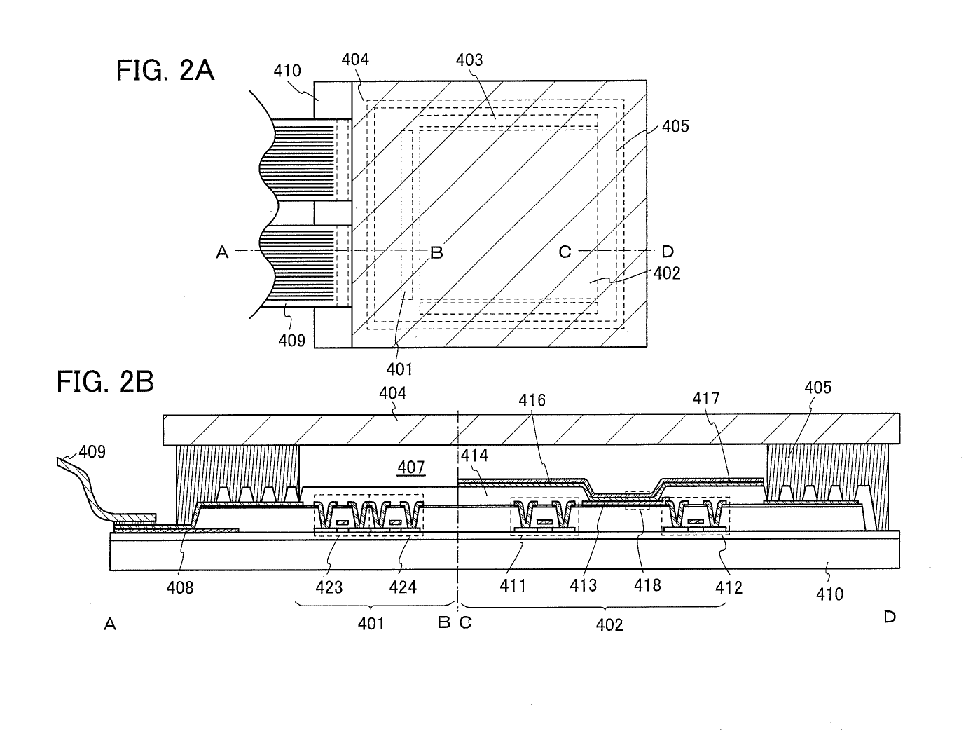

In this embodiment, a light-emitting device which includes the light-emitting element of one embodiment of the present invention will be described with reference to FIGS. 2A and 2B. Note that FIG. 2A is a top view illustrating the light-emitting device, and FIG. 2B is a cross-sectional view taken along the lines A-B and C-D in FIG. 2A.

The light-emitting device of this embodiment includes a source side driver circuit 401 and a gate side driver circuit 403 which are driver circuit portions, a pixel portion 402, a sealing substrate 404, a sealant 405, a flexible printed circuit (FPC) 409, and an element substrate 410. A portion enclosed by the sealant 405 is a space 407.

Note that a lead wiring 408 is a wiring for transmitting signals that are to be input to the source side driver circuit 401 and the gate side driver circuit 403, and receives a video signal, a clock signal, a start signal, a reset signal, and the like from an FPC 409 which serves as an external input terminal. Although only the FPC is illustrated here, a printed wiring board (PWB) may be attached to the FPC. The light-emitting device in this specification includes, in its category, not only the light-emitting device itself but also the light-emitting device provided with the FPC or the PWB.

The driver circuit portion and the pixel portion are formed over the element substrate 410 illustrated in FIG. 2A. In FIG. 2B, the source side driver circuit 401 which is the driver circuit portion and one pixel in the pixel portion 402 are illustrated.

Note that as the source side driver circuit 401, a CMOS circuit in which an n-channel FET 423 and a p-channel FET 424 are combined is formed. The driver circuit may be any of a variety of circuits formed with FETs, such as a CMOS circuit, a PMOS circuit, or an NMOS circuit. Although a driver-integrated type in which a driver circuit is formed over a substrate is described in this embodiment, one embodiment of the present invention is not limited to this type, and the driver circuit can be foamed outside the substrate.

The pixel portion 402 includes a plurality of pixels having a switching FET 411, a current control FET 412, and a first electrode 413 electrically connected to a drain of the current control FET 412. An insulator 414 is formed to cover an end portion of the first electrode 413. Here, the insulator 414 is formed using a positive type photosensitive acrylic resin film.

In order to improve the coverage, the insulator 414 is provided such that either an upper end portion or a lower end portion of the insulator 414 has a curved surface with a curvature. For example, in the case of using a positive photosensitive acrylic as a material for the insulator 414, it is preferable that the insulator 414 be formed so as to have a curved surface with radius of curvature (0.2 μm to 3 μm) only at the upper end portion thereof. The insulator 414 can be formed using either a negative photosensitive resin or a positive photosensitive resin.

An EL layer 416 and a second electrode 417 are formed over the first electrode 413. The first electrode 413, the EL layer 416, and the second electrode 417 can be formed using any of the materials given in Embodiment 1.

The sealing substrate 404 is attached to the element substrate 410 with the sealant 405; thus, a light-emitting element 418 is provided in the space 407 enclosed by the element substrate 410, the sealing substrate 404, and the sealant 405. The space 407 is filled with a filler and may be filled with an inert gas (such as nitrogen or argon) or the sealing material.

Note that as the sealant 405, an epoxy-based resin is preferably used. It is preferable that such a material do not transmit moisture or oxygen as much as possible. As a material for the sealing substrate 404, a glass substrate, a quartz substrate, or a plastic substrate including fiber-reinforced plastics (FRP), polyvinyl fluoride) (PVF), a polyester, an acrylic resin, or the like can be used.

As described above, the active matrix light-emitting device having the light-emitting element of one embodiment of the present invention can be obtained.

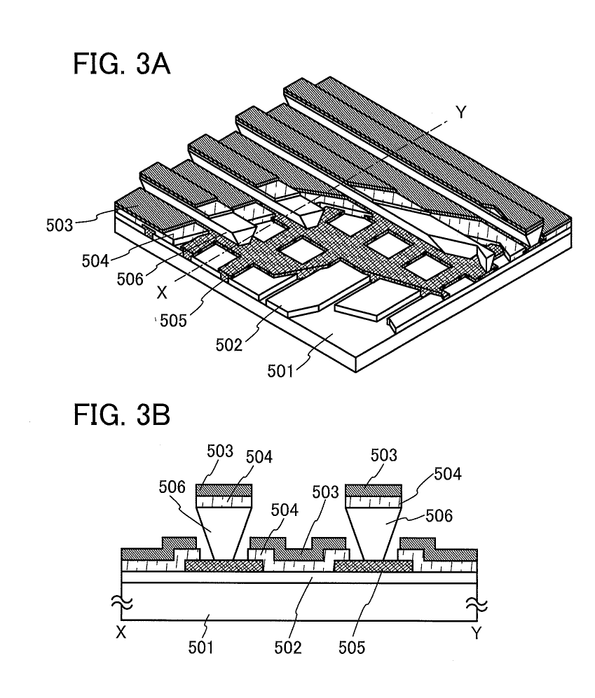

Further, a light-emitting element of one embodiment of the present invention can be used for a passive matrix light-emitting device as well as the above active matrix light-emitting device. FIGS. 3A and 3B illustrate a perspective view and a cross-sectional view of a passive matrix light-emitting device using a light-emitting element of one embodiment of the present invention. FIG. 3B is a cross-sectional view taken along line X-Y in FIG. 3A.

In FIGS. 3A and 3B, an EL layer 504 is provided between a first electrode 502 and a second electrode 503 over a substrate 501. An end portion of the first electrode 502 is covered with an insulating layer 505. In addition, a partition layer 506 is provided over the insulating layer 505. The sidewalls of the partition layer 506 slope so that the distance between one sidewall and the other sidewall gradually decreases toward the surface of the substrate. In other words, a cross section taken along the direction of the short side of the partition layer 506 is trapezoidal, and the lower side (a side in contact with the insulating layer 505) is shorter than the upper side (a side not in contact with the insulating layer 505). With the partition layer 506 provided in such a way, a defect of a light-emitting element due to crosstalk or the like can be prevented.

Thus, the light-emitting device which includes the light-emitting element of one embodiment of the present invention can be obtained.

Note that the light-emitting devices described in this embodiment are both manufactured using the light-emitting element of one embodiment of the present invention, and thus can have low power consumption.

Note that the structure described in this embodiment can be combined as appropriate with any of the structures described in the other embodiments or the example.

### Embodiment 3

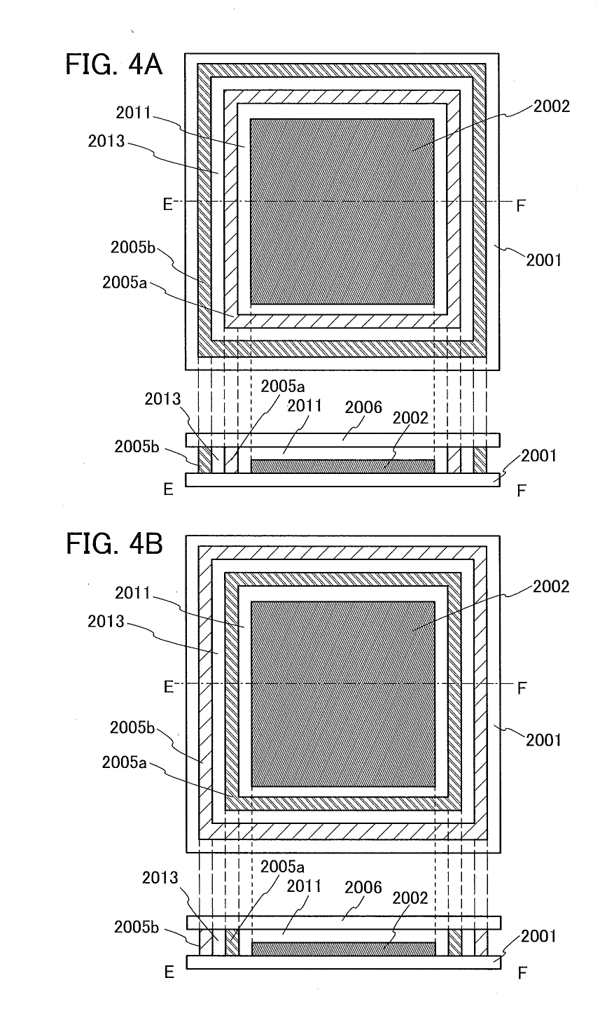

In this embodiment, a light-emitting device manufactured using the light-emitting element of one embodiment of the present invention is described with reference to FIGS. 4A and 4B.

In FIG. 4A, a plan view of a light-emitting device described in this embodiment and a cross-sectional view taken along dashed-dotted line E-F in the plan view are illustrated.

The light-emitting device illustrated in FIG. 4A includes a light-emitting portion 2002 including a light-emitting element over a first substrate 2001. The light-emitting device has a structure in which a first sealant 2005a is provided so as to surround the light-emitting portion 2002 and a second sealant 2005b is provided so as to surround the first sealant 2005a (i.e., a double sealing structure).

Thus, the light-emitting portion 2002 is positioned in a space surrounded by the first substrate 2001, the second substrate 2006, and the first sealant 2005a.

Note that in this specification, the first sealant 2005a and the second sealant 2005b are not necessarily in direct contact with the first substrate 2001 and the second substrate 2006. For example, the first sealant 2005a may be in contact with an insulating film or a conductive film formed over the first substrate 2001.

In the above structure, the first sealant 2005a is a resin layer containing a desiccant and the second sealant 2005b is a glass layer, whereby an effect of suppressing entry of impurities such as moisture and oxygen from the outside (hereinafter, referred to as a sealing property) can be increased.

The first sealant 2005a is the resin layer as described above, whereby the glass layer that is the second sealant 2005b can be prevented from having breaking or cracking (hereinafter, collectively referred to as a crack). Further, in the case where the sealing property of the second sealant 2005b is not sufficient, even when impurities enter a first space 2013, entry of the impurities into a second space 2011 can be suppressed owing to a high sealing property of the first sealant 2005a. Thus, deterioration of an organic compound, a metal material, and the like contained in the light-emitting element by impurities can be suppressed.

In addition, the structure illustrated in FIG. 4B can be employed: the first sealant 2005a is a glass layer and the second sealant 2005b is a resin layer containing a desiccant.

In each of the light-emitting devices described in this embodiment, distortion due to external force or the like increases toward the outer portion of the light-emitting device. In view of the above, a glass layer is used as the first sealant 2005a in which distortion due to external force or the like is relatively small, and a resin layer is employed as the second sealant 2005b which has excellent impact resistance and excellent heat resistance and is not easily broken by deformation due to external force or the like, whereby entry of impurities into the first space 2013 can be suppressed.

In addition to the above structure, a material serving as a desiccant may be contained in each of the first space 2013 and the second space 2011.

In the case where the first sealant 2005a or the second sealant 2005b is a glass layer, for example, a glass frit or a glass ribbon can be used. Note that at least a glass material is contained in a glass frit or a glass ribbon.

The glass frit contains a glass material as a frit material. The glass frit may contain, for example, magnesium oxide, calcium oxide, strontium oxide, barium oxide, cesium oxide, sodium oxide, potassium oxide, boron oxide, vanadium oxide, zinc oxide, tellurium oxide, aluminum oxide, silicon dioxide, lead oxide, tin oxide, ruthenium oxide, rhodium oxide, iron oxide, copper oxide, manganese dioxide, molybdenum oxide, niobium oxide, titanium oxide, tungsten oxide, bismuth oxide, zirconium oxide, lithium oxide, antimony oxide, lead borate glass, tin phosphate glass, vanadate glass, or borosilicate glass. The glass frit preferably contains at least one or more kinds of transition metals to absorb infrared light.

Further, in the case where a glass layer is formed using any of the above glass fits, for example, a frit paste is applied to a substrate and is subjected to heat treatment, laser light irradiation, or the like. The frit paste contains the frit material and a resin (also referred to as a binder) diluted by an organic solvent. The frit paste can be formed using a variety of materials and can employ a variety of structures. An absorber which absorbs laser light may be added to the frit material. For example, an Nd:YAG laser or a semiconductor laser is preferably used as the laser. The shape of laser light may be circular or quadrangular.

Note that the thermal expansion coefficient of the glass layer to be formed is preferably close to that of the substrate. The closer the thermal expansion coefficients are, the more generation of a crack in the glass layer or the substrate due to thermal stress can be suppressed.

Although any of a variety of materials, for example, photocurable resins such as an ultraviolet curable resin and thermosetting resins can be used in the case where the first sealant 2005a or the second sealant 2005b is a resin layer, it is particularly preferable to use a material which does not transmit moisture or oxygen. In particular, a photocurable resin is preferably used. The light-emitting element contains a material having low heat resistance in some cases. A photocurable resin, which is cured by light irradiation, is preferably used, in which case a change in film quality and deterioration of an organic compound itself caused by heating of the light-emitting element can be suppressed. Furthermore, any of the organic compounds that can be used for the light-emitting element of one embodiment of the present invention may be used.

As the desiccant contained in the resin layer, the first space 2013, or the second space 2011, a variety of materials can be used. As the desiccant, a substance which adsorbs moisture and the like by chemical adsorption or physical adsorption can be used. Examples thereof are alkali metal oxides, alkaline earth metal oxides (e.g., calcium oxide and barium oxide), sulfates, metal halides, perchlorates, zeolite, silica gel, and the like.

One or both of the first space 2013 and the second space 2011 may have, for example, an inert gas such as a rare gas or a nitrogen gas or may contain an organic resin. Note that these spaces are each in an atmospheric pressure state or a reduced pressure state.

As described above, the light-emitting device described in this embodiment has a double sealing structure, in which one of the first sealant 2005a and the second sealant 2005b is the glass layer having excellent productivity and an excellent sealing property, and the other is the resin layer which is not easily broken by external force or the like, and can contain the desiccant inside, so that a sealing property of suppressing entry of impurities from the outside can be improved.

Thus, the use of the structure described in this embodiment can provide a light-emitting device in which deterioration of a light-emitting element due to impurities is suppressed.

Note that the structure described in this embodiment can be combined as appropriate with any of the structures described in the other embodiments or the examples.

### Embodiment 4

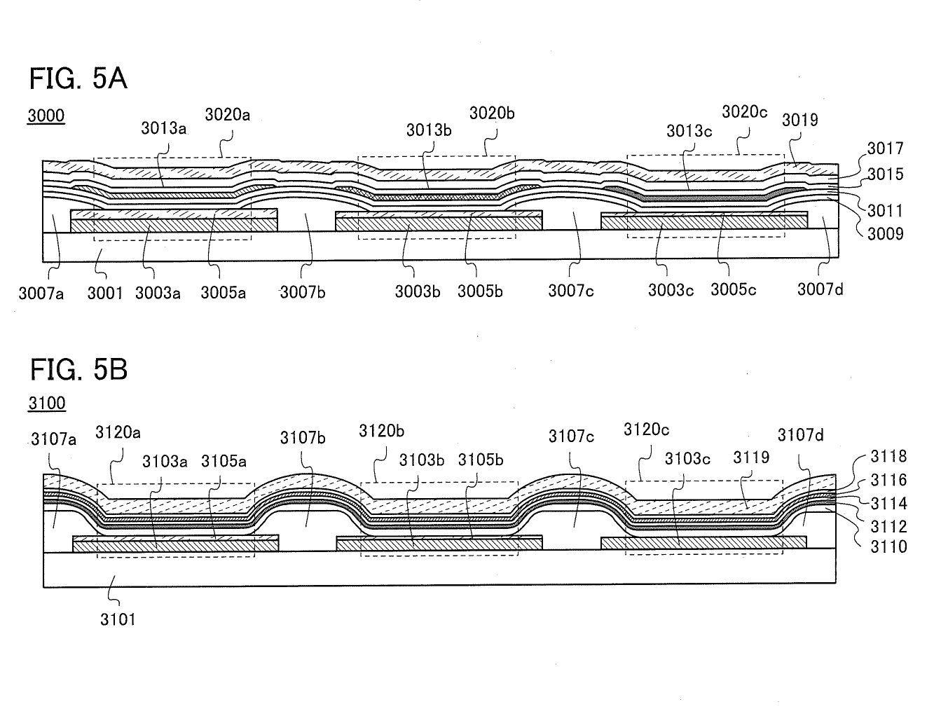

In this embodiment, a light-emitting device in which the light-emitting element of one embodiment of the present invention is used is described with reference to FIGS. 5A and 5B.

FIGS. 5A and 5B are each an example of a cross-sectional image of a light-emitting device including a plurality of light-emitting elements. A light-emitting device 3000 illustrated in FIG. 5A includes light-emitting elements 3020a, 3020b, and 3020c.

The light-emitting device 3000 includes island-shaped lower electrodes 3003a, 3003b, and 3003c over a substrate 3001. The lower electrodes 3003a, 3003b, and 3003c can function as anodes of the respective light-emitting elements. Reflective electrodes may be provided as the lower electrodes 3003a, 3003b, and 3003c. Transparent conductive layers 3005a, 3005b, and 3005c may be provided over the lower electrodes 3003a, 3003b, and 3003c, respectively. The transparent conductive layers 3005a, 3005b, and 3005c preferably have different thicknesses depending on emission colors of the elements.

Further, the light-emitting device 3000 includes partitions 3007a, 3007b, 3007c, and 3007d. Specifically, the partition 3007a covers one edge portion of the lower electrode 3003a and one edge portion of the transparent conductive layer 3005a; the partition 3007b covers the other edge portion of the lower electrode 3003a and the other edge portion of the transparent conductive layer 3005a and also covers one edge portion of the lower electrode 3003b and one edge portion of the transparent conductive layer 3005b; the partition 3007c covers the other edge portion of the lower electrode 3003b and the other edge portion of the transparent conductive layer 3005b and also covers one edge portion of the lower electrode 3003c and one edge portion of the transparent conductive layer 3005c; the partition 3007d covers the other edge portion of the lower electrode 3003c and the other edge portion of the transparent conductive layer 3005c.

The light-emitting device 3000 includes a hole-injection layer 3009 over the transparent conductive layers 3005a, 3005b, and 3005c and the partitions 3007a, 3007b, 3007c, and 3007d.

Further, the light-emitting device 3000 includes a hole-transport layer 3011 over the hole-injection layer 3009. The light-emitting device 3000 also includes light-emitting layers 3013a, 3013b, and 3013c over the hole-transport layer 3011. The light-emitting device 3000 also includes an electron-transport layer 3015 over the light-emitting layers 3013a, 3013b, and 3013c.

Further, the light-emitting device 3000 includes an electron-injection layer 3017 over the electron-transport layer 3015. The light-emitting device 3000 also includes an upper electrode 3019 over the electron-injection layer 3017. The upper electrode 3019 can function as cathodes of the light-emitting elements.

Note that although an example in which the lower electrodes 3003a, 3003b, and 3003c function as the anodes of the light-emitting elements and the upper electrode 3019 functions as the cathodes of the light-emitting elements is described with reference to FIG. 5A, the stacking order of the anode and the cathode may be switched. In this case, the stacking order of the electron-injection layer, the electron-transport layer, the hole-transport layer, and the hole-injection layer may be changed.

The light-emitting element of one embodiment of the present invention can be applied to the light-emitting layers 3013a, 3013b, and 3013c. The light-emitting element can have low driving voltage, high current efficiency, or a long lifetime; thus, the light-emitting device 3000 can have low power consumption or a long lifetime.

A light-emitting device 3100 illustrated in FIG. 5B includes light-emitting elements 3120a, 3120b, and 3120c. The light-emitting elements 3120a, 3120b, and 3120c are tandem light-emitting elements in which a plurality of light-emitting layers are provided between lower electrodes 3103a, 3103b, and 3103c and an upper electrode 3119.

The light-emitting device 3100 includes the island-shaped lower electrodes 3103a, 3103b, and 3103c over a substrate 3101. The lower electrodes 3103a, 3103b, and 3103c function as anodes of the light-emitting elements. Reflective electrodes may be provided as the lower electrodes 3103a, 3103b, and 3103c. Transparent conductive layers 3105a and 3105b may be provided over the lower electrodes 3103a and 3103b. The transparent conductive layers 3105a and 3105b preferably have different thicknesses depending on emission colors of the elements. Although not illustrated, a transparent conductive layer may also be provided over the lower electrode 3103c.

Further, the light-emitting device 3100 includes partitions 3107a, 3107b, 3107c, and 3107d. Specifically, the partition 3107a covers one edge portion of the lower electrode 3103a and one edge portion of the transparent conductive layer 3105a; the partition 3107b covers the other edge portion of the lower electrode 3103a and the other edge portion of the transparent conductive layer 3105a and also covers one edge portion of the lower electrode 3103b and one edge portion of the transparent conductive layer 3105b; the partition 3107c covers the other edge portion of the lower electrode 3103b and the other edge portion of the transparent conductive layer 3105b and also covers one edge portion of the lower electrode 3103c and one edge portion of the transparent conductive layer 3105c; the partition 3107d covers the other edge portion of the lower electrode 3103c and the other edge portion of the transparent conductive layer 3105c.

Further, the light-emitting device 3100 includes a hole-injection and hole-transport layers 3110 over the lower electrodes 3103a, 3103b, and 3103c and the partitions 3107a, 3107b, 3107c, and 3107d.

Further, the light-emitting device 3100 includes a first light-emitting layer 3112 over the hole-injection and hole-transport layers 3110. The light-emitting device 3100 also includes a second light-emitting layer 3116 over the first light-emitting layer 3112 with a charge generation layer 3114 therebetween.

Further, the light-emitting device 3100 includes an electron-transport and electron-injection layers 3118 over the second light-emitting layer 3116. In addition, the light-emitting device 3100 includes the upper electrode 3119 over the electron-transport and electron-injection layers 3118. The upper electrode 3119 can function as cathodes of the light-emitting elements.

Note that although an example in which the lower electrodes 3103a, 3103b, and 3103c function as the anodes of the light-emitting elements and the upper electrode 3119 functions as the cathodes of the light-emitting elements is described with reference to FIG. 5B, the stacking order of the anode and the cathode may be switched. In this case, the stacking order of the electron-injection layer, the electron-transport layer, the hole-transport layer, and the hole-injection layer may be changed.

The light-emitting element of one embodiment of the present invention can be applied to the first light-emitting layer 3112 and the second light-emitting layer 3116. The light-emitting element can have low driving voltage, high current efficiency, or a long lifetime; thus, the light-emitting device 3100 can have low power consumption or a long lifetime.

Note that the structure described in this embodiment can be combined as appropriate with any of the structures described in the other embodiments and the examples.

### Embodiment 5

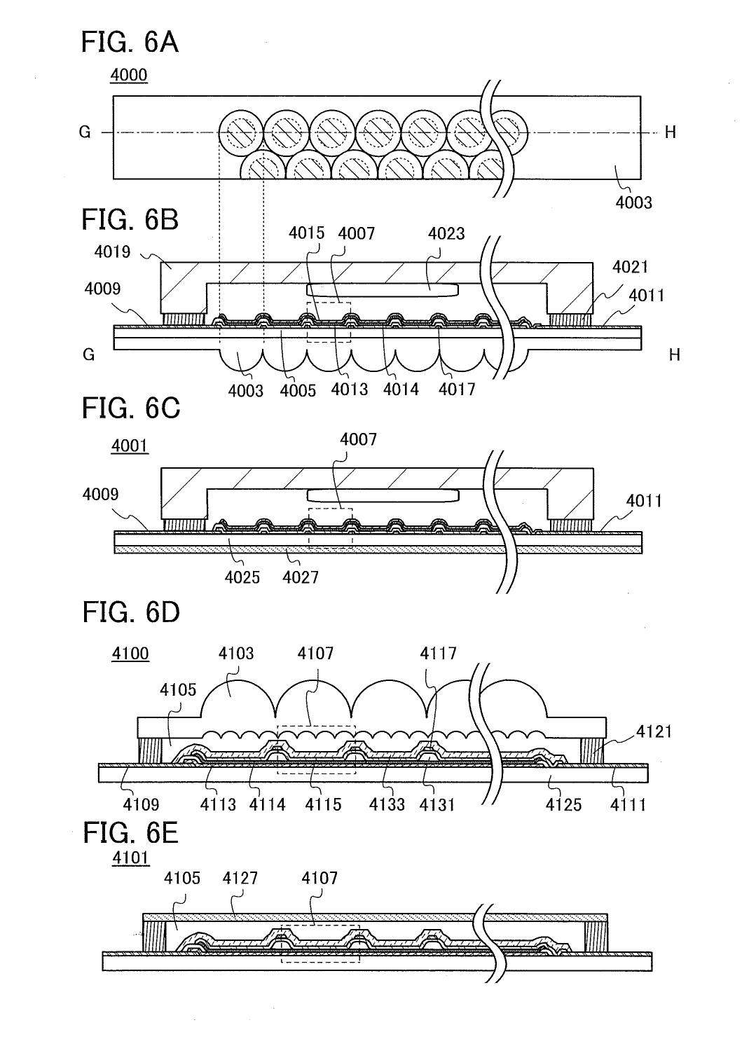

In this embodiment, a lighting device manufactured using the light-emitting element of one embodiment of the present invention is described with reference to FIGS. 6A to 6E.

FIGS. 6A to 6E are a plan view and cross-sectional views of lighting devices. FIGS. 6A to 6C are bottom-emission lighting devices in which light is extracted from the substrate side. FIG. 6B is a cross-sectional view taken along dashed-dotted line G-H in FIG. 6A.

A lighting device 4000 illustrated in FIGS. 6A and 6B includes a light-emitting element 4007 over a substrate 4005. In addition, the lighting device 4000 includes a substrate 4003 with unevenness on the outside of the substrate 4005. The light-emitting element 4007 includes a lower electrode 4013, an EL layer 4014, and an upper electrode 4015.

The lower electrode 4013 is electrically connected to an electrode 4009, and the upper electrode 4015 is electrically connected to an electrode 4011. In addition, an auxiliary wiring 4017 electrically connected to the lower electrode 4013 may be provided.

The substrate 4005 and a sealing substrate 4019 are bonded to each other by a sealant 4021. A desiccant 4023 is preferably provided between the sealing substrate 4019 and the light-emitting element 4007.

The substrate 4003 has the unevenness illustrated in FIG. 6A, whereby the extraction efficiency of light emitted from the light-emitting element 4007 can be increased. Instead of the substrate 4003, a diffusion plate 4027 may be provided on the outside of the substrate 4025 as in a lighting device 4001 illustrated in FIG. 6C.

FIGS. 6D and 6E illustrate top-emission lighting devices in which light is extracted from the side opposite to the substrate.

A lighting device 4100 illustrated in FIG. 6D includes a light-emitting element 4107 over a substrate 4125. The light-emitting element 4107 includes a lower electrode 4113, an EL layer 4114, and an upper electrode 4115.

The lower electrode 4113 is electrically connected to an electrode 4109, and the upper electrode 4115 is electrically connected to an electrode 4111. An auxiliary wiring 4117 electrically connected to the upper electrode 4115 may be provided. An insulating layer 4131 may be provided under the auxiliary wiring 4117.

The substrate 4125 and a sealing substrate 4103 with unevenness are bonded to each other by a sealant 4121. A planarization film 4105 and a barrier film 4133 may be provided between the sealing substrate 4103 and the light-emitting element 4107.

Since the sealing substrate 4103 has the unevenness illustrated in FIG. 6D, the extraction efficiency of light emitted from the light-emitting element 4107 can be increased. Instead of the sealing substrate 4103, a diffusion plate 4127 may be provided over the light-emitting element 4107 as in a lighting device 4101 illustrated in FIG. 6E.

The light-emitting element of one embodiment of the present invention can be applied to light-emitting layers included in the EL layer 4014 and the EL layer 4114. The light-emitting element can have low driving voltage, high current efficiency, or a long lifetime; thus, the lighting devices 4000, 4001, 4100, and 4101 can have low power consumption or a long lifetime.

Note that the structure described in this embodiment can be combined as appropriate with any of the structures described in the other embodiments and the examples.

### Embodiment 6

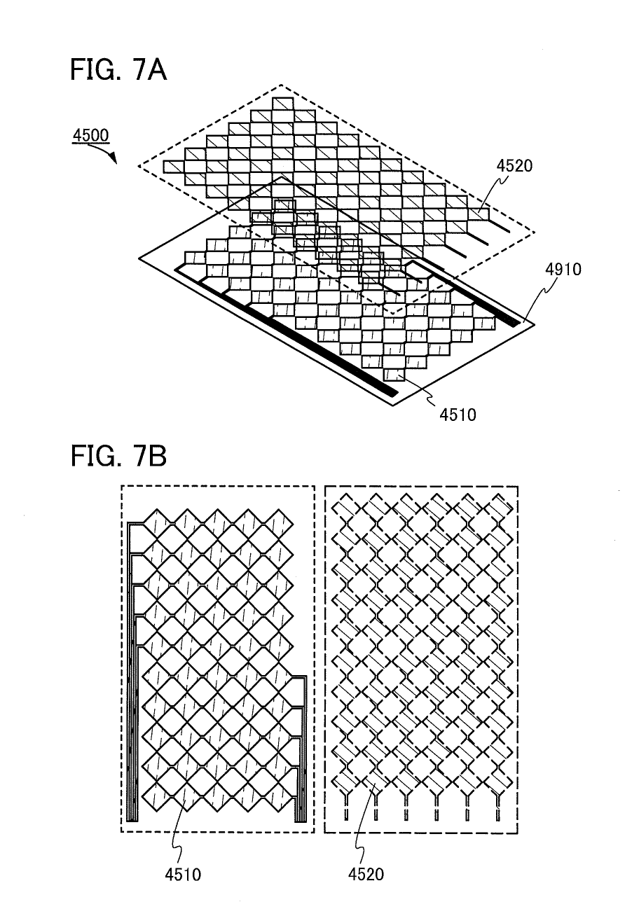

In this embodiment, a touch sensor and a display module which can be combined with the light-emitting device of one embodiment of the present invention are described with reference to FIGS. 7A and 7B, FIG. 8, FIG. 9, and FIG. 10.

FIG. 7A is an exploded perspective view illustrating a structural example of a touch sensor 4500. FIG. 7B is a plan view illustrating a structural example of the touch sensor 4500.

The touch sensor 4500 illustrated in FIGS. 7A and 7B includes, over a substrate 4910, conductive layers 4510 arranged in the X-axis direction and conductive layers 4520 arranged in the Y-axis direction which intersect with the X-axis direction. In FIGS. 7A and 7B illustrating the touch sensor 4500, a plane over which conductive layers 4510 are formed and a plane over which conductive layers 4520 are formed are separately illustrated.

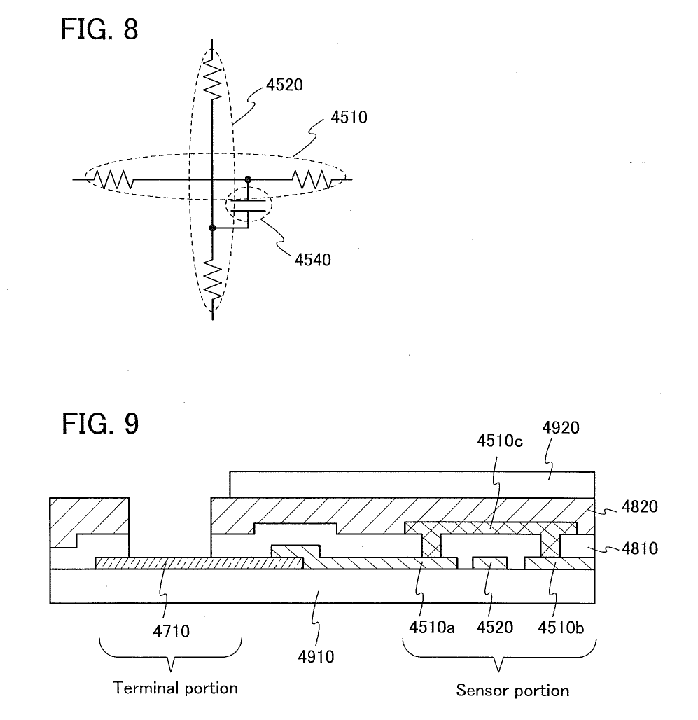

FIG. 8 is an equivalent circuit diagram illustrating the portion where the conductive layer 4510 and the conductive layer 4520 of the touch sensor 4500 illustrated in FIGS. 7A and 7B intersect with each other. As illustrated in FIG. 8, a capacitor 4540 is formed in the portion where the conductive layer 4510 and the conductive layer 4520 intersect with each other.

The conductive layer 4510 and the conductive layer 4520 each have a structure in which a plurality of quadrangular conductive films are connected to one another. The conductive layers 4510 and the conductive layers 4520 are provided so that the quadrangular conductive films of the conductive layer 4510 and the quadrangular conductive films of the conductive layer 4520 do not overlap with each other. In the portion where the conductive layer 4510 intersects with the conductive layer 4520, an insulating film is provided between the conductive layer 4510 and the conductive layer 4520 so that the conductive layer 4510 and the conductive layer 4520 are not in direct contact with each other.

FIG. 9 is a cross-sectional view illustrating an example of a connection between the conductive layers 4510a, 4510b, and 4510c and the conductive layer 4520 and is an example of a cross-sectional view illustrating a portion where the conductive layers 4510a, 4510b, and 4510c intersect with the conductive layer 4520.

As illustrated in FIG. 9, the conductive layer 4510 includes the conductive layer 4510a and the conductive layer 4510b in the first layer and the conductive layer 4510c in the second layer over an insulating layer 4810. The conductive layer 4510a and the conductive layer 4510b are connected to each other by the conductive layer 4510c. The conductive layer 4520 is formed using the conductive layer in the first layer. The insulating layers 4810 and 4820 is formed so as to cover the conductive layers 4510a, 4510b, 4510c, and 4520 and part of a conductive layer 4710. As the insulating layers 4810 and 4820, for example, a silicon oxynitride film may be formed. Note that a base film formed of an insulating film may be formed between a substrate 4910 and the conductive layers 4710, 4510a, 4510b, and 4520. As the base film, for example, a silicon oxynitride film can be formed.

The conductive layers 4510a, 4510b, and 4510c and the conductive layer 4520 are formed using a conductive material having a property of transmitting visible light. Examples of the conductive material having a property of transmitting visible light include indium tin oxide containing silicon oxide, indium tin oxide, zinc oxide, indium zinc oxide, and zinc oxide to which gallium is added.

The conductive layer 4510a is connected to the conductive layer 4710. A terminal for connection to an FPC is formed using the conductive layer 4710. The conductive layer 4520 is connected to the conductive layer 4710 like the conductive layer 4510a. The conductive layer 4710 can be formed of, for example, a tungsten film.

The insulating layer 4820 is formed so as to cover the conductive layers 4510a, 4510b, 4510c, and 4520 and part of the conductive layer 4710. An opening is formed in the insulating layers 4810 and 4820 over the conductive layer 4710 so that the conductive layer 4710 is electrically connected to an FPC. A substrate 4920 is attached to and placed over the insulating layer 4820 using an adhesive, an adhesive film, or the like. The substrate 4910 side is bonded to a color filter substrate of a display panel with an adhesive or an adhesive film, so that a touch panel is completed.

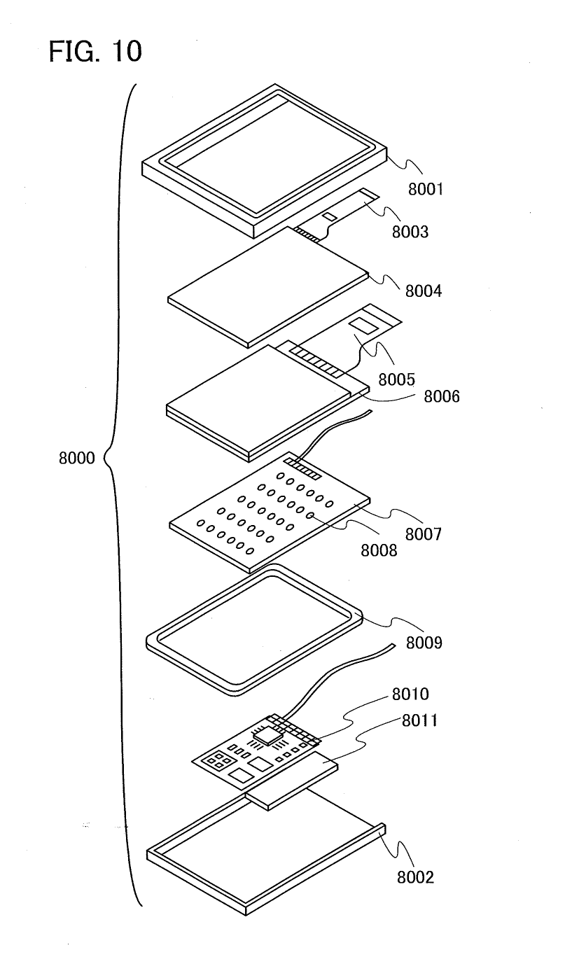

Next, a display module which can be used for a light-emitting device of one embodiment of the present invention is described with reference to FIG. 10.

In a display module 8000 illustrated in FIG. 10, a touch panel 8004 connected to an FPC 8003, a display panel 8006 connected to an FPC 8005, a backlight unit 8007, a frame 8009, a printed board 8010, and a battery 8011 are provided between an upper cover 8001 and a lower cover 8002.

The shapes and sizes of the upper cover 8001 and the lower cover 8002 can be changed as appropriate in accordance with the sizes of the touch panel 8004 and the display panel 8006.

The touch panel 8004 can be a resistive touch panel or a capacitive touch panel and can be formed to overlap with the display panel 8006. It is also possible to provide a touch panel function for a counter substrate (sealing substrate) of the display panel 8006. A photosensor may be provided in each pixel of the display panel 8006 so that an optical touch panel is obtained.

The backlight unit 8007 includes light sources 8008 to which the light-emitting elements of one embodiment of the invention can be applied. Note that although a structure in which the light sources 8008 are provided over the backlight unit 8007 is illustrated in FIG. 10, one embodiment of the present invention is not limited to this structure. For example, a structure in which a light source 8008 is provided at an end portion of the backlight unit 8007 and a light diffusion plate is further provided may be employed. Note that the backlight unit 8007 is not necessarily provided. In this case, the light-emitting elements of one embodiment of the invention can be incorporated to the display panel 8006.

The frame 8009 has a function of protecting the display panel 8006 and functions as an electromagnetic shield for blocking electromagnetic waves generated by the operation of the printed board 8010. The frame 8009 may function as a radiator plate.

The printed board 8010 has a power supply circuit and a signal processing circuit for outputting a video signal and a clock signal. As a power source for supplying electric power to the power supply circuit, an external commercial power source or a power source using a battery 8011 separately provided may be used. The battery 8011 can be omitted when a commercial power source is used.

The display module 8000 can be additionally provided with a member such as a polarizing plate, a retardation plate, or a prism sheet.

Note that the structure described in this embodiment can be combined as appropriate with any of the structures described in the other embodiments and the examples.

### Embodiment 7

In this embodiment, examples of electronic appliances are described.

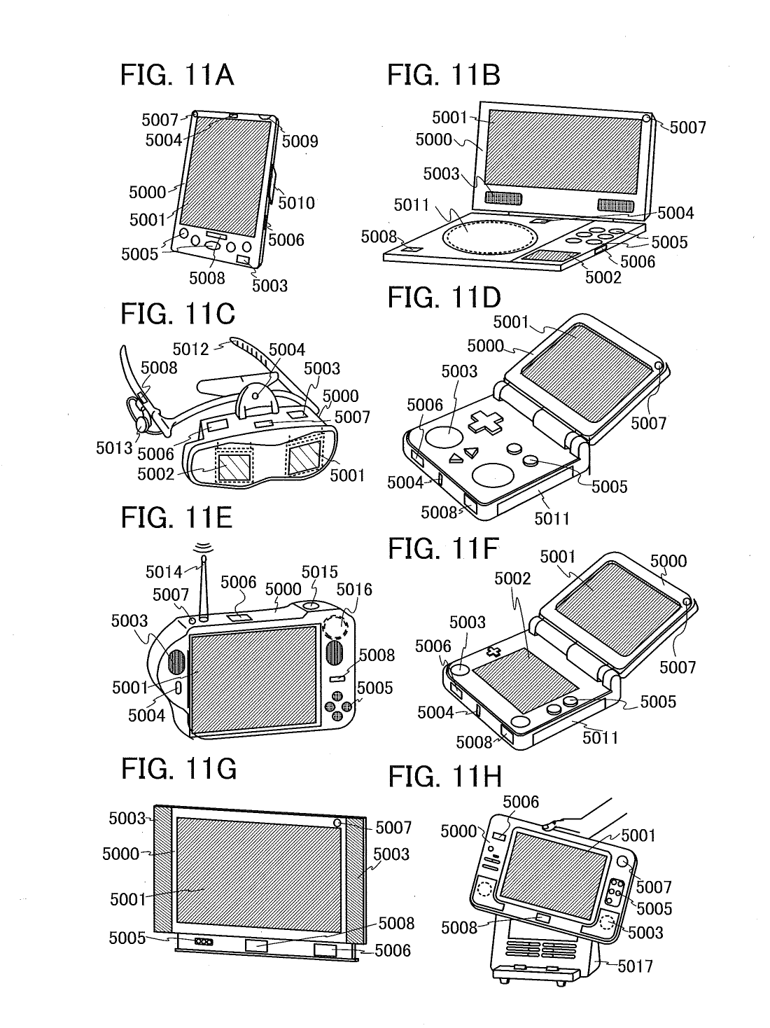

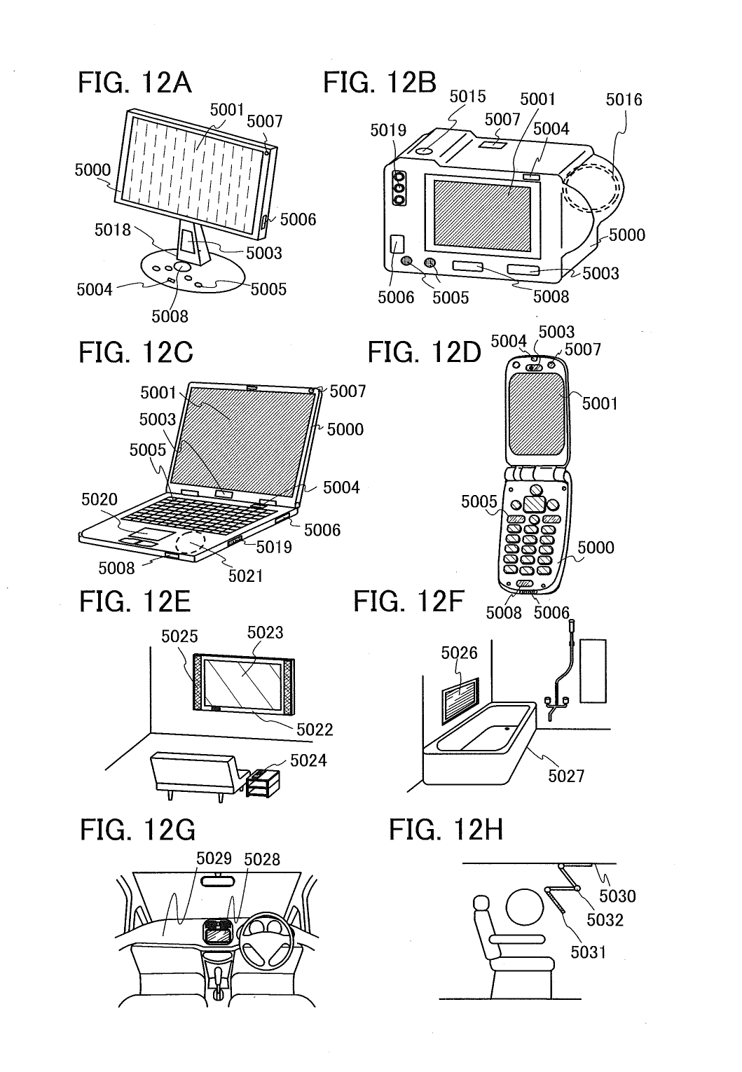

FIGS. 11A to 11H and FIGS. 12A to 12D illustrate electronic appliances. These electronic devices can include a housing 5000, a display portion 5001, a speaker 5003, an LED lamp 5004, operation keys 5005 (including a power switch or an operation switch), a connection terminal 5006, a sensor 5007 (a sensor having a function of measuring or sensing force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, and the like.

FIG. 11A illustrates a mobile computer which can include a switch 5009, an infrared port 5010, and the like in addition to the above components. FIG. 11B illustrates a portable image reproducing device (e.g., a DVD reproducing device) provided with a memory medium, which can include a second display portion 5002, a memory medium reading portion 5011, and the like in addition to the above components. FIG. 11C illustrates a goggle-type display which can include the second display portion 5002, a support 5012, an earphone 5013, and the like in addition to the above components. FIG. 11D illustrates a portable game machine which can include the memory medium reading portion 5011 and the like in addition to the above components. FIG. 11E illustrates a digital camera with a television reception function, which can include an antenna 5014, a shutter button 5015, an image reception portion 5016, and the like in addition to the above components. FIG. 11F illustrates a portable game machine which can include the second display portion 5002, the memory medium reading portion 5011, and the like in addition to the above components. FIG. 11G illustrates a television receiver which can include a tuner, an image processing portion, and the like in addition to the above components. FIG. 11H illustrates a portable television receiver which can be combined with a charger 5017 capable of transmitting and receiving signals. FIG. 12A illustrates a display which can include a support base 5018 and the like in addition to the above components. FIG. 12B illustrates a camera which can include an external connection port 5019, a shutter button 5015, an image reception portion 5016, and the like in addition to the above components. FIG. 12C is a computer which can include a pointing device 5020, the external connection port 5019, a reader/writer 5021, and the like in addition to the above components. FIG. 12D illustrates a mobile phone which can include a transmitter, a receiver, a tuner of one-segment partial reception service for mobile phones and mobile terminals, and the like in addition to the above components.

The electronic appliances illustrated in FIGS. 11A to 11H and FIGS. 12A to 12D can have a variety of functions. The electronic appliances can have, for example, a function of displaying various kinds of data (image data including a still image and a moving image, a text data, and the like) on the display portion, a touch panel function, a function of displaying a calendar, date, time, and the like, a function of controlling a process with a variety of software (programs), a wireless communication function, a function of being connected to a variety of computer networks with a wireless communication function, a function of transmitting and receiving various kinds of data with a wireless communication function, and a function of reading a program or data stored in a memory medium and displaying the program or data on the display portion. Further, the electronic appliance including the plurality of display portions can have a function of displaying image information mainly on one display portion while displaying text information on another display portion, a function of displaying a three-dimensional image by displaying images where parallax is considered on the plurality of display portions, or the like. Further, the electronic appliance including an image receiving portion can have a function of photographing a still image, a function of photographing a moving image, a function of automatically or manually correcting a photographed image, a function of storing a photographed image in a memory medium (an external memory medium or a memory medium incorporated in the camera), a function of displaying a photographed image on the display portion, or the like. Note that the electronic appliances illustrated in FIGS. 11A to 11H and FIGS. 12A to 12D can have a variety of functions without limitation to the above functions.

The electronic appliances described in this embodiment each include the display portion for displaying some sort of information.

Next, application examples of the display device are described.

FIG. 12E illustrates an example in which a display device is placed to be integrated in a building structure. FIG. 12E illustrates a housing 5022, a display portion 5023, a remote controller 5024 which is an operation portion, a speaker 5025, and the like. The display device is integrated in the building structure as a wall-hanging type and thus can be placed without requiring a large space.

FIG. 12F illustrates another example in which a display device is incorporated in a building structure. The display module 5026 is incorporated in a prefabricated bath 5027 so that a bather can watch the display module 5026.

Note that although the wall and the prefabricated bath unit are given as examples of the building structures in this embodiment, the display device can be placed in a variety of building structures without being limited to the example in this embodiment.

Next, examples where the display device is incorporated with a moving object are described.

FIG. 12G illustrates an example in which a display device is incorporated in a car. A display module 5028 is attached to a body 5029 of a vehicle and can display data on the operation of the body or data input from inside or outside of the body on demand. Note that a navigation function may be provided.

FIG. 12H illustrates an example in which a display device is placed to be integrated in a passenger airplane. FIG. 12H illustrates a usage pattern when a display module 5031 is provided for a ceiling 5030 above a seat of the passenger airplane. The display module 5031 is attached to the ceiling 5030 with a hinge portion 5032, and a passenger can watch the display module 5031 by stretching the hinge portion 5032. The display module 5031 has a function of displaying data when operated by a passenger.

Note that although the body of the vehicle and the body of the airplane are taken as examples of the moving object, one embodiment of the present invention is not limited thereto. The display device can be provided for a variety of moving objects such as a two-wheel vehicle, a four-wheel vehicle (including an automobile and a bus), a train (including a monorail train and a railway train), and a ship.

Note that the structure described in this embodiment can be combined as appropriate with any of the structures described in the other embodiments or the example.

Note that in this specification and the like, part of a diagram or a text described in one embodiment can be taken out to constitute one embodiment of the invention. Thus, in the case where a diagram or a text related to a certain part is described, a content taken out from the diagram or the text of the certain part is also disclosed as one embodiment of the invention and can constitute one embodiment of the invention. Thus, for example, part of a diagram or a text including one or more of active elements (e.g., transistors and diodes), wirings, passive elements (e.g., capacitors and resistors), conductive layers, insulating layers, semiconductor layers, organic materials, inorganic materials, components, devices, operating methods, manufacturing methods, and the like can be taken out to constitute one embodiment of the invention. For example, M circuit elements (e.g., transistors or capacitors) (M is an integer) are picked up from a circuit diagram in which N circuit elements (e.g., transistors or capacitors) (N is an integer, where M<N) are provided, whereby one embodiment of the invention can be constituted. As another example, M layers (M is an integer) are picked up from a cross-sectional view in which N layers (N is an integer, where M<N) are provided, whereby one embodiment of the invention can be constituted. As another example, M elements (M is an integer) are picked up from a flow chart in which N elements (N is an integer, where M<N) are provided, whereby one embodiment of the invention can be constituted.

Note that in this specification and the like, a content described in at least a diagram (which may be part of the diagram) is disclosed as one embodiment of the invention, and one embodiment of the invention can be constituted. Therefore, when a certain content is described in a diagram, the content is disclosed as one embodiment of the invention even when the content is not described with a text, and one embodiment of the invention can be constituted. In a similar manner, part of a diagram, which is taken out from the diagram, is disclosed as one embodiment of the invention, and one embodiment of the invention can be constituted.

### Example 1

In this example, a method of synthesizing 2mDBTPDBQu-II represented by the following structural formula (101) is described.

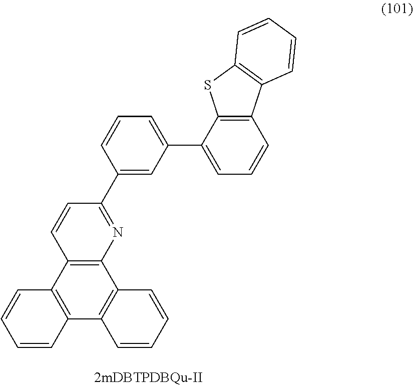 [SMILES: c1cc(-c2ccc3c4ccccc4c4ccccc4c3n2)cc(-c2cccc3c2sc2ccccc23)c1]

<<Synthesis of 2mDBTPDBQu-II>>

A synthesis scheme of 2mDBTPDBQu-II is shown in (C-1).

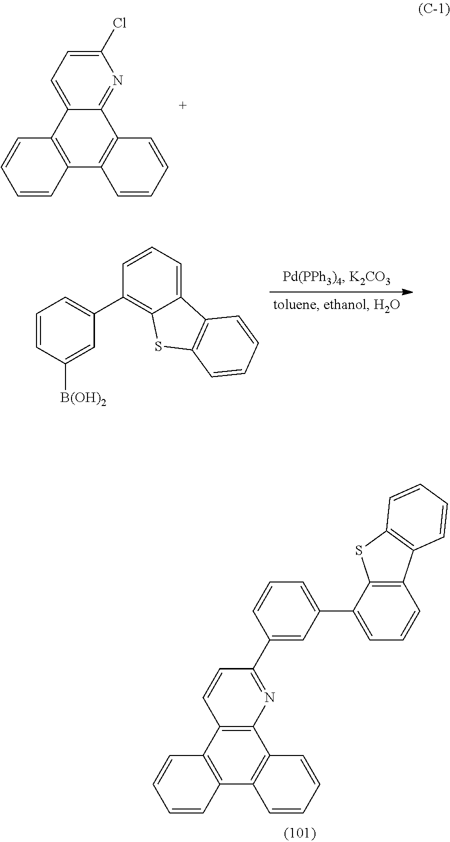 [SMILES: Clc1ccc2c3ccccc3c3ccccc3c2n1 ; OB(O)c1cccc(-c2cccc3c2sc2ccccc23)c1 ; c1cc(-c2ccc3c4ccccc4c4ccccc4c3n2)cc(-c2cccc3c2sc2ccccc23)c1]

In a 100-mL three-neck flask were put 0.46 g (1.7 mmol) of 2-chlorodibenzo[f,h]quinoline, 0.62 g (2.0 mmol) of 3-(dibenzothiophen-4-yl)phenylboronic acid, 20 mL of toluene, 2 mL of ethanol, and 2 mL of a 2M aqueous solution of potassium carbonate. The mixture was degassed by being stirred under reduced pressure, and the air in the flask was replaced with nitrogen. To the mixture, 65 mg (56 μmol) of tetrakis(triphenylphosphine)palladium(0) was added, and the mixture was stirred at 80° C. under nitrogen stream for 7 hours. After predetermined time, water was added to the mixture, and an aqueous layer was extracted with toluene. The solution of the obtained extract and the organic layer were combined and washed with a saturated aqueous solution of sodium carbonate and saturated saline, and the resulting organic layer was dried with magnesium sulfate. The obtained mixture was gravity-filtered, and the filtrate was concentrated to give an oily substance. The obtained oily substance was purified by silica gel column chromatography (toluene:hexane=1:1) to give a solid. The obtained solid was purified by high performance liquid column chromatography. The obtained fraction was concentrated to give a solid. Methanol was added to the solid, the resulting suspension was irradiated with ultrasonic waves, and the solid was collected by suction filtration, so that the objective substance was obtained as 0.68 g of white powder in 79% yield.

Then, 0.66 g of the obtained white powder of 2mDBTPDBQu-II was purified by a train sublimation method. In the purification, 2mDBTPDBQu-II was heated at 280° C. for 14 hours under the conditions where the pressure was 2.7 Pa and the argon flow was 5.0 mL/min. After the purification, 0.60 g of a white solid of 2mDBTPDBQu-II was obtained at a collection rate of 90%.

Nuclear magnetic resonance (¹H NMR) spectroscopy identified this compound as 2mDBTPDBQu-II, which was the objective substance.

¹H NMR data of the obtained substance are as follows: ¹H NMR (CDCl₃, 300 MHz): δ=7.48-7.51 (m, 2H), 7.61-7.89 (m, 9H), 8.16 (d, J=8.4 Hz, 1H), 8.22-8.25 (m, 2H), 8.44 (d, J=7.8 Hz, 1H), 8.60-8.72 (m, 3H), 8.79 (s, 1H), 8.97 (d, J=8.7 Hz, 1H), 9.57-9.60 (m, 1H).

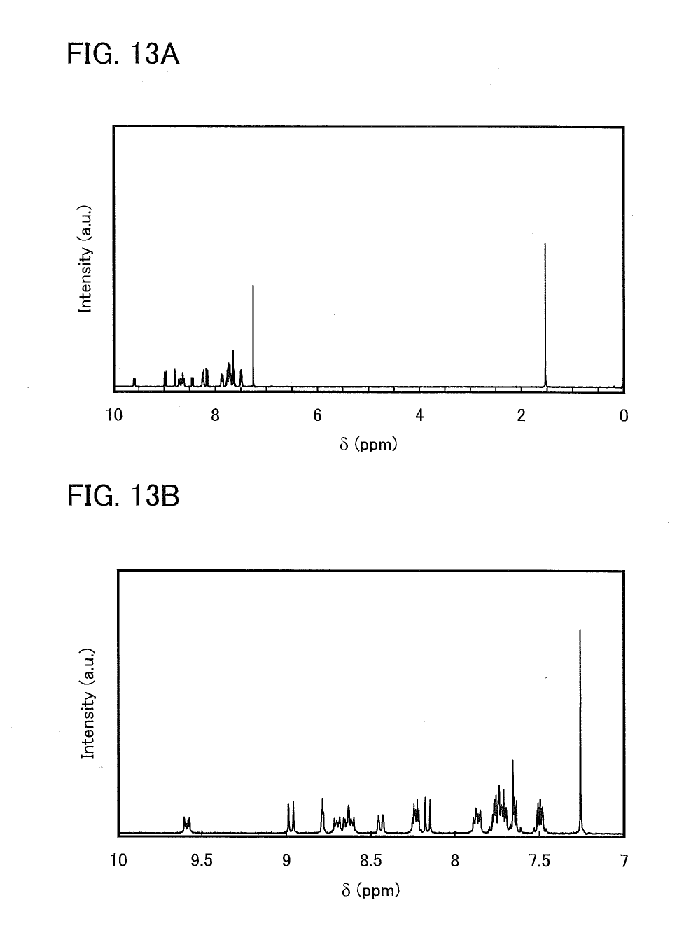

FIGS. 13A and 13B are ¹H NMR charts. Note that FIG. 13B is a chart showing an enlarged part of FIG. 13A in the range of 7.0 ppm to 10.0 ppm.

Next, 2mDBTPDBQu-II (abbreviation) obtained in this example was analyzed by liquid chromatography mass spectrometry (LC/MS).

The LC/MS analysis was carried out with Acquity UPLC (produced by Waters Corporation) and Xevo G2 T of MS (produced by Waters Corporation).

In the MS analysis, ionization was carried out by an electrospray ionization (ESI) method. At this time, the capillary voltage and the sample cone voltage were set to 3.0 kV and 30 V, respectively, and detection was performed in a positive mode. A component which underwent the ionization under the above-mentioned conditions was made to collide with an argon gas in a collision cell to dissociate into product ions. Energy (collision energy) for the collision with argon was 70 eV. The range of the mass-to-charge ratio to be measured was m/z=100 to 1200.

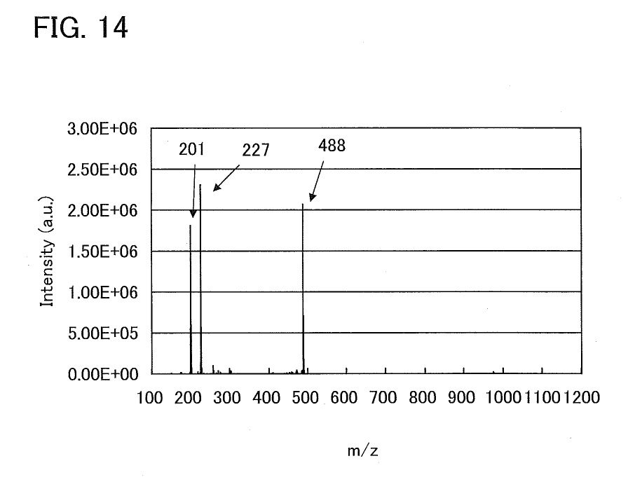

FIG. 14 shows a mass spectrum obtained from the MS analysis. The results in FIG. 14 shows that as for 2mDBTPDBQu-II obtained in this example, peaks of product ions are detected mainly around m/z=201 and m/z=227, and a peak derived from a precursor ion is detected around m/z=488.

In the LC/MS analysis, product ions and precursor ions exhibit a plurality of peaks with different m/z due to the addition or elimination of proton and the existence of isotopes. The word “around” is used in the specification in order to collectively describe the plurality of peaks. Note that the results in FIG. 14 show characteristics derived from 2mDBTPDBQu-II and therefore can be regarded as important data for identifying 2mDBTPDBQu-II contained in the mixture.

For example, the measurement results indicate that the peak around m/z=201 is derived from a radical cation of a fragment (C₁₆H₉) resulting from the dissociation of nitrogen and carbon at the 1-position and 2-position of the dibenzo[f,h]quinoline ring, respectively, as well as hydrogen. The measurement results also indicate that the peak around m/z=227, is derived from a radical cation of a fragment (C₁₇H₁₀N) having the dibenzo[f,h]quinoline ring.

That is, in the case where a substituent is bonded to the 2-position of the dibenzo[f,h]quinoline ring, peaks are easily detected around m/z=227 corresponding to a fragment which is resulted from the dissociation of the substituent from the ring and around m/z=201 corresponding to a fragment after subtraction of a molecular weight of 26 from m/z=201. Note that the substituent here refers to a portion represented by Ar-A in the general formula (G1).

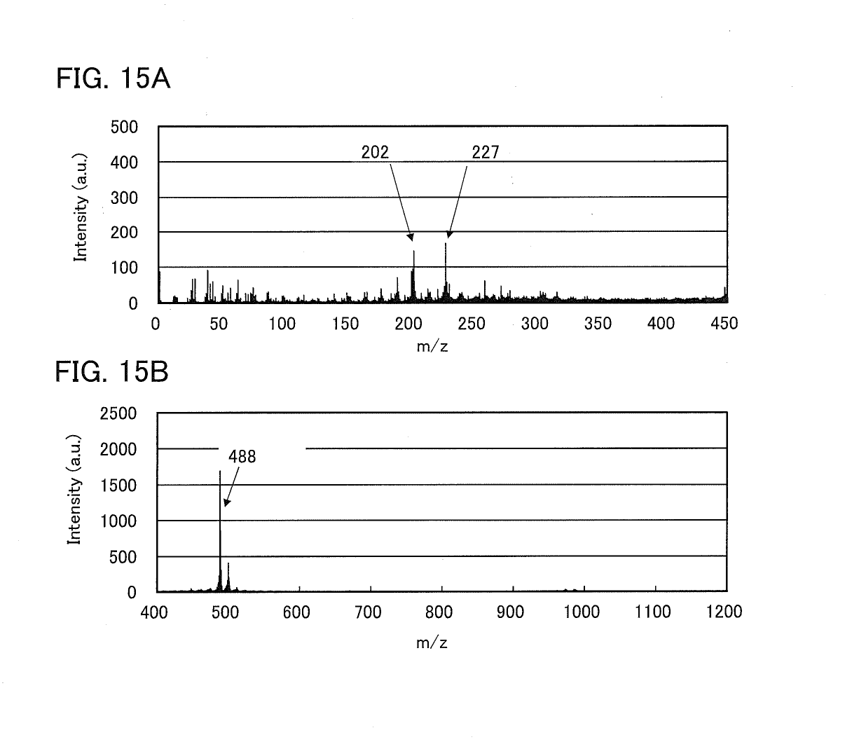

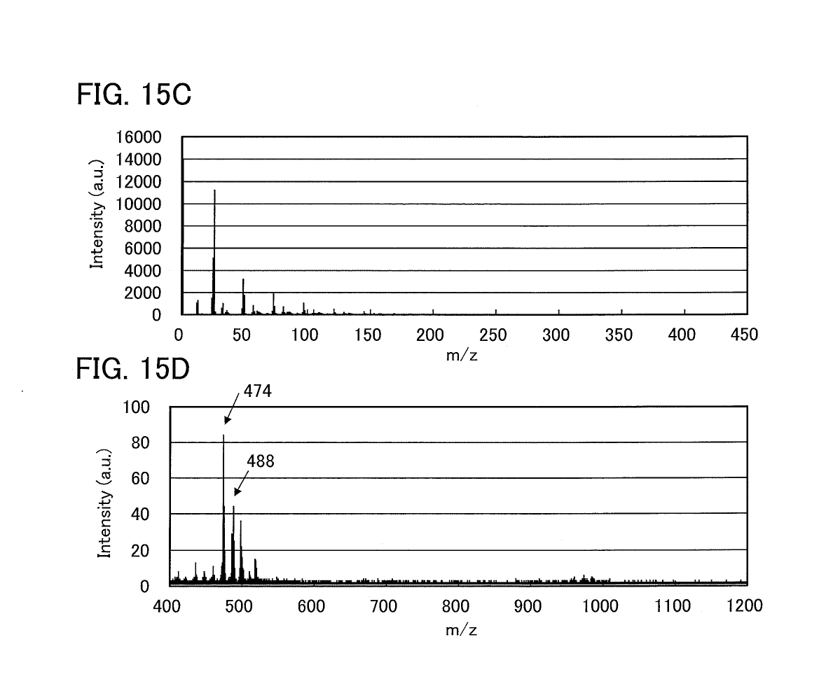

FIGS. 15A to 15D show qualitative mass spectra of 2mDBTPDBQu-II obtained in this example, which were obtained with a time-of-flight secondary ion mass spectrometer (ToF-SIMS).

FIG. 15A shows measurement results of positive ions. In FIG. 15A, the horizontal axis represents m/z ranging from 0 to 450 and the vertical axis represents intensity (arbitrary unit). FIG. 15B shows measurement results of positive ions. In FIG. 15B, the horizontal axis represents m/z ranging from 400 to 1200 and the vertical axis represents intensity (arbitrary unit). FIG. 15C shows measurement results of negative ions. In FIG. 15C, the horizontal axis represents m/z ranging from 0 to 450 and the vertical axis represents intensity (arbitrary unit). FIG. 15D shows measurement results of negative ions. In FIG. 15D, the horizontal axis represents m/z ranging from 400 to 1200 and the vertical axis represents intensity (arbitrary unit).

TOF SIMS 5 (produced by ION-TOF GmbH) was used as a measurement apparatus, and Bi₃²⁺ was used as a primary ion source. Note that irradiation with primary ions was performed with a pulse width of 11.3 ns. The irradiation amount was greater than or equal to 8.2×10¹⁰ ions/cm² and less than or equal to 6.7×10¹¹ ions/cm², the acceleration voltage was 25 keV, and the current value was 0.2 pA. Powder of 2mDBTPDBQu-II was used as a sample in the measurement.

The results in FIGS. 15A and 15B show that 2mDBTPDBQu-II that can be used for a light-emitting element of one embodiment of the present invention mainly gives peaks of product ions around m/z=202 and m/z=227 and a peak derived from a precursor ion around m/z=488.

The results in FIGS. 15C and 15D show that 2mDBTPDBQu-II mainly gives a peak of a product ion around m/z=474 and a peak derived from a precursor ion around m/z=488.

The results in FIGS. 15A to 15D show characteristics derived from 2mDBTPDBQu-II and therefore can be regarded as important data for identifying 2mDBTPDBQu-II contained in the mixture.

For example, the measurement results of positive ions shown in FIGS. 15A and 15B indicate that the peak of the product ion of 2mDBTPDBQu-II, which is detected around m/z=202, is derived from a radical cation of a fragment (C₁₆H₉) resulting from the dissociation of nitrogen and carbon from the 1-position and 2-position of a dibenzo[f,h]quinoline ring, respectively, as well as hydrogen. The measurement results also indicate that the peak of the product ion of 2mDBTPDBQu-II, which is detected around m/z=227, is derived from a radical cation of a fragment (C₁₇H₁₀N) having a dibenzo[f,h]quinoline ring.

That is, in the case where a substituent is bonded to the 2-position of the dibenzo[f,h]quinoline ring, peaks are easily detected around m/z=227 corresponding to a fragment which is resulted from the dissociation of the substituent from the ring and around m/z=202 corresponding a fragment after subtraction of a molecular weight of 25 from m/z=227. Note that the substituent here refers to a portion represented by Ar-A in the general formula (G1).

The measurement results of negative ions shown in FIGS. 15C and 15D indicate that the peak of the product ion of 2mDBTPDBQu-II, which is detected around m/z=474, is derived from a radical anion of a fragment (C₃₅H₂₂S) in which nitrogen is dissociated from the 1-position.

As described above, portions which are easily dissociated from a precursor ion are detected as the product ions in the LC/MS analysis and the ToF-SIMS analysis. The product ions which are particularly easy to detect are fragments derived from the dibenzo[f,h]quinoline ring, and the like.

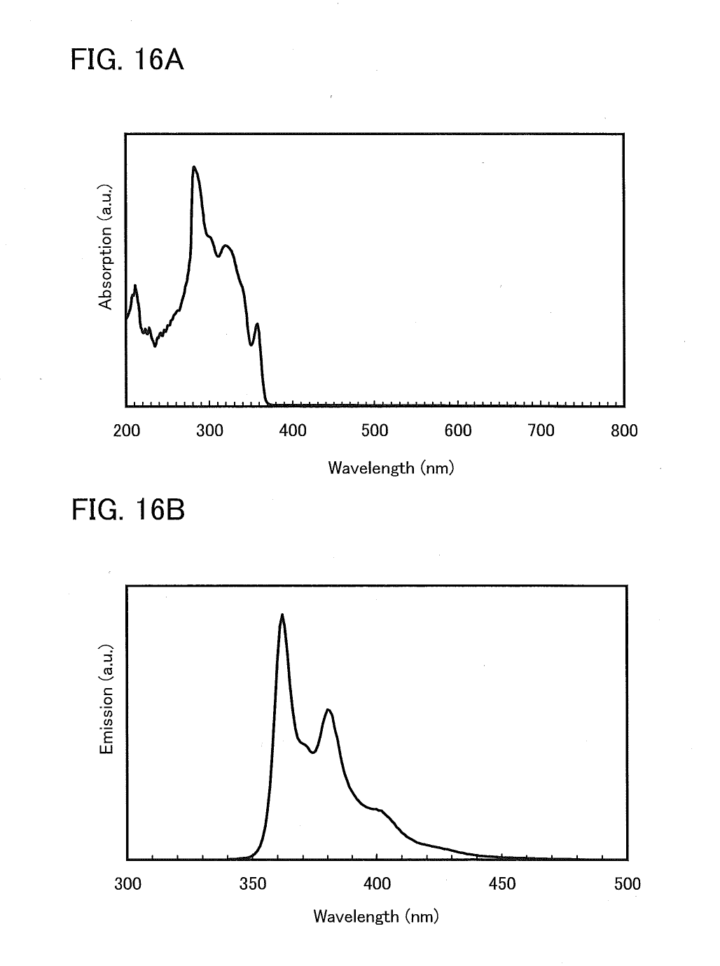

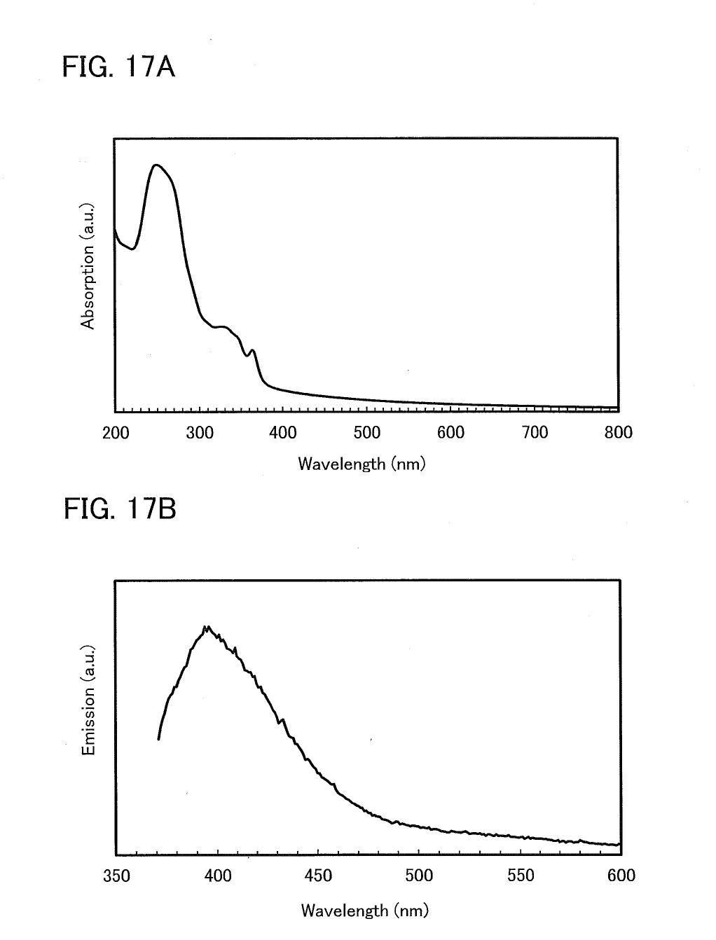

Next, an ultraviolet-visible absorption spectrum (hereinafter, simply referred to as absorption spectrum) and an emission spectrum of 2mDBTPDBQu-II were measured. FIG. 16A shows an absorption spectrum of a toluene solution of 2mDBTPDBQu-II, and FIG. 16B shows an emission spectrum thereof. FIG. 17A shows an absorption spectrum of a thin film of 2mDBTPDBQu-II, and FIG. 17B shows an emission spectrum thereof. The absorption spectrum was measured using an ultraviolet-visible spectrophotometer (V-550, produced by JASCO Corporation). The measurements were performed with samples prepared in such a way that the toluene solution was put in a quartz cell and the thin film was obtained by deposition of 2mDBTPDBQu-II on a quartz substrate by evaporation. The absorption spectrum of the toluene solution of 2mDBTPDBQu-II was obtained by subtracting the absorption spectra of quartz and toluene from that of the toluene solution in a quartz cell, and the absorption spectrum of the thin film of 2mDBTPDBQu-II was obtained by subtracting the absorption spectrum of the quartz substrate from that of the thin film on the quartz substrate. In FIGS. 16A and 16B and FIGS. 17A and 17B, the horizontal axes represent wavelength (nm) and the vertical axes represent intensity (arbitrary unit). In the case of the toluene solution, absorption peaks are observed at 282 nm, 320 nm, and 358 nm, and emission wavelength peaks are observed at 362 nm, 380 nm, and 402 nm (at an excitation wavelength of 327 nm). In the case of the thin film, absorption peaks are observed 250 nm, 264 nm, 325 nm, 344 nm, and 364 nm, and an emission wavelength peak is observed at 395 nm (at an excitation wavelength of 365 nm).

Note that the structure described in this example can be combined as appropriate with any of the structures described in the embodiments or the other examples.

### Example 2

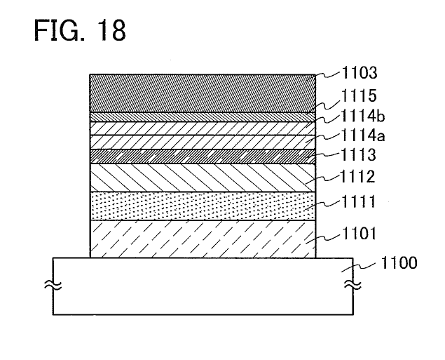

In this example, light-emitting elements of the embodiments of the present invention (a light-emitting element 1 and a light-emitting element 3), and a light-emitting element for comparison (a comparative light-emitting element 2 (reference element 2)) are described with reference to FIG. 18. Chemical formulae of materials used in this example are shown below.

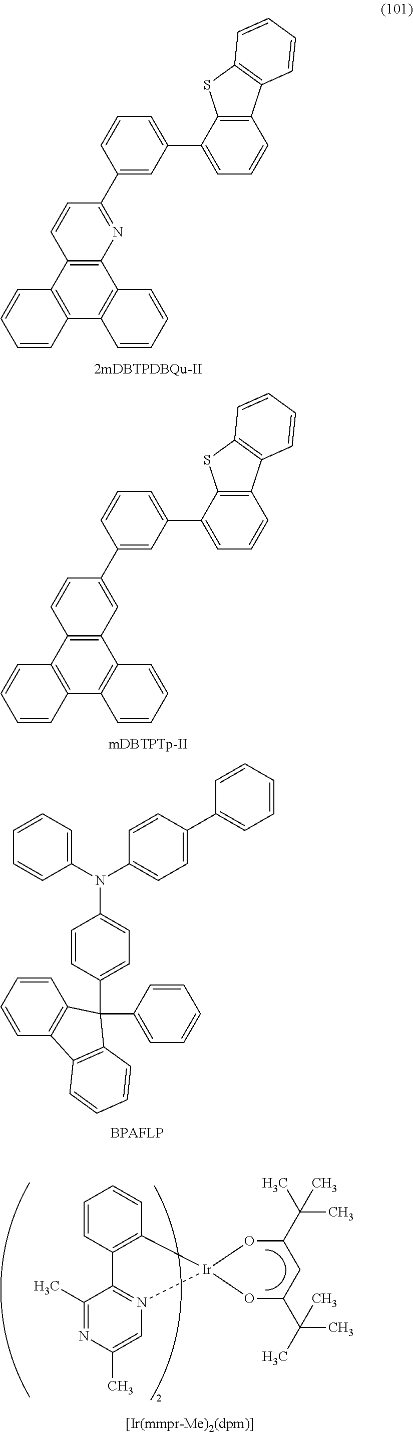

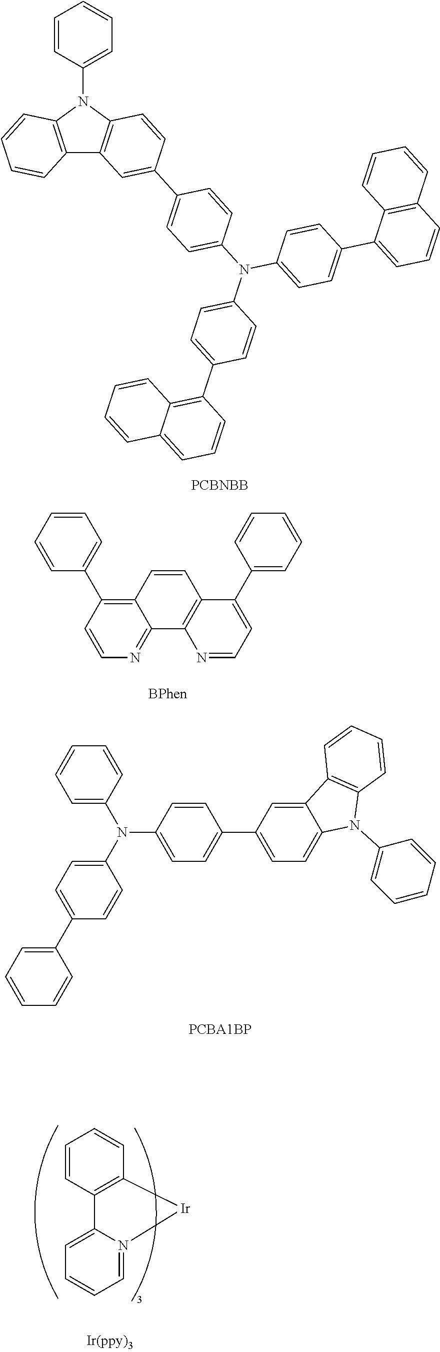

Methods for manufacturing the light-emitting element 1, the comparative light-emitting element 2, and the light-emitting element 3 of this example are described below.

### (Light-Emitting Element 1)

First, over a substrate 1100, an indium oxide-tin oxide containing silicon or silicon oxide (ITO-SiO₂, hereinafter abbreviated to ITSO) was deposited by a sputtering method, whereby a first electrode 1101 was formed. Note that the composition ratio of In₂O₃ to SnO₂ and SiO₂ in the target used was 85:10:5 [wt %]. The thickness of the first electrode 1101 was 110 nm and the electrode area was 2 mm×2 mm. Here, the first electrode 1101 is an electrode that functions as an anode of the light-emitting element.

Next, in pretreatment for forming the light-emitting element over the substrate 1100, UV ozone treatment was performed for 370 seconds after washing of a surface of the substrate with water and baking that was performed at 200° C. for 1 hour.

After that, the substrate was transferred into a vacuum evaporation apparatus where the pressure had been reduced to approximately 10⁻⁴ Pa, and subjected to vacuum baking at 170° C. for 30 minutes in a heating chamber of the vacuum evaporation apparatus, and then the substrate 1100 was cooled down for about 30 minutes.

Then, the substrate 1100 over which the first electrode 1101 was formed was fixed to a substrate holder provided in a vacuum evaporation apparatus so that the surface on which the first electrode 1101 was formed faced downward. The pressure in the vacuum evaporation apparatus was reduced to about 10⁻⁴ Pa. After that, over the first electrode 1101, 4-phenyl-4′-(9-phenylfluoren-9-yl)triphenylamine (abbreviation: BPAFLP) and molybdenum oxide were co-evaporated by an evaporation method, so that a hole-injection layer 1111 was formed. The thickness of the hole-injection layer 1111 was set to 40 nm, and the weight ratio of BPAFLP to molybdenum oxide was adjusted to 4:2 (=BPAFLP:molybdenum oxide). Note that the co-evaporation method refers to an evaporation method in which evaporation is carried out from a plurality of evaporation sources at the same time in one treatment chamber.

Next, on the hole-injection layer 1111, a film of BPAFLP was formed to a thickness of 20 nm, so that a hole-transport layer 1112 was formed.

Further, 2mDBTPDBQu-II synthesized in Example 1, 4,4′-di(1-naphthyl)-4″-(9-phenyl-9H-carbazol-3-yl)triphenylamine (abbreviation: PCBNBB), and bis(3,5-dimethyl-2-phenylpyrazinato)(dipivaloylmethanato)iridium(III) (abbreviation: [Ir(mppr-Me)₂(dpm)]) were deposited by co-evaporation, so that a light-emitting layer 1113 was fanned on the hole-transport layer 1112. Here, the weight ratio of 2mDBTPDBQu-II to PCBNBB and [Ir(mppr-Me)₂(dpm)] was adjusted to 0.8:0.2:0.05 (=2mDBTPDBQu-II:PCBNBB:[Ir(mppr-Me)₂(dpm)]). The thickness of the light-emitting layer 1113 was set to 40 nm.

Further, a film of 2mDBTPDBQu-II was formed to a thickness of 10 nm on the light-emitting layer 1113, so that a first electron-transport layer 1114a was formed.

Then, a film of bathophenanthroline (abbreviation: BPhen) was formed to a thickness of 20 nm on the first electron-transport layer 1114a, so that a second electron-transport layer 1114b was formed.

Further, a film of lithium fluoride (LiF) was formed to a thickness of 1 nm on the second electron-transport layer 1114b using evaporation, so that an electron-injection layer 1115 was formed.

Lastly, an aluminum film was formed to a thickness of 200 nm using evaporation as a second electrode 1103 functioning as a cathode. Thus, the light-emitting element 1 of this example was fabricated.

Note that in all the above evaporation steps, evaporation was performed by a resistance heating method.

### (Comparative Light-Emitting Element 2)

The light-emitting layer 1113 of the comparative light-emitting element 2, which corresponds to the light-emitting layer 1113 of the light-emitting element 1, was formed in such a manner that 4-[3-(triphenylene-2-yl)phenyl]dibenzothiophene (abbreviation: mDBTPTp-II), PCBNBB, and [Ir(mppr-Me)₂(dpm)] were deposited by co-evaporation. The weight ratio of mDBTPTp-II to PCBNBB and [Ir(mppr-Me)₂(dpm)] was adjusted to 0.8:0.2:0.05 (=mDBTPTp-II:PCBNBB:[Ir(mppr-Me)₂(dpm)]). The thickness of the light-emitting layer 1113 was set to 40 nm.

Further, the first electron-transport layer 1114a of the comparative light-emitting element 2, which corresponds to the first electron-transport layer 1114a of the light-emitting element 1, was formed by forming a film of mDBTPTp-II to a thickness of 10 nm. The components other than the light-emitting layer 1113 and the first electron-transport layer 1114a were formed in the same manners as those of the light-emitting element 1.

### (Light-Emitting Element 3)

The light-emitting layer 1113 of the light-emitting element 3, which corresponds to the light-emitting layer 1113 of the light-emitting element 1, was formed in such a manner that 2mDBTPDBQu-II, 4-phenyl-4′-(9-phenyl-9H-carbazol-3-yl)triphenylamine (abbreviation: PCBA1BP), and tris(2-phenylpyridinato-N,C^{2′})iridium(III) (abbreviation: [Ir(ppy)₃]) were deposited by co-evaporation. The weight ratio of 2mDBTPDBQu-II to PCBA1BP and [Ir(ppy)₃] was adjusted to 0.8:0.2:0.06 (=2mDBTPDBQu-II:PCBA1BP:[Ir(ppy)₃]). The thickness of the light-emitting layer 1113 was set to 30 nm.

The components of the light-emitting element 3 other than the light-emitting layer 1113 were formed in the same manner as those of light-emitting element 1.

Table 1 shows element structures of the light-emitting element 1, the comparative light-emitting element 2, and the light-emitting element 3 obtained as described above.

TABLE 1
Structure of the light-emitting elements of Example 2.

| | 1st electrode | HIL ^{a} | HTL ^{b} | light-emitting layer |
|---|---|---|---|---|
| light-emitting | ITSO | BPAFLP:MoOx | BPAFLP | 2mDBTPDBQu-II:PCBNBB:[Ir(mppr-Me)₂(dpm)] |
| element 1 | 110 nm | 4:2 | 20 nm | 0.8:0.2:0.05 |
| | | 40 nm | | 40 nm |
| comparative | | | | mDBTPTp-II:PCBNBB:[Ir(mppr-Me)₂(dpm)] |
| light-emitting | | | | 0.8:0.2:0.05 |
| element 2 ^{e} | | | | 40 nm |
| light-emitting | | | | 2mDBTPDBQu-II:PCBA1BP:[Ir(ppy)₃] |
| element 3 | | | | 0.8:0.2:0.05 |
| | | | | 40 nm |

| | 1st ETL ^{c} | 2nd ETL | EIL ^{d} | 2nd electrode | Note |
|---|---|---|---|---|---|
| light-emitting | 2mDBTPDBQu-II | BPhen | LiF | Al | orange |
| element 1 | 10 nm | 20 nm | 1 nm | 200 nm | emissive |
| comparative | mDBTPTp-II | | | | orange |
| light-emitting | 10 nm | | | | emissive |
| element 2 ^{e} | | | | | |
| light-emitting | 2mDBTPDBQu-II | | | | green |
| element 3 | 10 nm | | | | emissive |

^{a} Hole-injection layer.
^{b} Hole-transport layer.
^{c} Electron-transport layer.
^{d} Electron-injection layer.
^{e} Reference element 2.

The light-emitting element 1, the comparative light-emitting element 2, and the light-emitting element 3 were sealed with a glass substrate in a glove box under a nitrogen atmosphere so as not to be exposed to the air (a sealant was applied onto an outer edge of each element and heat treatment was performed at 80° C. for 1 hour at the time of sealing). Then, operating characteristics of the light-emitting element 1 were measured. Note that the measurements were carried out at room temperature (in the atmosphere kept at 25° C.).

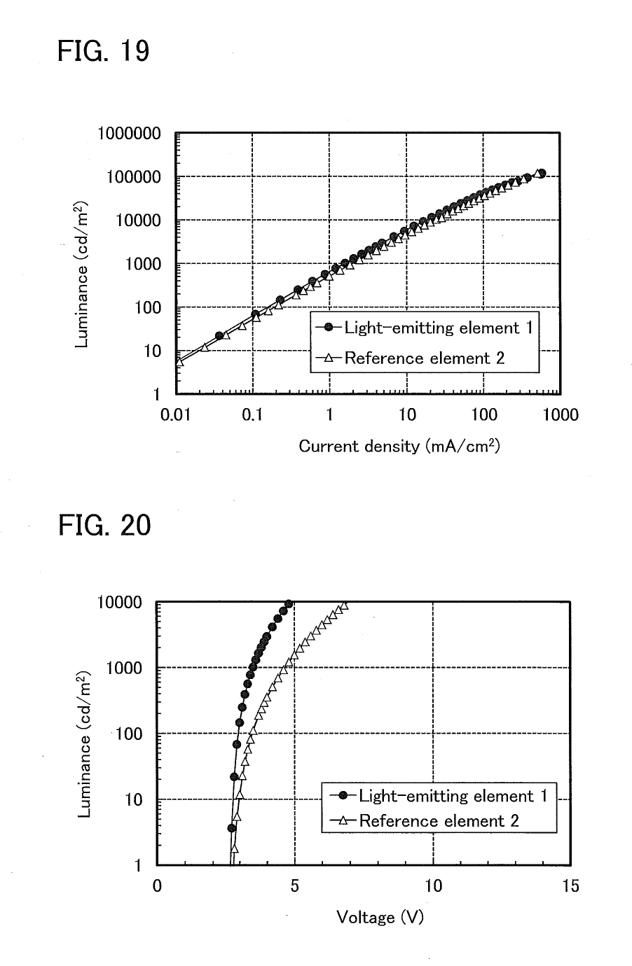

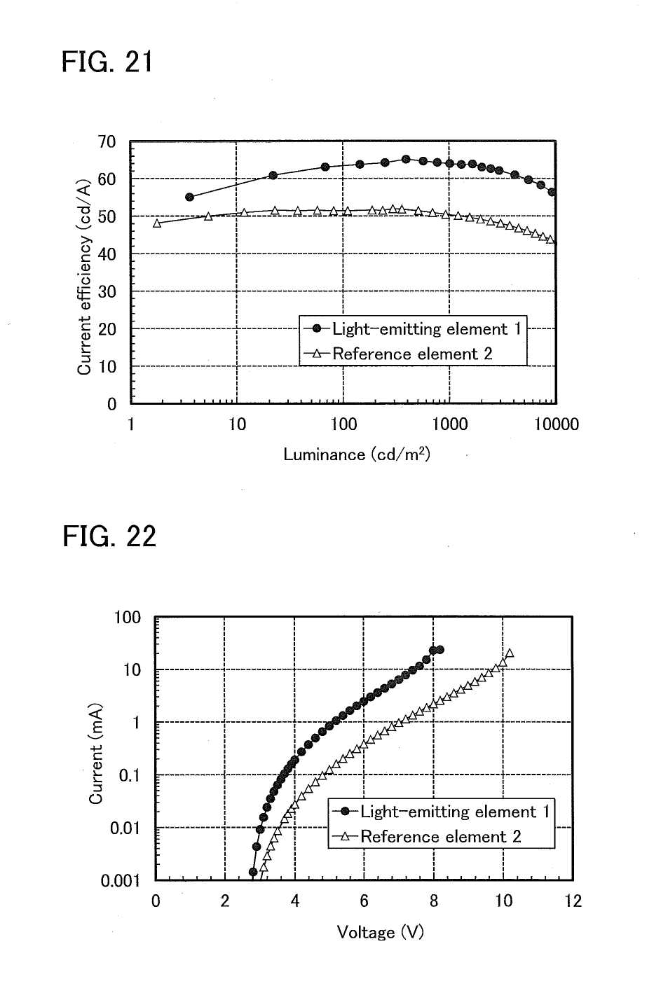

FIG. 19 shows luminance versus current density characteristics of the light-emitting element 1 and the comparative light-emitting element 2. In FIG. 19, the horizontal axis represents the current density (mA/cm²) and the vertical axis represents the luminance (cd/m²). FIG. 20 shows luminance versus voltage characteristics of the light-emitting element 1 and the comparative light-emitting element 2. In FIG. 20, the horizontal axis represents the voltage (V), and the vertical axis represents the luminance (cd/m²). FIG. 21 shows current efficiency versus luminance characteristics of the light-emitting element 1 and the comparative light-emitting element 2. In FIG. 21, the horizontal axis represents the luminance (cd/m²) and the vertical axis represents the current efficiency (cd/A). FIG. 22 shows current versus voltage characteristics of the light-emitting element 1 and the comparative light-emitting element 2. In FIG. 22, the horizontal axis represents the voltage (V) and the vertical axis represents the current (mA).

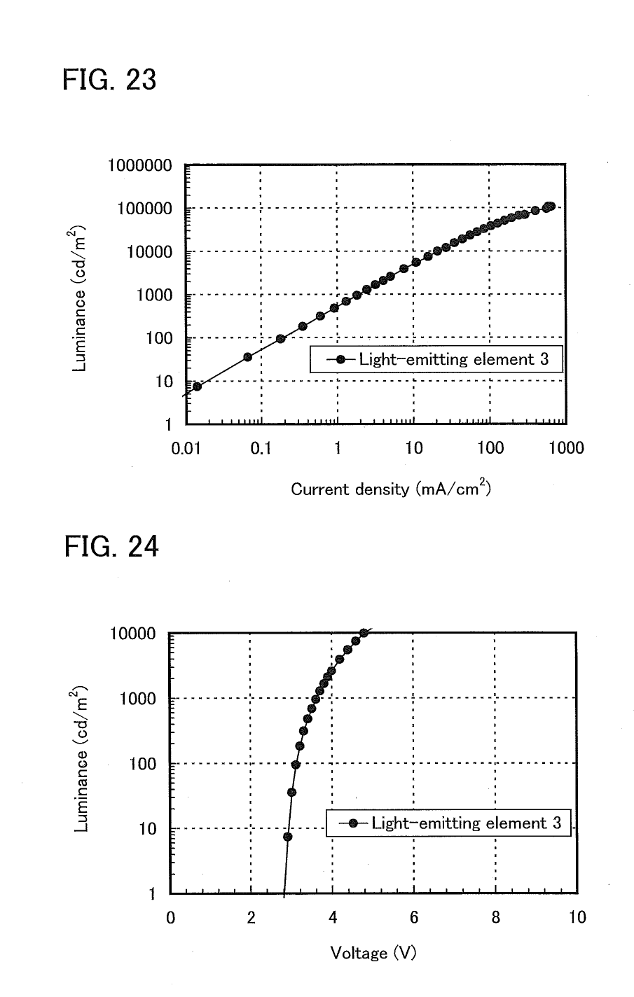

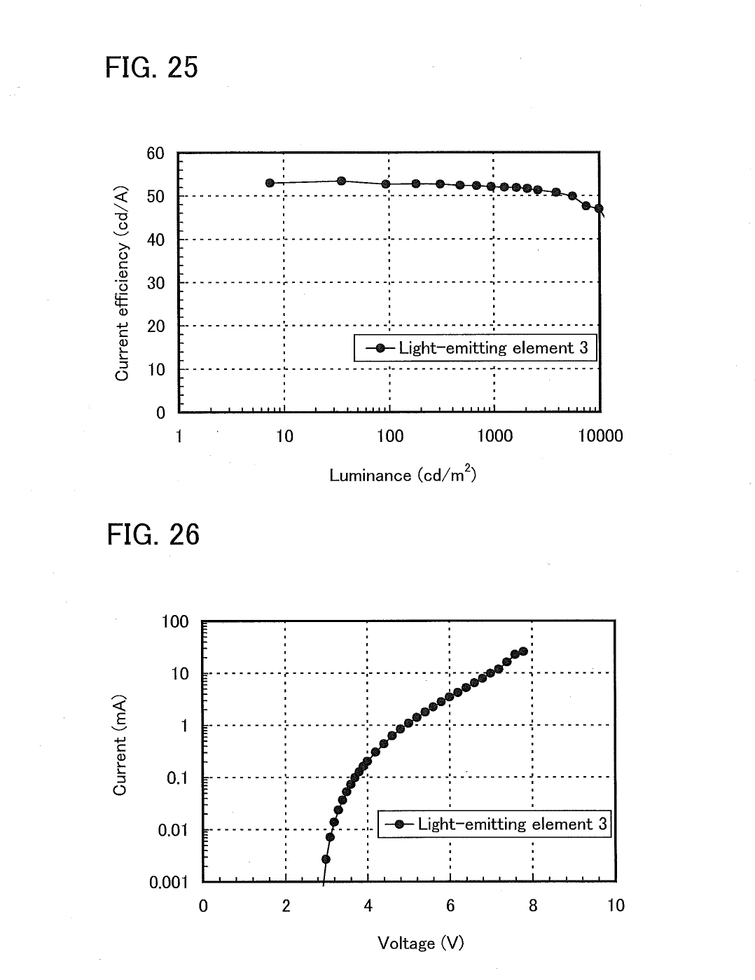

FIG. 23 shows luminance versus current density characteristics of the light-emitting element 3. In FIG. 23, the horizontal axis represents the current density (mA/cm²) and the vertical axis represents the luminance (cd/m²). FIG. 24 shows luminance versus voltage characteristics of the light-emitting element 3. In FIG. 24, the horizontal axis represents the voltage (V) and the vertical axis represents the luminance (cd/m²). FIG. 25 shows current efficiency versus luminance characteristics of the light-emitting element 3. In FIG. 25, the horizontal axis represents the luminance (cd/m²) and the vertical axis represents the current efficiency (cd/A). FIG. 26 shows current efficiency versus voltage characteristics of the light-emitting element 3. In FIG. 26, the horizontal axis represents the voltage (V) and the vertical axis represents the current (mA).

Table 2 shows voltage (V), current density (mA/cm²), CIE chromaticity coordinates (x, y), current efficiency (cd/A), and external quantum efficiency (%) of each light-emitting element at a luminance of around 1000 cd/m².

TABLE 2
Characteristics of the light-emitting elements
of Example 2 at ca. 1000 cd/m².

| | | current | | lumi- | current | external |
|---|---|---|---|---|---|---|
| | volt- | density | chroma- | nance | effi- | quantum |
| | age | (mA/ | ticity | (cd/ | ciency | efficiency |
| | (V) | cm²) | (x, y) | m²) | (cd/A) | (%) |
| light- | 3.5 | 1.6 | (0.54, 0.46) | 1020 | 64 | 24 |
| emitting | | | | | | |
| element 1 | | | | | | |
| comparative | 4.6 | 1.8 | (0.53, 0.46) | 930 | 50 | 19 |
| light- | | | | | | |
| emitting | | | | | | |
| element 2 ^{a} | | | | | | |
| light- | 3.6 | 1.8 | (0.34, 0.61) | 950 | 52 | 15 |
| emitting | | | | | | |
| element 3 | | | | | | |

^{a} Reference element 2.

As shown in Table 2, the CIE chromaticity coordinates (x, y) of the light-emitting element 1 were (0.54, 0.46) at a luminance of 1020 cd/m². The CIE, chromaticity coordinates (x, y) of the comparative light-emitting element 2 were (0.53, 0.46) at a luminance of 930 cd/m². The CIE chromaticity coordinates (x, y) of the light-emitting element 3 were (0.34, 0.61) at a luminance of 950 cd/m².

According to the Table 2, the current efficiencies of the light-emitting element 1 at a luminance of 1020 cd/m², of the comparative light-emitting element 2 at a luminance of 930 cd/m², and of the light-emitting element 3 at a luminance of 950 cd/m² were 64 cd/A, 50 cd/A, and 52 cd/A, respectively. Further, the external quantum efficiencies of the light-emitting element 1 at a luminance of 1020 cd/m², of the comparative light-emitting element 2 at a luminance of 930 cd/m², and of the light-emitting element 3 at a luminance of 950 cd/m² were 24%, 19%, and 15%, respectively.

As described above, the luminance versus voltage characteristics, the current efficiency versus luminance characteristics, and the current versus voltage characteristics differ between the light-emitting element 1 of one embodiment of the present invention and the comparative light-emitting element 2. It is found that the light-emitting element 1 is driven at lower voltage and has higher current efficiency than the comparative light-emitting element 2. A structure difference between the compounds used as host materials in the light-emitting layers is as follows: the compound used for the light-emitting element 1 has a dibenzo[f,h]quinoline ring while the compound used for the comparative light-emitting element 2 has a triphenylene ring.

Thus, the light-emitting element of one embodiment of the present invention contains an organic compound having a dibenzo[f,h]quinoline ring, an arylene group, and a hole-transport skeleton, and thus has excellent luminance versus voltage characteristics, current efficiency versus luminance characteristics, and current versus voltage characteristics.

According to Table 2, the light-emitting element 1 has higher current efficiency and higher external quantum efficiency than the comparative light-emitting element 2. The light-emitting element of one embodiment of the present invention contains the organic compound having the dibenzo[f,h]quinoline ring, an arylene group, and a hole-transport skeleton, and thus is effective in achieving high current efficiency and high external quantum efficiency.

Note that the structure described in this example can be combined as appropriate with any of the structures described in the embodiments or the other examples.

### Example 3

In this example, a method of synthesizing 2mDBTBPDBQu-II represented by the following structural formula (109) is described.

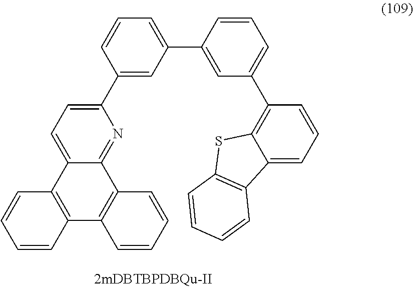 [SMILES: c1cc(-c2cccc(-c3cccc4c3sc3ccccc34)c2)cc(-c2ccc3c4ccccc4c4ccccc4c3n2)c1]

<<Synthesis of 2mDBTBPDBQu-II>>

A synthesis scheme of 2mDBTBPDBQu-II is shown in (F-1).

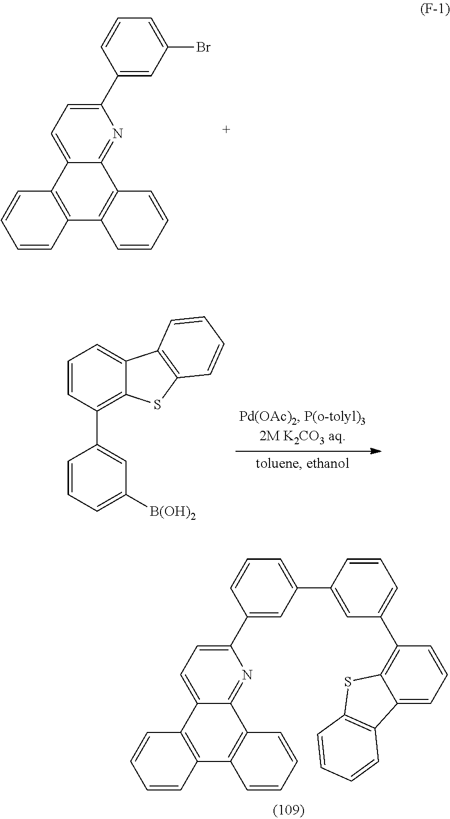 [SMILES: Brc1cccc(-c2ccc3c4ccccc4c4ccccc4c3n2)c1 ; "+" ; OB(O)c1cccc(-c2cccc3c2sc2ccccc23)c1 ; c1cc(-c2cccc(-c3cccc4c3sc3ccccc34)c2)cc(-c2ccc3c4ccccc4c4ccccc4c3n2)c1]

In a 50-mL three-neck flask were put 0.56 g (1.5 mmol) of 2-(3-bromophenyl)dibenzo[f,h]quinoline, 0.46 g (1.5 mmol) of 3-(dibenzothiophen-4-yl)phenylboronic acid, 58 mg (0.19 mmol) of tri(ortho-tolyl)phosphine, 15 mL of toluene, 1.5 mL of ethanol, and 1.5 mL of a 2M aqueous solution of potassium carbonate. The mixture was degassed by being stirred under reduced pressure, and the air in the flask was replaced with nitrogen. To the mixture, 17 mg (77 μmol) of palladium(II) acetate was added, and the mixture was stirred at 80° C. under nitrogen stream for 9 hours. After predetermined time, water and toluene were added to this mixture, and the resulting solid was collected by suction filtration. A toluene solution of the obtained solid was suction-filtered through alumina and Celite, and the filtrate was concentrated to give a yellow solid. Methanol was added to the solid, the resulting suspension was irradiated with ultrasonic waves, and the solid was collected by suction filtration, so that the object of the synthesis was obtained as 0.52 g of white powder in 63% yield.

Then, 0.53 g of the obtained white powder of 2mDBTBPDBQu-II was purified by a train sublimation method. In the purification, 2mDBTBPDBQu-II was heated at 280° C. for 15 hours under the conditions where the pressure was 3.2 Pa and the argon flow was 5.0 mL/min. After the purification, 0.43 g of a white powder of 2mDBTBPDBQu-II was obtained at a collection rate of 80%.

Nuclear magnetic resonance (¹H NMR) spectroscopy identified this compound as 2mDBTBPDBQu-II, which was the objective substance.

¹H NMR data of the obtained substance are as follows: ¹H NMR (CDCl₃, 300 MHz): δ=7.43-7.51 (m, 2H), 7.60-7.85 (m, 12H), 8.13 (d, J=8.7 Hz, 1H), 8.18-8.23 (m, 3H), 8.35 (d, J=7.8 Hz, 1H), 8.59-8.71 (m, 4H), 8.94 (d, J=8.7 Hz, 1H), 9.58 (dd, J=1.5 Hz, 8.4 Hz, 1H).

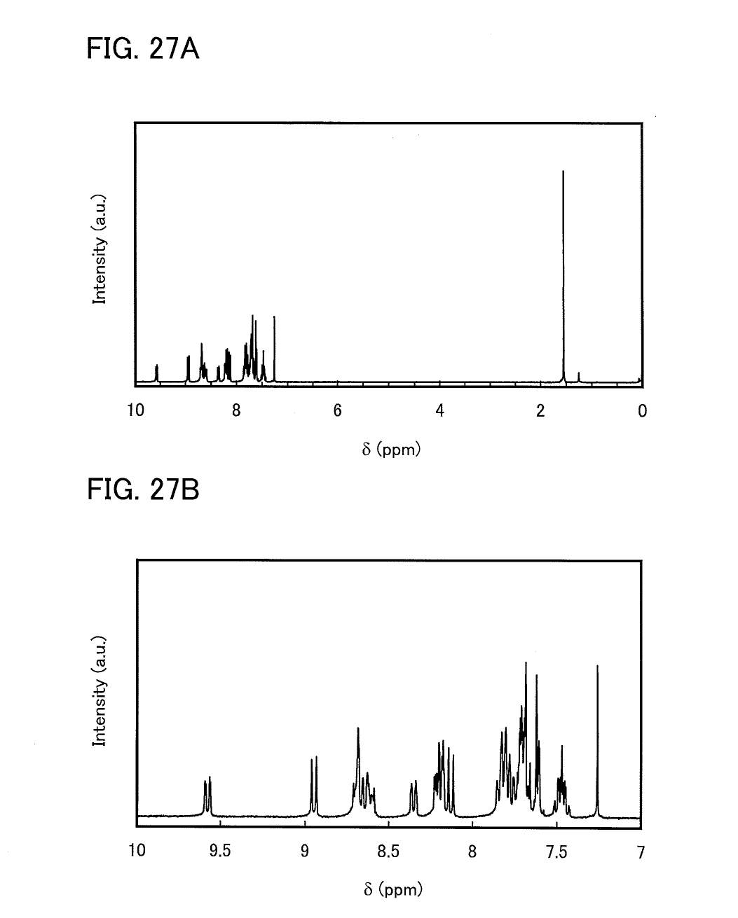

FIGS. 27A and 27B are ¹H NMR charts. Note that FIG. 27B is a chart showing an enlarged part of FIG. 27A in the range of 7.0 ppm to 10.0 ppm.

Next, 2mDBTBPDBQu-II obtained in this example was analyzed by liquid chromatography mass spectrometry (LC/MS).

The LC/MS analysis was carried out with Acquity UPLC (produced by Waters Corporation) and Xevo G2 T of MS (produced by Waters Corporation).

In the MS analysis, ionization was carried out by an electrospray ionization (ESI) method. At this time, the capillary voltage and the sample cone voltage were set to 3.0 kV and 30 V, respectively, and detection was performed in a positive mode. A component which underwent the ionization under the above-mentioned conditions was made to collide with an argon gas in a collision cell to dissociate into product ions. Energy (collision energy) for the collision with argon was 70 eV. The range of the mass-to-charge ratio to be measured was m/z=100 to 1200.

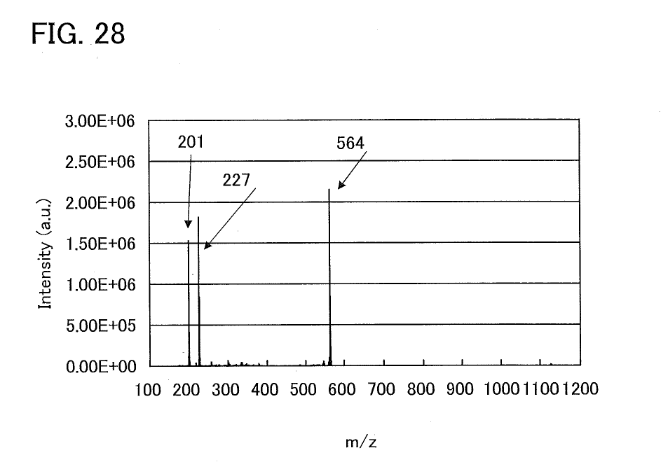

FIG. 28 shows a mass spectrum obtained from the MS analysis. The results in FIG. 28 shows that as for 2mDBTBPDBQu-II obtained in this example, peaks of product ions are detected mainly around m/z=201 and m/z=227, and a peak derived from a precursor ion is detected around m/z=564.

The results in FIG. 28 show characteristics derived from 2mDBTBPDBQu-II and therefore can be regarded as important data for identifying 2mDBTBPDBQu-II contained in the mixture.

For example, the measurement results indicate that the peak around m/z=201 is derived from a radical cation of a fragment (C₁₆H₉) resulting from the dissociation of nitrogen and carbon from the 1-position and 2-position of the dibenzo[f,h]quinoline ring, respectively, as well as hydrogen. The measurement results also indicate that the peak around m/z=227 is derived from a radical cation of fragment (C₁₇H₁₀N) having a dibenzo[f,h]quinoline ring.

That is, in the case where a substituent is bonded to the 2-position of the dibenzo[f,h]quinoline ring, peaks are easily detected around m/z=227 corresponding to a fragment which is resulted from the dissociation of the substituent from the ring and around m/z=201 corresponding a fragment after subtraction of a molecular weight of 26 from m/z=227. Note that the substituent here refers to a portion represented by Ar-A in the general formula (G1).

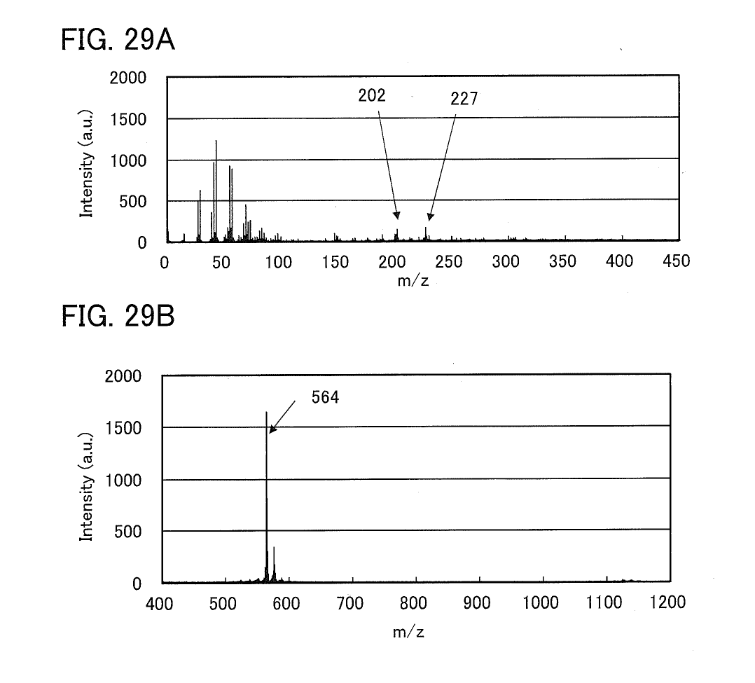

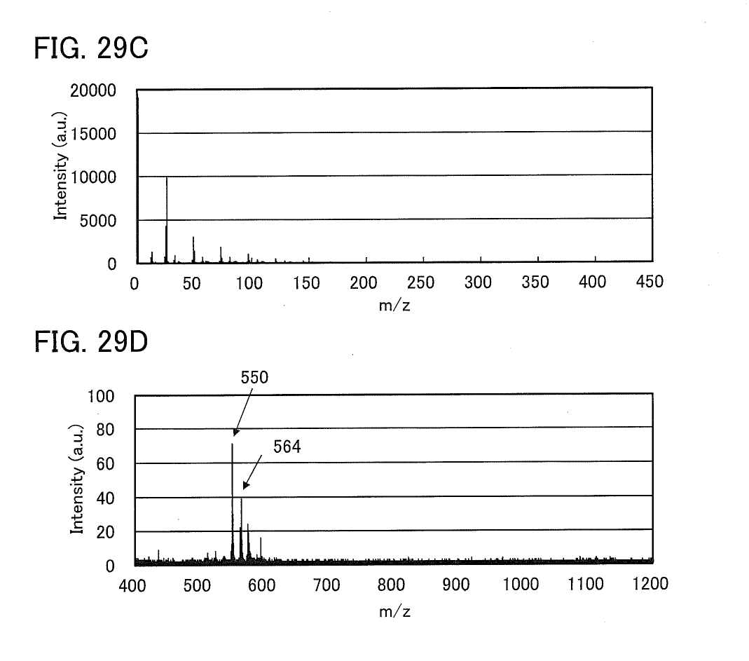

FIGS. 29A to 29D show qualitative mass spectra of 2mDBTBPDBQu-II obtained in this example, which were obtained with a time-of-flight secondary ion mass spectrometer (ToF-SIMS).

FIG. 29A shows measurement results of positive ions. In FIG. 29A, the horizontal axis represents m/z ranging from 0 to 450 and the vertical axis represents intensity (arbitrary unit). FIG. 29B shows measurement results of positive ions. In FIG. 29B, the horizontal axis represents m/z ranging from 400 to 1200 and the vertical axis represents intensity (arbitrary unit). FIG. 29C shows measurement results of negative ions. In FIG. 29C, the horizontal axis represents m/z ranging from 0 to 450 and the vertical axis represents intensity (arbitrary unit). FIG. 29D shows measurement results of negative ions. In FIG. 29D, the horizontal axis represents m/z ranging from 400 to 1200 and the vertical axis represents intensity (arbitrary unit).

TOF SIMS 5 (produced by ION-TOF GmbH) was used as a measurement apparatus, and Bi₃²⁺ was used as a primary ion source. Note that irradiation with primary ions was performed with a pulse width of 11.3 ns. The irradiation amount was greater than or equal to 8.2×10¹⁰ ions/cm² and less than or equal to 6.7×10¹¹ ions/cm², the acceleration voltage was 25 keV, and the current value was 0.2 pA. Powder of 2mDBTBPDBQu-II was used as a sample in the measurement.

The results in FIGS. 29A and 29B show that 2mDBTBPDBQu-II that can be used for a light-emitting element of one embodiment of the present invention mainly gives peaks of product ions around m/z=202 and m/z=227, and a peak derived from a precursor ion around m/z=564.

The results in FIGS. 29C and 29D show that 2mDBTBPDBQu-II that can be used for a light-emitting element of one embodiment of the present invention mainly gives a peak of a product ion around m/z=550, and a peak derived from a precursor ion around m/z=564.

The results in FIGS. 29A to 29D show characteristics derived from 2mDBTBPDBQu-II and therefore can be regarded as important data for identifying 2mDBTBPDBQu-II contained in the mixture.

For example, the measurement results of positive ions shown in FIGS. 29A and 29B indicate that the peak of the product ion of 2mDBTBPDBQu-II detected around m/z=202 is derived from a radical cation of a fragment (C₁₆H₉) resulting from the dissociation of nitrogen and carbon, from the 1-position and 2-position of a dibenzo[f,h]quinoline ring, respectively, as well as hydrogen. The measurement results also indicate that the peak of the product ion of 2mDBTBPDBQu-II detected around m/z=227 is derived from a radical cation of a fragment (C₁₇H₁₀N) having a dibenzo[f,h]quinoline ring.

That is, in the case where a substituent is bonded to the 2-position of the dibenzo[f,h]quinoline ring, peaks are easily detected around m/z=227 corresponding to a fragment which is resulted from the dissociation of the substituent from the ring and around m/z=202 corresponding a fragment after subtraction of molecular weight of 25 from m/z=227. Note that the substituent here refers to a portion represented by Ar-A in the general formula (G1).

The measurement results of negative ions shown in FIGS. 29C and 29D indicate that the peak of the product ion of 2mDBTBPDBQu-II, which is detected around m/z=550, is derived from a fragment (C₄₁H₂₆S) in which nitrogen is dissociated from the 1-position.

As described above, portions which are easily dissociated from a precursor ion are detected as product ions in the LC/MS analysis and ToF-SIMS analysis. The product ions which are particularly easy to detect are fragments derived from the dibenzo[f,h]quinoline ring, and the like.

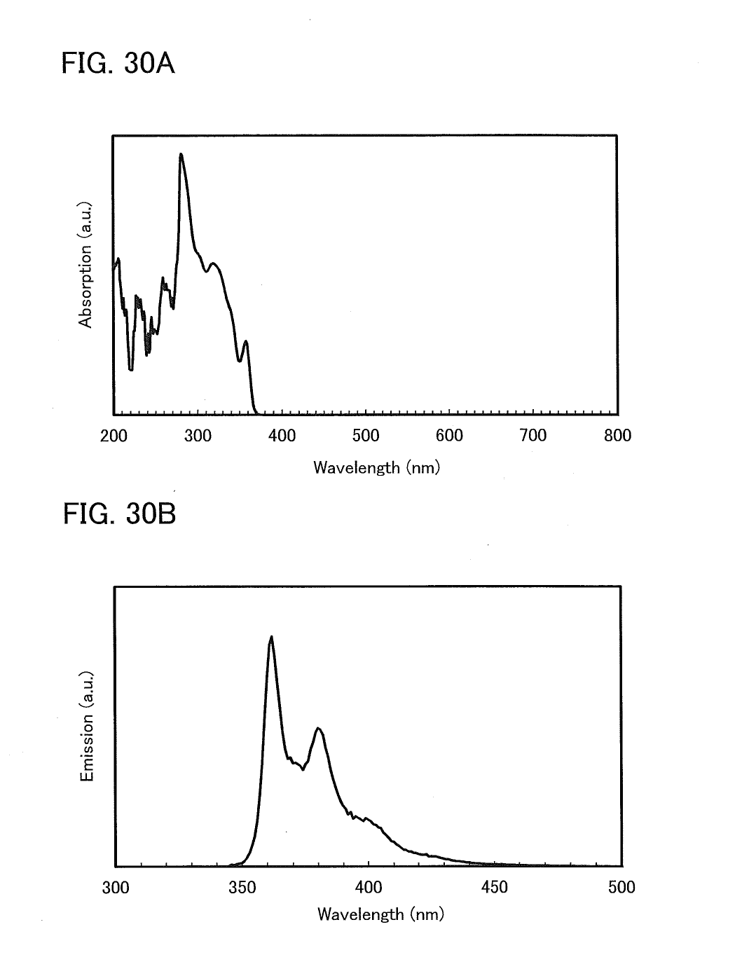

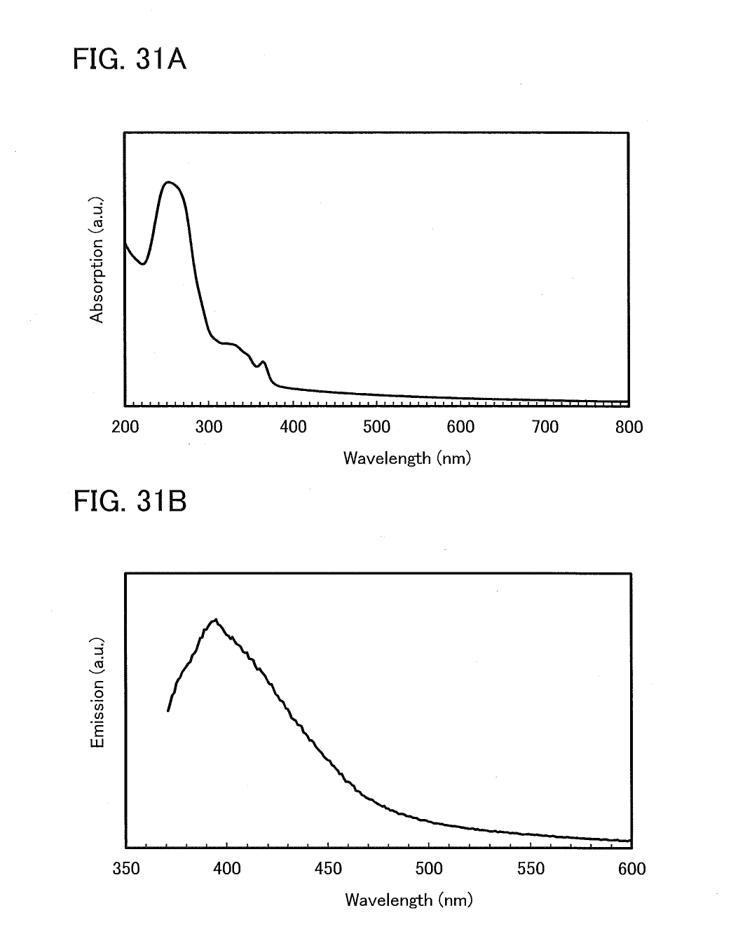

Next, an ultraviolet-visible absorption spectrum (hereinafter, simply referred to as absorption spectrum) and an emission spectrum of 2mDBTBPDBQu-II were measured. FIG. 30A shows an absorption spectrum of a toluene solution of 2mDBTBPDBQu-II, and FIG. 30B shows an emission spectrum thereof. FIG. 31A shows an absorption spectrum of a thin film of 2mDBTBPDBQu-II, and FIG. 31B shows an emission spectrum thereof. The absorption spectrum was measured using an ultraviolet-visible spectrophotometer (V-550, produced by JASCO Corporation). The measurements were performed with samples prepared in such a way that the toluene solution was put in a quartz cell and the thin film was obtained by deposition of 2mDBTBPDBQu-II on a quartz substrate by evaporation. The absorption spectrum of the toluene solution of 2mDBTBPDBQu-II was obtained by subtracting the absorption spectra of quartz and toluene from that of the toluene solution in a quartz cell, and the absorption spectrum of the thin film of 2mDBTBPDBQu-II was obtained by subtracting the absorption spectrum of the quartz substrate from that the thin film on the quartz substrate. In FIGS. 30A and 30B and FIGS. 31A and 31B, the horizontal axes represent wavelength (nm) and the vertical axes represent intensity (arbitrary unit). In the case of the toluene solution, absorption peaks are observed 281 nm, 319 nm, and 358 nm, and emission wavelength peaks are observed at 362 nm, 380 nm, and 399 nm (at an excitation wavelength of 339 nm). In the case of the thin film, absorption peaks are observed 253 nm, 321 nm, and 364 nm, and an emission wavelength peak is observed at 395 nm (at an excitation wavelength of 365 nm).

Note that the structure described in this example can be combined as appropriate with any of the structures described in the embodiments or the other examples.

### Example 4

In this example, a light-emitting element of one embodiment of the present invention (a light-emitting element 4) and a light-emitting element for comparison (a comparative light-emitting element 5 (reference element 5)), which are different from the light-emitting elements described in Example 2, are described with reference to FIG. 18. Chemical formulae of materials used in this example are shown below.

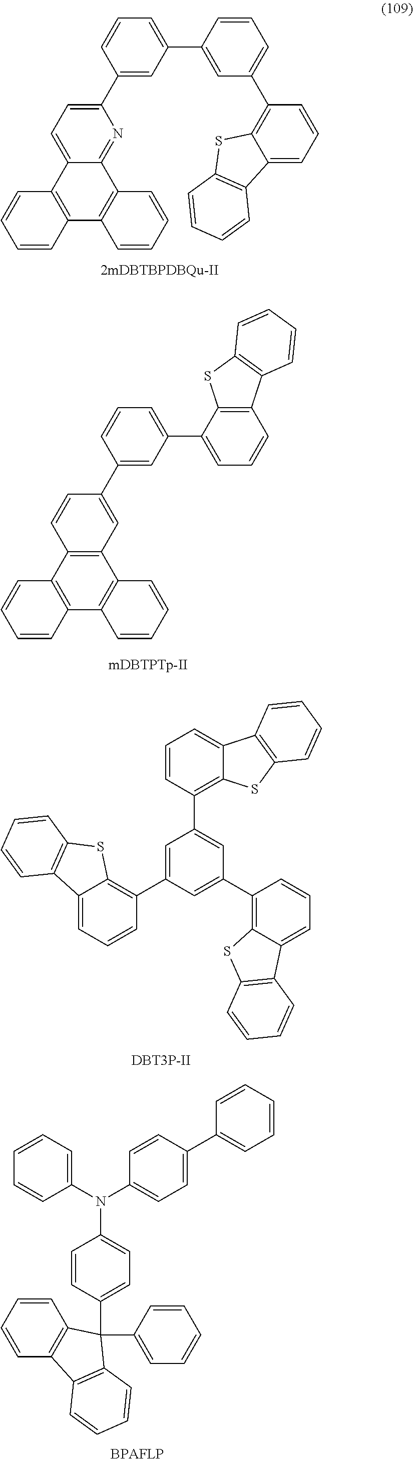

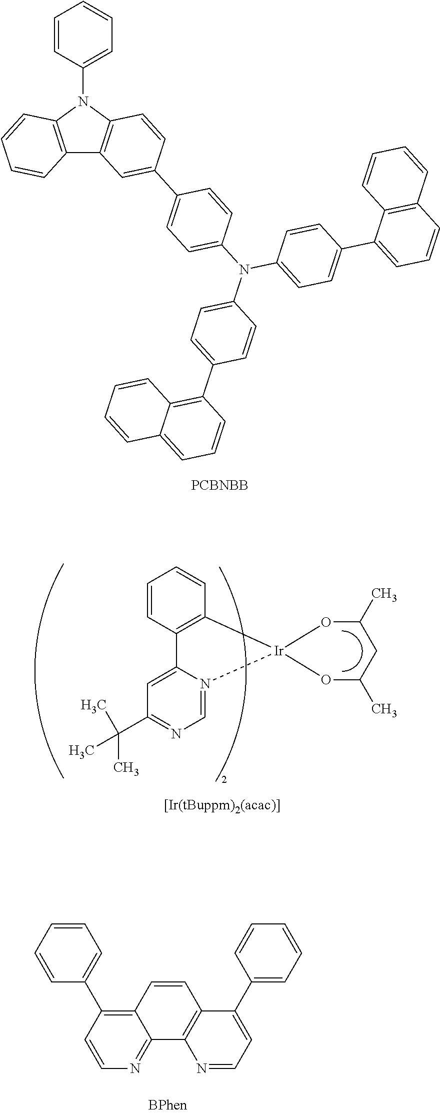

Methods for manufacturing the light-emitting element 4 and the comparative light-emitting element 5 of this example are described below.

### (Light-Emitting Element 4)

First, over a substrate 1100, an indium oxide-tin oxide containing silicon or silicon oxide (ITO-SiO₂, hereinafter abbreviated to ITSO) was deposited by a sputtering method, whereby a first electrode 1101 was formed. Note that the composition ratio of In₂O₃ to SnO₂ and SiO₂ in the target used was 85:10:5 [wt %]. The thickness of the first electrode 1101 was 110 nm and the electrode area was 2 mm×2 mm. Here, the first electrode 1101 is an electrode that functions as an anode of the light-emitting element.

Next, in pretreatment for forming the light-emitting element over the substrate 1100, UV ozone treatment was performed for 370 seconds after washing of a surface of the substrate with water and baking that was performed at 200° C. for 1 hour.

After that, the substrate was transferred into a vacuum evaporation apparatus where the pressure had been reduced to approximately 10⁻⁴ Pa, and subjected to vacuum baking at 170° C. for 30 minutes in a heating chamber of the vacuum evaporation apparatus, and then the substrate 1100 was cooled down for about 30 minutes.

Then, the substrate 1100 over which the first electrode 1101 was formed was fixed to a substrate holder provided in a vacuum evaporation apparatus so that the surface on which the first electrode 1101 was formed faced downward. The pressure in the vacuum evaporation apparatus was reduced to about 10⁻⁴ Pa. After that, over the first electrode 1101, 1,3,5-tri(dibenzothiophen-4-yl)-benzene (abbreviation: DBT3P-II) and molybdenum oxide were co-evaporated by an evaporation method, so that a hole-injection layer 1111 was formed. The thickness of the hole-injection layer 1111 was set to 40 nm, and the weight ratio of DBT3P-II to molybdenum oxide was adjusted to 4:2 (=DBT3P-II:molybdenum oxide).

Next, on the hole-injection layer 1111, a film of BPAFLP was formed to a thickness of 20 nm, so that a hole-transport layer 1112 was formed.

Further, 2mDBTBPDBQu-II synthesized in Example 3, 4,4′-di(1-naphthyl)-4″-(9-phenyl-9H-carbazol-3-yl)triphenylamine (abbreviation: PCBNBB), and (acetylacetonato)bis(6-tert-butyl-4-phenylpyrimidinato)iridium(III) (abbreviation: [Ir(tBuppm)₂(acac)]) were deposited by co-evaporation, so that the light-emitting layer 1113 was formed on the hole-transport layer 1112. The weight ratio of 2mDBTBPDBQu-II to PCBNBB and [Ir(tBuppm)₂(acac)] was adjusted to 0.8:0.2:0.05 (=2mDBTBPDBQu-II:PCBNBB:[Ir(tBuppm)₂(acac)]). The thickness of the light-emitting layer 1113 was set to 40 nm.

Further, a film of 2mDBTBPDBQu-II was formed to a thickness of 10 nm on the light-emitting layer 1113, so that a first electron-transport layer 1114a was formed.

Then, a film of bathophenanthroline (abbreviation: BPhen) was formed to a thickness of 20 nm on the first electron-transport layer 1114a, so that a second electron-transport layer 1114b was formed.

Further, a film of lithium fluoride (LiF) was formed to a thickness of 1 nm on the second electron-transport layer 1114b using evaporation, so that an electron-injection layer 1115 was formed.

Lastly, an aluminum film was formed to a thickness of 200 nm using evaporation as a second electrode 1103 functioning as a cathode. Thus, the light-emitting element 4 of this example was fabricated.

Note that in all the above evaporation steps, evaporation was performed by a resistance heating method.

### (Comparative Light-Emitting Element 5)

The light-emitting layer 1113 of the comparative light-emitting element 5, which corresponds to the light-emitting layer 1113 of the light-emitting element 4, was formed in such a manner that 4-[3-(triphenylene-2-yl)phenyl]dibenzothiophene (abbreviation: mDBTPTp-II), PCBNBB, and [Ir(tBuppm)₂(acac)] were deposited by co-evaporation. The weight ratio of mDBTPTp-II to PCBNBB and [Ir(tBuppm)₂(acac)] was adjusted to 0.8:0.2:0.05 (=mDBTPTp-II:PCBNBB:[Ir(tBuppm)₂(acac)]). The thickness of the light-emitting layer 1113 was set to 40 nm.

Further, the first electron-transport layer 1114a of the comparative light-emitting element 5, which corresponds to the first electron-transport layer 1114a of the light-emitting element 4, was formed by forming a film of mDBTPTp-II to a thickness of 10 nm. The components other than the light-emitting layer 1113 and the first electron-transport layer 1114a were formed in the same manners as those of the light-emitting element 4.

Table 3 shows element structures of the light-emitting element 4 and the comparative light-emitting element 5 obtained as described above.

TABLE 3
Structure of the light-emitting elements of Example 4.

| | 1st electrode | HIL ^{a} | HTL ^{b} | light-emitting layer |
|---|---|---|---|---|
| light-emitting | ITSO | DBT3P-II:MoOx | BPAFLP | 2mDBTBPDBQu-II:PCBNBB:Ir(tBuppm)₂(acac) |
| element 4 | 110 nm | 4:2 | 20 nm | 0.8:0.2:0.05 |
| | | 40 nm | | 40 nm |
| comparative | | | | mDBTPTp-II:PCBNBB:Ir(tBuppm)₂(acac) |
| light-emitting | | | | 0.8:0.2:0.05 |
| element 5 ^{e} | | | | 40 nm |

| | 1st ETL ^{c} | 2nd ETL | EIL ^{d} | 2nd electrode | Note |
|---|---|---|---|---|---|
| light-emitting | 2mDBTBPDBQu-II | BPhen | LiF | Al | yellow-green |
| element 4 | 10 nm | 20 nm | 1 nm | 200 nm | emissive |
| comparative | mDBTPTp-II | | | | yellow-green |
| light-emitting | 10 nm | | | | emissive |
| element 5 ^{e} | | | | | |

^{a} Hole-injection layer.
^{b} Hole-transport layer.
^{c} Electron-transport layer.
^{d} Electron-injection layer.
^{e} Reference element 5.

The light-emitting element 4 and the comparative light-emitting element 5 were sealed with a glass substrate in a glove box under a nitrogen atmosphere so as not to be exposed to the air (a sealant was applied onto an outer edge of each element and heat treatment was performed at 80° C. for 1 hour at the time of sealing). Then, operating characteristics of the light-emitting element 1 were measured. Note that the measurements were carried out at room temperature (in the atmosphere kept at 25° C.).

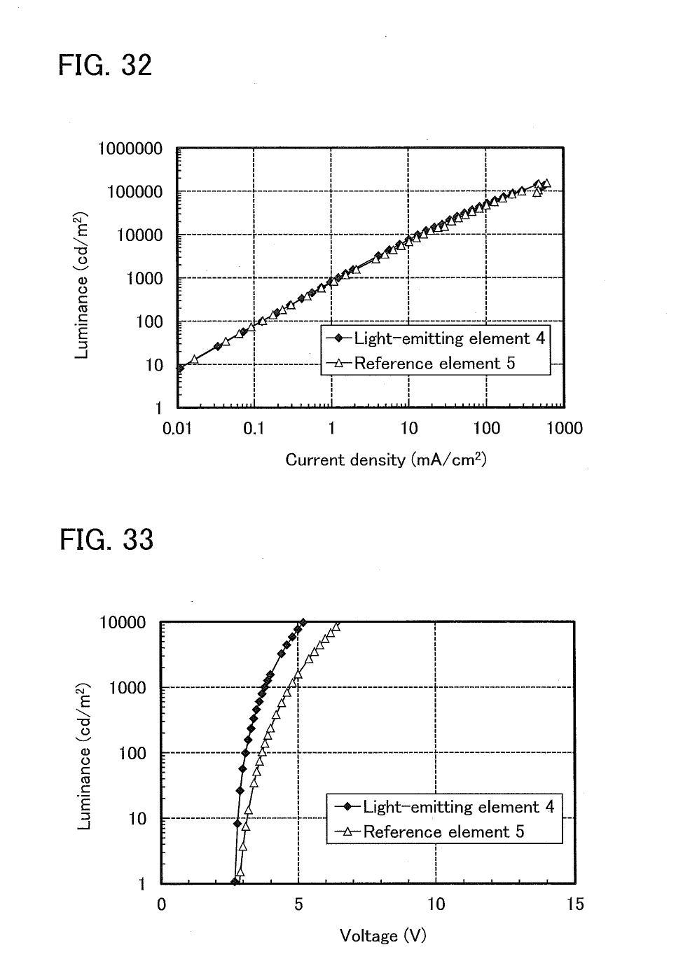

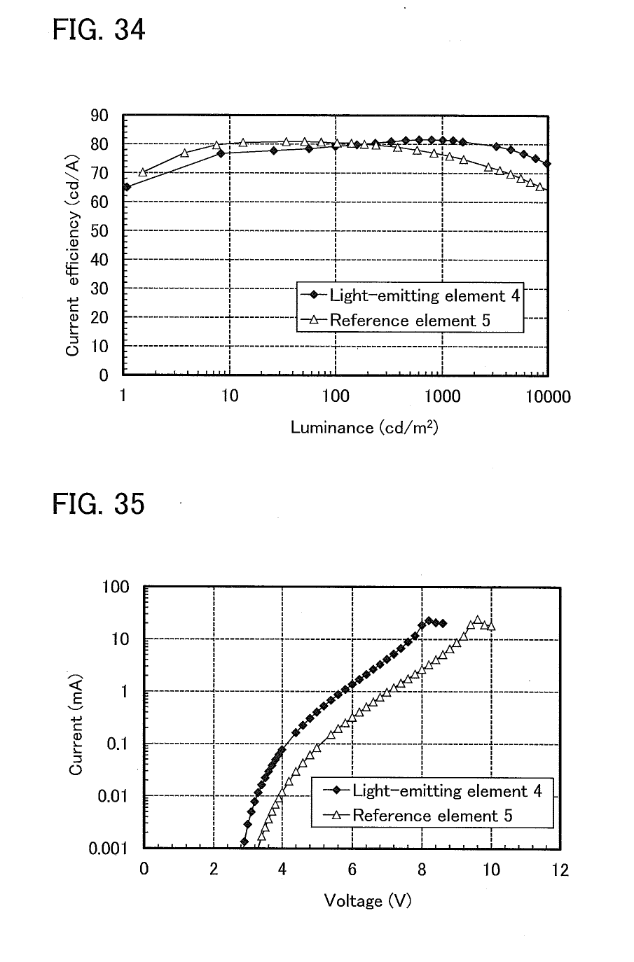

FIG. 32 shows luminance versus current density characteristics of the light-emitting element 4 and the comparative light-emitting element 5. In FIG. 32, the horizontal axis represents the current density (mA/cm²) and the vertical axis represents the luminance (cd/m²). FIG. 33 shows luminance versus voltage characteristics of the light-emitting element 4 and the comparative light-emitting element 5. In FIG. 33, the horizontal axis represents the voltage (V), and the vertical axis represents the luminance (cd/m²). FIG. 34 shows current efficiency versus luminance characteristics of the light-emitting element 4 and the comparative light-emitting element 5. In FIG. 34, the horizontal axis represents the luminance (cd/m²) and the vertical axis represents the current efficiency (cd/A). FIG. 35 shows current versus voltage characteristics of the light-emitting element 4 and the comparative light-emitting element 5. In FIG. 35, the horizontal axis represents the voltage (V) and the vertical axis represents the current (mA).

Table 4 shows voltage (V), current density (mA/cm²), CIE chromaticity coordinates (x, y), current efficiency (cd/A), and external quantum efficiency (%) of each light-emitting element at a luminance of around 1000 cd/m².

TABLE 4
Characteristics of the light-emitting elements
of Example 4 at ca. 1000 cd/m².

| | | current | | lumi- | current | external |
|---|---|---|---|---|---|---|
| | volt- | density | chroma- | nance | effi- | quantum |
| | age | (mA/ | ticity | (cd/ | ciency | efficiency |
| | (V) | cm²) | (x, y) | m²) | (cd/A) | (%) |
| light- | 3.8 | 1.2 | (0.42, 0.57) | 1009 | 82 | 23 |
| emitting | | | | | | |
| element 4 | | | | | | |
| comparative | 4.6 | 1.1 | (0.41, 0.58) | 836 | 77 | 22 |
| light- | | | | | | |
| emitting | | | | | | |
| element 5 ^{a} | | | | | | |

^{a} Reference element 2.

As shown in Table 4, the CIE chromaticity coordinates (x, y) of the light-emitting element 4 were (0.42, 0.57) at a luminance of 1009 cd/m². The CIE chromaticity coordinates (x, y) of the comparative light-emitting element 5 were (0.41, 0.58) at a luminance of 836 cd/m².

According to Table 4, the current efficiencies of the light-emitting element 4 at a luminance of 1009 cd/m² and of the comparative light-emitting element 5 at a luminance of 836 cd/m² were 82 cd/A and 77 cd/A, respectively. Further, the external quantum efficiencies of the light-emitting element 4 at a luminance of 1009 cd/m² and of the comparative light-emitting element 5 at a luminance of 836 cd/m² were 23% and 22%, respectively.

As described above, the luminance versus voltage characteristics, the current efficiency versus luminance characteristics, and the current versus voltage characteristics differ between the light-emitting element 4 of one embodiment of the present invention and the comparative light-emitting element 5. It is found that the light-emitting element 4 is driven at lower voltage and has higher current efficiency than the comparative light-emitting element 5. A structure difference between the compounds used as host materials in the light-emitting layers is as follows: the compound used for the light-emitting element 4 has a dibenzo[f,h]quinoline ring while the compound used for the comparative light-emitting element 5 has a triphenylene ring.

According to Table 4, the light-emitting element 4 has higher current efficiency and external quantum efficiency than the comparative light-emitting element 5. The light-emitting element of one embodiment of the present invention contains, between the pair of electrodes, the organic compound having the dibenzo[f,h]quinoline ring, and thus is effective in achieving high current efficiency and high external quantum efficiency.

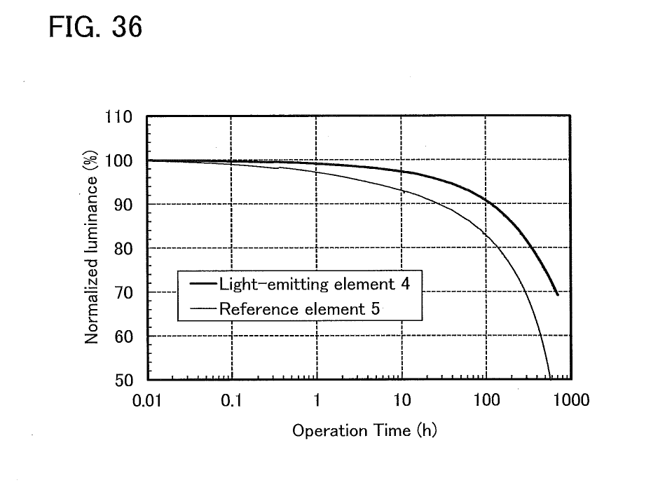

Next, reliability tests of the light-emitting element 4 and the comparative light-emitting element 5 were carried out. FIG. 36 shows results of the reliability tests.

In the reliability tests, the light-emitting element 4 and the comparative light-emitting element 5 were driven under the conditions where the initial luminance was set to 5000 cd/m² and the current density was constant. The results are shown in FIG. 36. The horizontal axis represents the driving time (h) of the element and the vertical axis represents the normalized luminance (%) on the assumption that the initial luminance is 100%. As shown in FIG. 36, it took 678 hours of driving time for the normalized luminance of the light-emitting element 4 to decline 70% or lower, whereas it took 291 hours of driving time for the normalized luminance of the comparative light-emitting element 5 to decline 70% or lower.

FIG. 36 demonstrates that the light-emitting element 4 of one embodiment of the present invention has a longer lifetime than the comparative light-emitting element 5.

The above results demonstrate that the light-emitting element 4 in which 2mDBTBPDBQu-II is used for the light-emitting layer is driven at low voltage and has high efficiency, low power consumption, and a long lifetime.

Note that the structure described in this example can be combined as appropriate with any of the structures described in the embodiments or the other examples.

This application is based on Japanese Patent Application serial no. 2012-286619 filed with the Japan Patent Office on Dec. 28, 2012, the entire contents of which are hereby incorporated by reference.

What is claimed is:

1. A compound configured to give a first peak of m/z around 201 and a second peak of m/z around 227 in a mass spectrum.

2. The compound according to claim 1, further configured to give a third peak of m/z around 488.

3. The compound according to claim 1,
wherein the first peak and the second peak are respectively derived from a first product ion and a second product ion of the compound.

4. The compound according to claim 2,
wherein the third peak is derived from a precursor ion of the compound.

5. The compound according to claim 3,
wherein the first product ion has a composition of C₁₆H₉.

6. The compound according to claim 3,
wherein the second product ion has a composition of C₁₇H₁₀N.

7. A film comprising the compound according to claim 1.

8. A compound comprising:
a dibenzo[f,h]quinoline ring;
a heteroaromatic ring selected from a carbazole ring, a dibenzofuran ring, and a dibenzothiophene ring; and
an arylene group having 6 to 13 carbon atoms,
wherein the dibenzo[f,h]quinoline ring is bonded to the heteroaromatic ring via the arylene group, and
wherein the compound is configured to give a first peak of m/z around 202 and a second peak of m/z around 227 in a mass spectrum.

9. The compound according to claim 8, further configured to give a third peak of m/z around 488.

10. The compound according to claim 8,
wherein the first peak and the second peak are respectively derived from a first product ion and a second product ion of the compound.

11. The compound according to claim 9,
wherein the third peak is derived from a precursor ion of the compound.

12. The compound according to claim 10,
wherein the first product ion has a composition of C₁₆H₉.

13. The compound according to claim 10,
wherein the second product ion has a composition of C₁₇H₁₀N.

14. A film comprising the compound according to claim 8.

15. A light-emitting element comprising:
a layer between a pair of electrodes, the layer comprising a compound,
wherein the compound is configured to give a first peak of m/z around 202 and a second peak of m/z around 227 in a mass spectrum.

16. The light-emitting element according to claim 15,
wherein the compound is further configured to give a third peak of m/z around 488.

17. The light-emitting element according to claim 15,
wherein the first peak and the second peak are respectively derived from a first product ion and a second product ion of the compound.

18. The light-emitting element according to claim 16,
wherein the third peak is derived from a precursor ion of the compound.

19. The light-emitting element according to claim 17,
wherein the first product ion has a composition of C₁₆H₉.

20. The light-emitting element according to claim 17,
wherein the second product ion has a composition of C₁₇H₁₀N.

21. An electronic appliance comprising the light-emitting element according to claim 15.

22. A lighting device comprising the light-emitting element according to claim 15.
